(19) United States
(12) Patent Application Publication
(10) Pub. No.: US 2025/0275155 A1
(43) Pub. Date: Aug. 28, 2025

(54) HIGH BANDWIDTH MEMORY SYSTEMS AND DEVICES

(71) Applicant: Yangtze Memory Technologies Co., Ltd., Wuhan (CN)

(72) Inventors: Zhiliang XIA, Wuhan (CN); Zongliang HUO, Wuhan (CN)

(21) Appl. No.: 18/666,719

(22) Filed: May 16, 2024

Related U.S. Application Data
(63) Continuation of application No. PCT/CN2024/078561, filed on Feb. 26, 2024.

(51) Int. Cl. H10B 80/00; H01L 23/522; H01L 23/528; H01L 25/065

(52) U.S. Cl. CPC H10B 80/00; H01L 23/5226; H01L 23/5283; H01L 25/0657; H01L 2225/06524

(57) ABSTRACT

The present disclosure relates methods, devices, systems, and techniques for high bandwidth memory (HBM). An example semiconductor device includes a first layer, a second layer, a first die between the first layer and the second layer, and a second die stacked together along a first direction. Each of the first die and the second die has a conductive layer. The first die and the second die are bonded through the second layer. The semiconductor device further includes a first contact structure coupled to the conductive layer of the first die and a second contact structure coupled to the conductive layer of the second die. The first contact structure extends along the first direction and contacts the conductive layer of the first die without extending through the second layer. The second contact structure extends through the second layer along the first direction without extending through the second die.

### CROSS-REFERENCE TO RELATED APPLICATIONS

This application is a continuation of International Application No. PCT/CN2024/078561, filed on Feb. 26, 2024, the disclosure of which is hereby incorporated by reference in its entirety.

### TECHNICAL FIELD

The present disclosure relates to high bandwidth memory (HBM) systems and devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

A high bandwidth memory (HBM) uses stacked memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers.

### SUMMARY

The present disclosure describes methods, devices, systems and techniques for high bandwidth memory (HBM).

One aspect of the present disclosure features a semiconductor device including a first layer, a second layer, a first die between the first layer and the second layer, and a second die stacked together along a first direction. Each of the first die and the second die has a conductive layer. The first die and the second die are bonded through the second layer. The semiconductor device further includes a first contact structure coupled to the conductive layer of the first die and a second contact structure coupled to the conductive layer of the second die. The first contact structure extends along the first direction and contacts the conductive layer of the first die without extending through the second layer. The second contact structure extends through the second layer along the first direction without extending through the second die. The second contact structure contacts the conductive layer of the second die without extending through the conductive layer of the first die.

In some implementations, the semiconductor device further includes a base die. The base die, the first layer, the first die, the second layer, and the second die are stacked along the first direction. The base die and the first die are bonded through the first layer.

In some implementations, a first end of the conductive layer of the first die and a first end of the conductive layer of the second die are offset along a second direction perpendicular to the first direction.

In some implementations, the second contact structure is between the first end of the conductive layer of the first die and the first end of the conductive layer of the second die along the second direction.

In some implementations, each of the first contact structure and the second contact structure is a continuous structure.

In some implementations, the second layer includes at least one dielectric material and excludes a conductive bonding contact, and the first layer includes conductive bonding contacts and at least one dielectric material isolating the conductive bonding contacts.

In some implementations, the second layer includes a top bonding layer and a bottom bonding layer each including a dielectric material and excluding a conductive bonding contact. The dielectric material of the top bonding layer of the second layer is bonded to the dielectric material of the bottom bonding layer of the second layer. The first layer includes a top bonding layer and a bottom bonding layer each including conductive bonding contacts and a dielectric material isolating the conductive bonding contacts. The dielectric material of the top bonding layer of the first layer is bonded to the dielectric material of the bottom bonding layer of the first layer. The conductive bonding contacts of the top bonding layer of the first layer are bonded to the conductive bonding contacts of the bottom bonding layer of the first layer.

In some implementations, the base die includes first vias extending along the first direction and being coupled to the conductive bonding contacts of the first layer. Each of the first contact structure and the second contact structure is coupled to one of the first vias through one of the conductive bonding contacts of the first layer.

In some implementations, the semiconductor device further includes a computing die and an interposer, where the base die and the computing die are integrated on different positions of the interposer along a second direction perpendicular to the first direction.

In some implementations, the base die includes first vias coupled to the computing die through the interposer, the first vias are coupled to first conductive terminals on a surface of the interposer, the computing die is coupled to second conductive terminals on the surface of the interposer, and the first conductive terminals and the second conductive terminals are coupled through conductive lines in the interposer.

In some implementations, the semiconductor device further includes a computing die and a third layer between the computing die and the base die. The computing die, the third layer, the base die, the first layer, the first die, the second layer, and the second die are stacked along the first direction. The base die and the computing die are bonded through the third layer.

In some implementations, the third layer includes conductive bonding contacts and at least one dielectric material isolating the conductive bonding contacts.

In some implementations, the third layer includes a top bonding layer and a bottom bonding layer each including conductive bonding contacts and a dielectric material isolating the conductive bonding contacts. The dielectric material of the top bonding layer of the third layer is bonded to the dielectric material of the bottom bonding layer of the third layer. The conductive bonding contacts of the top bonding layer of the third layer are bonded to the conductive bonding contacts of the bottom bonding layer of the third layer.

In some implementations, the base die includes first vias coupled to the computing die. The computing die includes second vias extending along the first direction and being coupled to the conductive bonding contacts of the third layer. The first vias are coupled to the second vias through the conductive bonding contacts of third layer.

In some implementations, the semiconductor device further includes an interposer, where the interposer, the computing die, the third layer, the base die, the first layer, the first die, the second layer, and the second die are stacked along the first direction.

In some implementations, the semiconductor device further includes a third die farthest from the base die among the first die, the second die, and the third die along the first direction, where each of a thickness of the first die and a thickness of the second die is smaller than a thickness of the third die along the first direction.

In some implementations, each of the thickness of the first die and the thickness of the second die is in a range between 3 micrometers (μm) and 20 μm.

In some implementations, a size of a cross section of the second contact structure in the first die is greater than a size of a cross section of the second contact structure in the second die. The cross section of the second contact structure in the first die and the cross section of the second contact structure in the second die are perpendicular to the first direction.

In some implementations, the first contact structure and the second contact structure are formed by a same process.

In some implementations, each of the first contact structure and the second contact structure has a critical dimension (CD) in a range between 0.5 μm and 10 μm.

In some implementations, at least one of the first die or the second die includes a memory array comprising an array of memory cells and a peripheral circuitry coupled to the memory array.

In some implementations, the at least one of the first die or the second die is a dynamic random-access memory (DRAM) device.

In some implementations, the base die includes a control circuitry configured to control the first die and the second die.

In some implementations, a stacked structure of the first die and the second die includes a first device area, a second device area, and a connection area between the first device area and the second device area along a second direction perpendicular to the first direction. Each of the first die and the second die includes one or more memory arrays in the first device area and the second device area. The first contact structure and the second contact structure are in the connection area.

In some implementations, a ratio of a size of a cross section of the connection area to a sum of a first size of a cross section of the first device area and a second size of a cross section of the second device area is in a range between ⅙ and ⅕. The crosse section of the connection area, the cross section of the first device area, and the cross section of the second device area are perpendicular to the first direction.

Another aspect of the present disclosure features a semiconductor device including a base die, a first layer, a second layer, a first die between the first layer and the second layer, and a second die stacked together along a first direction. Each of the base die, the first die, and the second die has a conductive layer. The first die and the second die are bonded through the second layer. The base die and the first die are bonded through the first layer. The semiconductor device further includes a first contact structure coupled to the conductive layer of the base die and a second contact structure coupled to the conductive layer of the first die. The first contact structure extends along the first direction and contacts the conductive layer of the base die without extending through the first layer. The second contact structure extends through the first layer along the first direction without extending through the second layer. The second contact structure contacts the conductive layer of the first die without extending through the conductive layer of the base die. The semiconductor device further includes a third contact structure coupled to the conductive layer of the second die. The third contact structure extends through the first layer and the second layer along the first direction without extending through the second die. The third contact structure contacts the conductive layer of the second die without extending through the conductive layer of the first die.

In some implementations, a first end of the conductive layer of the first die and a first end of the conductive layer of the second die are offset along a second direction perpendicular to the first direction.

In some implementations, the third contact structure is between the first end of the conductive layer of the first die and the first end of the conductive layer of the second die along the second direction.

In some implementations, each of the first contact structure, the second contact structure, and the third contact structure is a continuous structure.

In some implementations, the second layer includes at least one dielectric material and excludes a conductive bonding contact, and the first layer includes at least one dielectric material and excludes a conductive bonding contact.

In some implementations, the second layer includes a top bonding layer and a bottom bonding layer each including a dielectric material and excluding a conductive bonding contact. The dielectric material of the top bonding layer of the second layer is bonded to the dielectric material of the bottom bonding layer of the second layer. The first layer includes a top bonding layer and a bottom bonding layer each including a dielectric material and excluding a conductive bonding contact. The dielectric material of the top bonding layer of the first layer is bonded to the dielectric material of the bottom bonding layer of the first layer.

In some implementations, the base die includes an interconnect layer extending along a second direction perpendicular to the first direction. Each of the first contact structure, the second contact structure, and the third contact structure is coupled to the interconnect layer.

In some implementations, the semiconductor device further includes a computing die and an interposer. The base die and the computing die are integrated on different positions of the interposer along the second direction. The base die and the computing die are coupled through the interconnect layer and the interposer.

In some implementations, the interconnect layer is coupled to first conductive terminals on a surface of the interposer. The computing die is coupled to second conductive terminals on the surface of the interposer. The first conductive terminals and the second conductive terminals are coupled through conductive lines in the interposer.

In some implementations, the semiconductor device further includes a computing die and a third layer between the computing die and the base die. The computing die, the third layer, the base die, the first layer, the first die, the second layer, and the second die are stacked along the first direction. The base die and the computing die are bonded through the third layer.

In some implementations, the third layer includes conductive bonding contacts and at least one dielectric material isolating the conductive bonding contacts.

In some implementations, the third layer includes a top bonding layer and a bottom bonding layer each including conductive bonding contacts and a dielectric material isolating the conductive bonding contacts. The dielectric material of the top bonding layer of the third layer is bonded to the dielectric material of the bottom bonding layer of the third layer. The conductive bonding contacts of the top bonding layer of the third layer are bonded to the conductive bonding contacts of the bottom bonding layer of the third layer.

In some implementations, the computing die includes vias extending along the first direction and being coupled to the conductive bonding contacts of the third layer. The interconnect layer of the base die is coupled to the vias through the conductive bonding contacts of the third layer.

In some implementations, the semiconductor device further includes an interposer, where the interposer, the computing die, the base die, the first die, and the second die are stacked along the first direction.

In some implementations, the semiconductor device further includes a third die farthest from the base die among the first die, the second die, and the third die along the first direction. Each of a thickness of the first die and a thickness of the second die is smaller than a thickness of the third die along the first direction.

In some implementations, each of the thickness of the first die and the thickness of the second die is in a range between 3 μm and 20 μm.

In some implementations, a size of a cross section of the second contact structure in the first die is greater than a size of a cross section of the second contact structure in the second die. The cross section of the second contact structure in the first die and the cross section of the second contact structure in the second die are perpendicular to the first direction.

In some implementations, the first contact structure and the second contact structure are formed by a same process.

In some implementations, each of the first contact structure and the second contact structure has a CD in a range between 0.5 μm and 10 μm.

In some implementations, at least one of the first die or the second die includes a memory array comprising an array of memory cells and a peripheral circuitry coupled to the memory array.

In some implementations, the at least one of the first die or the second die is a DRAM device.

In some implementations, the base die includes a control circuitry configured to control the first die and the second die.

In some implementations, a stacked structure of the first die and the second die includes a first device area, a second device area, and a connection area between the first device area and the second device area along a second direction perpendicular to the first direction Each of the first die and the second die includes one or more memory arrays in the first device area and the second device area. The first contact structure and the second contact structure are in the connection area.

In some implementations, a ratio of a size of a cross section of the connection area to a sum of a first size of a cross section of the first device area and a second size of a cross section of the second device area is in a range between ⅙ and ⅕. The crosse section of the connection area, the cross section of the first device area, and the cross section of the second device area are perpendicular to the first direction.

Another aspect of the present disclosure features a method including providing a first die and a second die, where the first die includes a conductive layer and at least a first bonding layer, and the second die includes a conductive layer and at least a second bonding layer. The method further includes stacking the second die on the first die along a first direction and bonding the second bonding layer of the second die to the first bonding layer of the first die. The method further includes forming a first contact structure and a second contact structure that extend along the first direction. The first contact structure contacts the conductive layer of the first die. The second contact structure extends through the first bonding layer of the first die and the second bonding layer of the second die. The second contact structure contacts the conductive layer of the second die without contacting the conductive layer of the first die.

In some implementations, the first bonding layer of the first die and the second bonding layer of the second die each includes a dielectric material and excludes a conductive bonding contact.

In some implementations, stacking the second die on the first die along the first direction includes aligning the second die with the first die to offset a first end of the conductive layer of the first die and a first end of the conductive layer of the second die along a second direction perpendicular to the first direction.

In some implementations, providing the first die includes thinning the first die by thinning a substrate included in the first die.

In some implementations, the method further includes stacking the first die on a carrier wafer, where the first die is between the carrier wafer and the second die.

In some implementations, the first contact structure and the second contact structure are formed by a same process. The process includes forming a first contact hole and a second contact hole, forming an insulating layer in each of the first contact hole and the second contact hole, and forming the first contact structure and the second contact structure by forming a conductive structure in the insulating layer of each of the first contact hole and the second contact hole. The first contact structure includes the insulating layer and the conductive structure in the first contact hole, and the second contact structure includes the insulating layer and the conductive structure in the second contact hole.

In some implementations, the first contact hole and the second contact hole are formed during a same etching process.

In some implementations, the method further includes forming a mask layer on top of the first die and etching the mask layer to form a first opening and a second opening. The first contact hole extends from the first opening to the conductive layer of the first die, and the second contact hole extends from the second opening to the conductive layer of the second die.

In some implementations, the method further includes forming a third bonding layer on top of the first die, wherein the third bonding layer includes conductive bonding contacts and a dielectric material isolating the conductive bonding contacts.

In some implementations, the method further includes providing a base die, where the base die includes a bottom bonding layer including conductive bonding contacts and a dielectric material isolating the conductive bonding contacts.

In some implementations, the method further includes stacking the base die on the first die by bonding the dielectric material of the bottom bonding layer of the base die to the dielectric material of the third bonding layer of the first die and bonding the conductive bonding contacts of the bottom bonding layer of the base die to the conductive bonding contacts of the third bonding layer of the first die.

Another aspect of the present disclosure features a semiconductor device including a first layer, a second layer, a first die between the first layer and the second layer, and a second die stacked together along a first direction. Each of the first die and the second die has a conductive layer. The first die and the second die are bonded through the second layer. The semiconductor device further includes a first contact structure coupled to the conductive layer of the first die and a second contact structure coupled to the conductive layer of the second die. The first contact structure extends along the first direction and contacts the conductive layer of the first die without extending through the second layer. The second contact structure extends through the conductive layer of the first die and the second layer along the first direction and contacts the conductive layer of the second die without extending through the second die.

In some implementations, the conductive layer of the first die and the conductive layer of the second die are of a same size and at a same position along a second direction perpendicular to the first direction.

In some implementations, each of the first contact structure and the second contact structure includes a conductive layer extending along the first direction and an insulating layer surrounding the conductive layer.

In some implementations, the first layer includes conductive bonding contacts and at least one dielectric material isolating the conductive bonding contacts, and the second layer includes at least one dielectric material and excludes a conductive bonding contact.

In some implementations, the first layer includes a top bonding layer and a bottom bonding layer each including conductive bonding contacts and a dielectric material isolating the conductive bonding contacts. The dielectric material of the top bonding layer of the first layer is bonded to the dielectric material of the bottom bonding layer of the first layer. The conductive bonding contacts of the top bonding layer of the first layer are bonded to the conductive bonding contacts of the bottom bonding layer of the first layer. The second layer includes a top bonding layer and a bottom bonding layer each including a dielectric material and excluding a conductive bonding contact. The dielectric material of the top bonding layer of the second layer is bonded to the dielectric material of the bottom bonding layer of the second layer.

In some implementations, the semiconductor device further includes a base die bonded to the first die through the first layer, where the base die, the first layer, the first die, the second layer, and the second die are stacked along the first direction.

In some implementations, the base die includes first vias extending along the first direction and being coupled to the conductive bonding contacts of the first layer. Each of the first contact structure and the second contact structure is coupled to one of the first vias through one of the conductive bonding contacts of the first layer.

In some implementations, the semiconductor device further includes a computing die and an interposer, where the base die and the computing die are integrated on different positions of the interposer along a second direction perpendicular to the first direction.

In some implementations, the first vias are coupled to first conductive terminals on a surface of the interposer. The computing die is coupled to second conductive terminals on the surface of the interposer. The first conductive terminals and the second conductive terminals are coupled through conductive lines in the interposer.

In some implementations, the semiconductor device further includes a computing die bonded to the base die through a third layer, where the computing die, the third layer, the base die, the first layer, the first die, the second layer, and the second die are stacked along the first direction.

In some implementations, the third layer includes conductive bonding contacts and at least one dielectric material isolating the conductive bonding contacts.

In some implementations, the third layer includes a top bonding layer and a bottom bonding layer each including conductive bonding contacts and a dielectric material isolating the conductive bonding contacts. The dielectric material of the top bonding layer of the third layer is bonded to the dielectric material of the bottom bonding layer of the third layer. The conductive bonding contacts of the top bonding layer of the third layer are bonded to the conductive bonding contacts of the bottom bonding layer of the third layer.

In some implementations, the computing die includes second vias extending along the first direction and being coupled to the conductive bonding contacts of the third layer. The first vias are coupled to the second vias through the conductive bonding contacts of the third layer.

In some implementations, the semiconductor device further includes an interposer, where the interposer, the computing die, the third layer, the base die, the first layer, the first die, the second layer, and the second die are stacked along the first direction.

In some implementations, the semiconductor device further includes a third die farthest from the base die among the first die, the second die, and the third die along the first direction. Each of a thickness of the first die and a thickness of the second die is smaller than a thickness of the third die along the first direction.

In some implementations, each of the thickness of the first die and the thickness of the second die is in a range between 3 μm and 20 μm.

In some implementations, a size of a cross section of the second contact structure in the first die is greater than a size of a cross section of the second contact structure in the second die. The cross section of the second contact structure in the first die and the cross section of the second contact structure in the second die are perpendicular to the first direction.

In some implementations, each of the first contact structure and the second contact structure is a continuous structure.

In some implementations, the first contact structure and the second contact structure are formed by a same process.

In some implementations, each of the first contact structure and the second contact structure has a CD in a range between 0.5 μm and 10 μm.

In some implementations, at least one of the first die or the second die includes a memory array comprising an array of memory cells and a peripheral circuitry coupled to the memory array.

In some implementations, the at least one of the first die or the second die includes a DRAM device.

In some implementations, the base die includes a control circuitry configured to control the first die and the second die.

In some implementations, a stacked structure of the first die and the second die includes a first device area, a second device area, and a connection area between the first device area and the second device area along a second direction perpendicular to the first direction. Each of the first die and the second die includes one or more memory arrays in the first device area and the second device area. The first contact structure and the second contact structure are in the connection area.

In some implementations, a ratio of a size of a cross section of the connection area to a sum of a first size of a cross section of the first device area and a second size of a cross section of the second device area is in a range between ⅙ and ⅕. The crosse section of the connection area, the cross section of the first device area, and the cross section of the second device area are perpendicular to the first direction.

Another aspect of the present disclosure features a semiconductor device including a base die, a first layer, a second layer, a first die between the first layer and the second layer, and a second die stacked together along a first direction. Each of the base die, the first die, and the second die has a conductive layer. The base die and the first die are bonded through the first layer. The first die and the second die are bonded through the second layer. The semiconductor device further includes a first contact structure coupled to the conductive layer of the base die and a second contact structure coupled to the conductive layer of the first die. The first contact structure extends along the first direction and contacts the conductive layer of the base die without extending through the first layer. The second contact structure extends along the first direction and contacts the conductive layer of the first die without extending through the second layer. The semiconductor device further includes a third contact structure coupled to the conductive layer of the second die. The third contact structure extends through the first layer, the conductive layer of the first die, and the second layer along the first direction and contacts the conductive layer of the second die without extending through the second die.

In some implementations, the conductive layer of the first die and the conductive layer of the second die are of a same size and at a same position along a second direction perpendicular to the first direction.

In some implementations, each of the first contact structure, the second contact structure, and the third contact structure includes a conductive layer extending along the first direction and an insulating layer surrounding the conductive layer.

In some implementations, the first layer includes at least one dielectric material and excludes a conductive bonding contact, and the second layer includes at least one dielectric material and excludes a conductive bonding contact.

In some implementations, the first layer includes a top bonding layer and a bottom bonding layer each including a dielectric material and excluding a conductive bonding contact. The dielectric material of the top bonding layer of the first layer is bonded to the dielectric material of the bottom bonding layer of the first layer. The second layer includes a top bonding layer and a bottom bonding layer each including a dielectric material and excluding a conductive bonding contact. The dielectric material of the top bonding layer of the second layer is bonded to the dielectric material of the bottom bonding layer of the second layer.

In some implementations, the base die includes an interconnect layer extending along a second direction perpendicular to the first direction. Each of the first contact structure, the second contact structure, and the third contact structure is coupled to the interconnect layer.

In some implementations, the semiconductor device further includes a computing die and an interposer. The base die and the computing die are integrated on different positions of the interposer along the second direction. The base die and the computing die are coupled through the interconnect layer and the interposer.

In some implementations, the interconnect layer is coupled to first conductive terminals on a surface of the interposer. The computing die is coupled to second conductive terminals on the surface of the interposer. The first conductive terminals and the second conductive terminals are coupled through conductive lines in the interposer.

In some implementations, the semiconductor device further includes a computing die bonded to the base die through a third layer, where the computing die, the third layer, the base die, the first layer, the first die, the second layer, and the second die are stacked along the first direction.

In some implementations, the third layer includes conductive bonding contacts and at least one dielectric material isolating the conductive bonding contacts.

In some implementations, the third layer includes a top bonding layer and a bottom bonding layer each including conductive bonding contacts and a dielectric material isolating the conductive bonding contacts. The dielectric material of the top bonding layer of the third layer is bonded to the dielectric material of the bottom bonding layer of the third layer. The conductive bonding contacts of the top bonding layer of the third layer are bonded to the conductive bonding contacts of the bottom bonding layer of the third layer.

In some implementations, the computing die includes vias extending along the first direction and being coupled to the conductive bonding contacts of the third layer.

In some implementations, the semiconductor device further includes an interposer, where the interposer, the computing die, the third layer, the base die, the first layer, the first die, the second layer, and the second die are stacked along the first direction.

In some implementations, the semiconductor device further includes a third die farthest from the base die among the first die, the second die, and the third die along the first direction. Each of a thickness of the first die and a thickness of the second die is smaller than a thickness of the third die along the first direction.

In some implementations, a size of a cross section of the second contact structure in the first die is greater than a size of a cross section of the second contact structure in the second die. The cross section of the second contact structure in the first die and the cross section of the second contact structure in the second die are perpendicular to the first direction.

In some implementations, each of the first contact structure and the second contact structure is a continuous structure.

In some implementations, the first contact structure and the second contact structure are formed by a same process.

In some implementations, each of the first contact structure, the second contact structure, and the third contact structure has a CD in a range between 0.5 μm and 10 μm.

In some implementations, at least one of the first die or the second die includes a memory array comprising an array of memory cells and a peripheral circuitry coupled to the memory array.

In some implementations, the at least one of the first die or the second die includes a DRAM device.

In some implementations, the base die includes a control circuitry configured to control the first die and the second die.

In some implementations, a stacked structure of the first die and the second die includes a first device area, a second device area, and a connection area between the first device area and the second device area along a second direction perpendicular to the first direction. Each of the first die and the second die includes one or more memory arrays in the first device area and the second device area. The first contact structure and the second contact structure are in the connection area.

In some implementations, a ratio of a size of a cross section of the connection area to a sum of a first size of a cross section of the first device area and a second size of a cross section of the second device area is in a range between ⅙ and ⅕. The crosse section of the connection area, the cross section of the first device area, and the cross section of the second device area are perpendicular to the first direction.

Another aspect of the present disclosure features a method including providing a first die and a second die, where the first die includes a first conductive layer and at least a first bonding layer, and the second die includes a second conductive layer and at least a second bonding layer. The method further includes stacking the second die on the first die along a first direction and bonding the second bonding layer to the first bonding layer. The method further includes forming a first contact structure and a second contact structure that extend along the first direction. The first contact structure contacts the first conductive layer without extending through the first bonding layer. The second contact structure extends through the first conductive layer, the first bonding layer, and the second bonding layer and contacts the second conductive layer without extending through the second die.

In some implementations, the first bonding layer and the second bonding layer each includes a dielectric material and excludes a conductive bonding contact. Bonding the second bonding layer to the first bonding layer includes bonding the dielectric material of the first bonding layer to the dielectric material of the second bonding layer.

In some implementations, stacking the second die on the first die along the first direction includes aligning the second die with the first die to place the first conductive layer and the second conductive layer at a same position along a second direction perpendicular to the first direction, where the first conductive layer and the second conductive layer are of a same size.

In some implementations, the method further includes thinning the first die by thinning a substrate included in the first die.

In some implementations, the method further includes bonding a carrier wafer to a surface of the first die, where the first die is between the carrier wafer and the second die.

In some implementations, forming the first contact structure and the second contact structure includes forming a mask layer on top of the first die, etching the mask layer to form a first opening and a second opening, forming a first contact hole and a second contact hole extending along the first direction, where the first contact hole extends from the first opening to the first conductive layer, and the second contact hole extends from the second opening to the first conductive layer, filling the first contact hole with a filler material, deepening the second contact hole until the second contact hole extends through the first conductive layer and extends to the second conductive layer, removing the filler material in the first contact hole, forming insulating layers in each of the first contact hole and the second contact hole, and forming the first contact structure in the first contact hole and the second contact structure in the second contact hole by depositing a conductive material into the first contact hole and the second contact hole.

In some implementations, forming the first contact hole and the second contact hole includes etching an isolating material in the first die using a first etching gas. Deepening the second contact hole includes etching a conductive material of the first conductive layer using a second etching gas that is different from the first etching gas.

In some implementations, the method further includes forming a third bonding layer on a surface of the first die opposite to the first bonding layer, where the third bonding layer includes conductive bonding contacts and a dielectric material isolating the conductive bonding contacts.

In some implementations, the method further includes providing a base die, where the base die includes vias extending along the first direction and a fourth bonding layer including conductive bonding contacts coupled to the vias and a dielectric material isolating the conductive bonding contacts. The method further includes bonding the fourth bonding layer of the base die to the third bonding layer on the surface of the first die.

In some implementations, bonding the fourth bonding layer to the third bonding layer includes bonding the dielectric material of the fourth bonding layer to the dielectric material of the third bonding layer and bonding the conductive bonding contacts of the fourth bonding layer to the conductive bonding contacts of the third bonding layer.

In some implementations, the method further includes stacking a base die on the first die, where the base die includes a third conductive layer, and forming a third contact structure coupled to the base die. Forming the first contact structure, the second contact structure, and the third contact structure includes forming a mask layer on top of the base die, etching the mask layer to form a first opening, a second opening, and a third opening, forming a first contact hole, a second contact hole, and a third contact hole extending along the first direction, where the first contact hole extends from the first opening to the first conductive layer, the second contact hole extends from the second opening to the first conductive layer, and the third contact hole extends from the third opening to the third conductive layer, filling the first contact hole and the third contact hole with a filler material, deepening the second contact hole until the second contact hole extends through the first conductive layer and extends to the second conductive layer, removing the filler material in the first contact hole and the third contact hole, forming insulating layers in each of the first contact hole, the second contact hole, and the third contact hole, and forming the first contact structure in the first contact hole, the second contact structure in the second contact hole, and the third contact structure in the third contact hole by depositing a conductive material into the first contact hole, the second contact hole, and the third contact hole.

Implementations of the present disclosure can provide one or more of the following technical advantages and/or benefits. For example, a semiconductor device can include multiple memory dice stacked in the vertical direction. Note that the terms “dice” and “dies” can be used interchangeably in the present disclosure. The multiple memory dice are bonded together using a direct bonding technology. Some of the memory dice can be thinned, thereby increasing the memory density and capacity of the semiconductor device. One of the memory dice can be thicker than other memory dice, and thus can replace a carrier wafer to provide support to the other memory dice during a manufacturing process of the semiconductor device. As a result, the carrier wafer can be used less frequently in the manufacturing process, thereby effectively improving the manufacturing efficiency and reducing the manufacturing costs. The memory dice can be coupled to each other and coupled to logic devices through contact structures that extend into the stacked memory dice. With direct bonding between the memory dice, hybrid bonding between adjacent semiconductor structures (such as between a memory die and a base die or between a base die and a computing die), and the usage of contact structures, self-alignment can be achieved in the manufacturing process of the semiconductor device, which effectively improving reliability of the manufacturing. In addition, each of the contact structures can have a continuous structure and a smaller critical dimension. Therefore, higher interconnection density between different dice in the semiconductor device can be achieved, and memory bandwidth and data transfer speed of the semiconductor device can be increased.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices, according to some aspects of the present disclosure.

FIGS. 2A-2E illustrate example semiconductor devices, according to some aspects of the present disclosure.

FIGS. 3A-3H illustrate example semiconductor devices, according to some aspects of the present disclosure.

FIGS. 4A-4J illustrate an example process of manufacturing a semiconductor device, according to some aspects of the present disclosure.

FIG. 5 illustrates a flow chart of an example process of forming a semiconductor device, according to some aspects of the present disclosure.

FIGS. 6A-6G illustrate example semiconductor devices, according to some aspects of the present disclosure.

FIGS. 7A-7N illustrate an example process of manufacturing a semiconductor device, according to some aspects of the present disclosure.

FIG. 8 illustrates a flow chart of an example process of forming a semiconductor device, according to some aspects of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

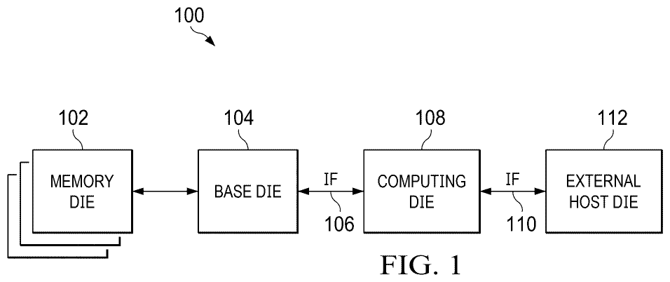

FIG. 1 illustrates a block diagram of an example system 100 having one or more semiconductor devices (e.g., memory devices), according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include one or more memory devices 102, a base device 104, a computing device 108, and an external host device 112. In some implementations, each of devices 102, 104, 108, and 112 can be a die or multiple dies stacked together. Each of devices 102, 104, 108, and 112 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system.

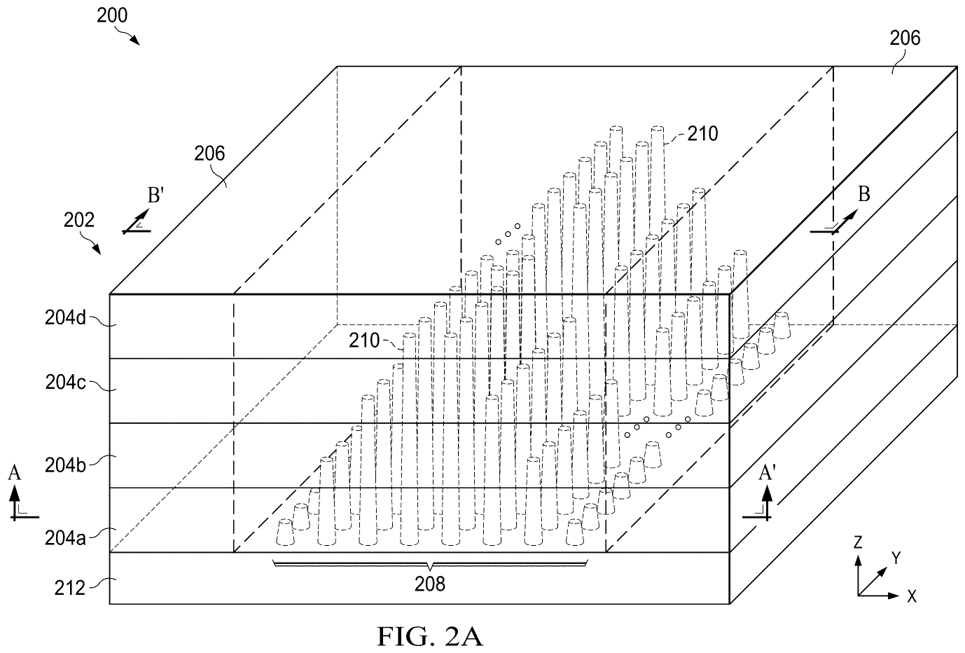

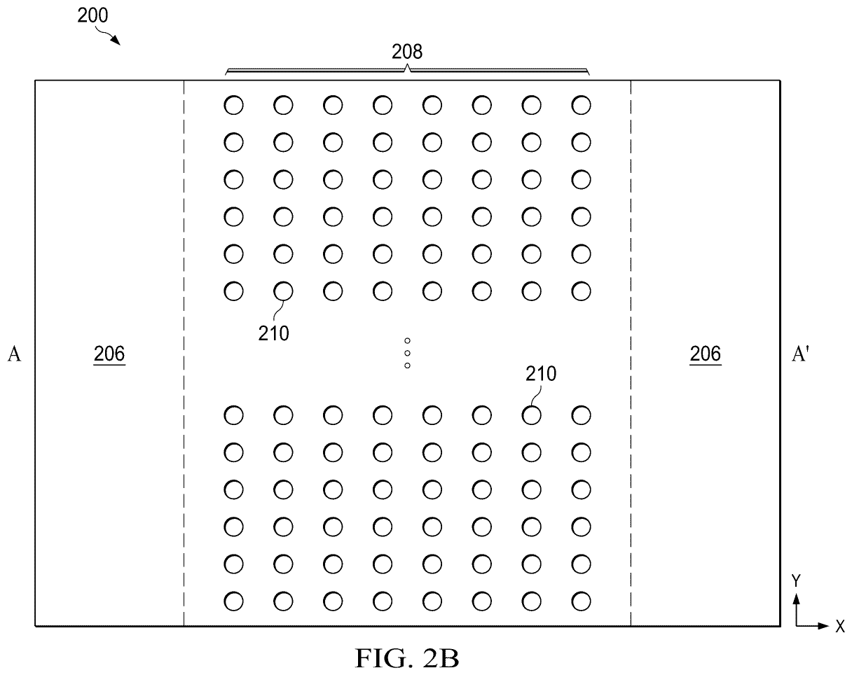

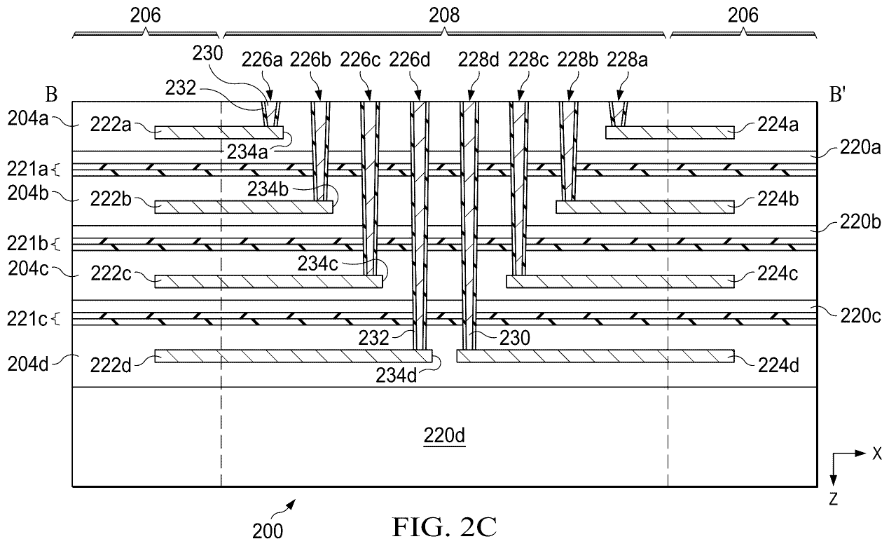

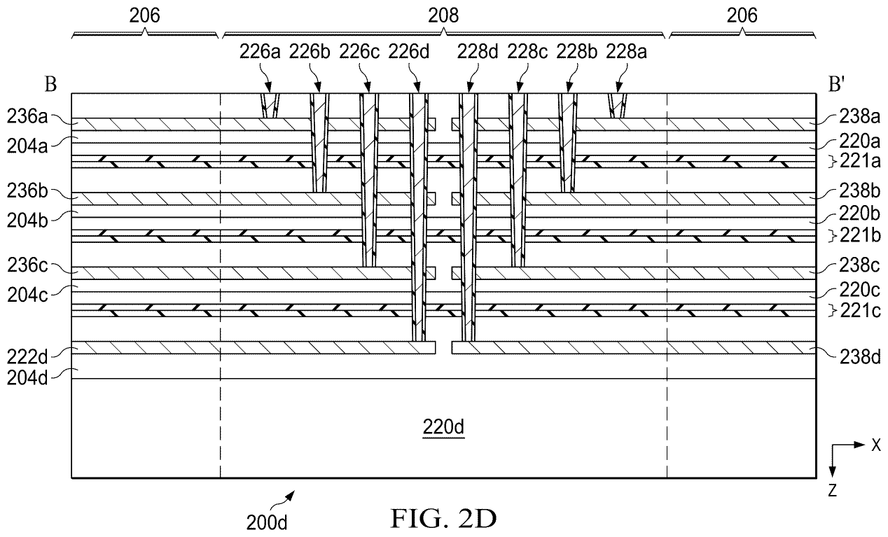

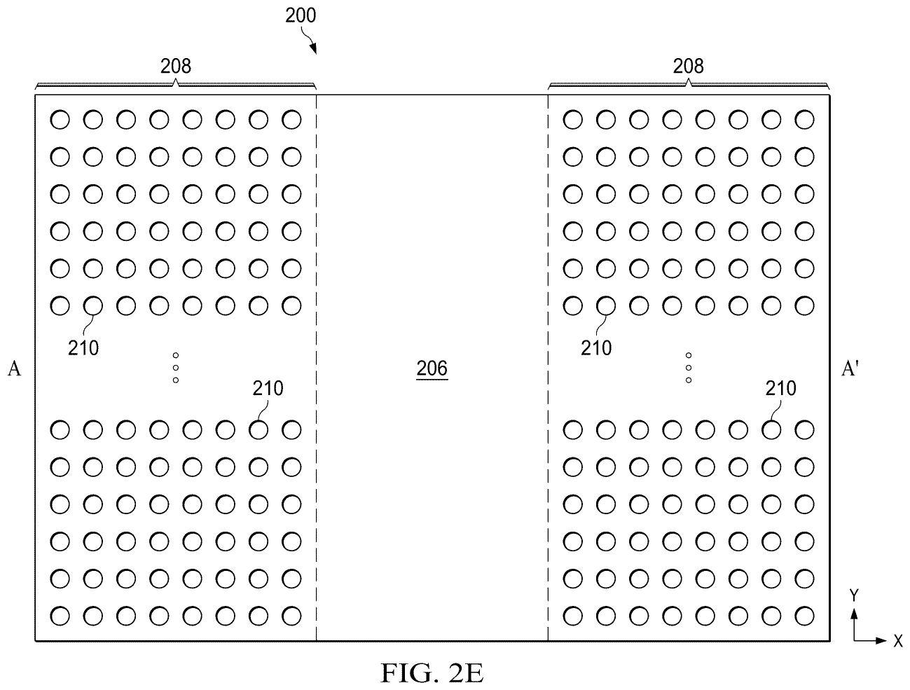

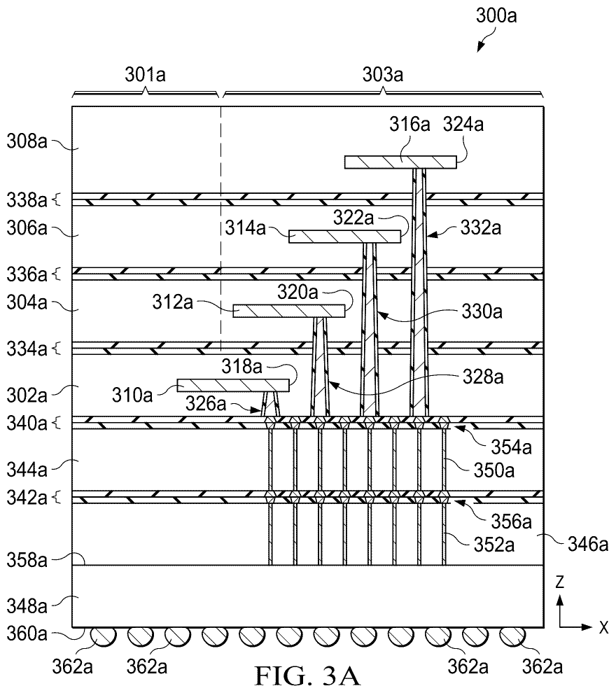

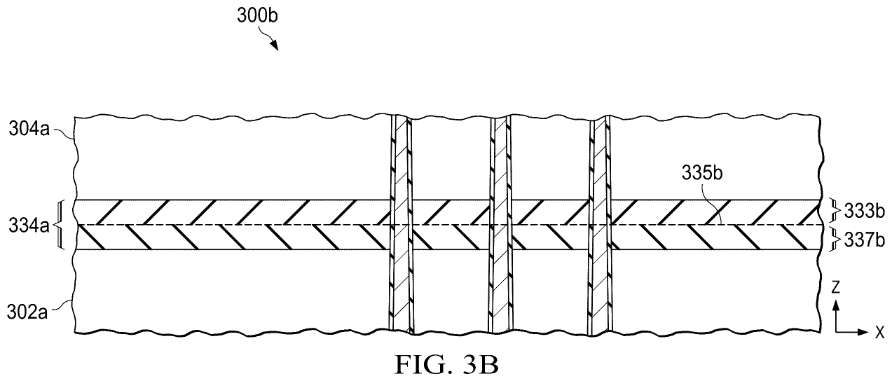

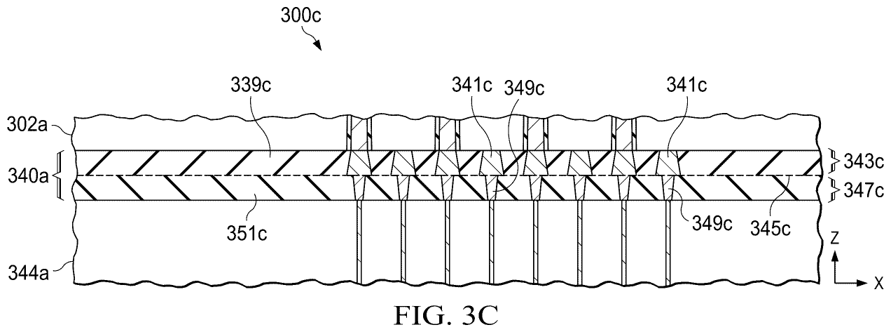

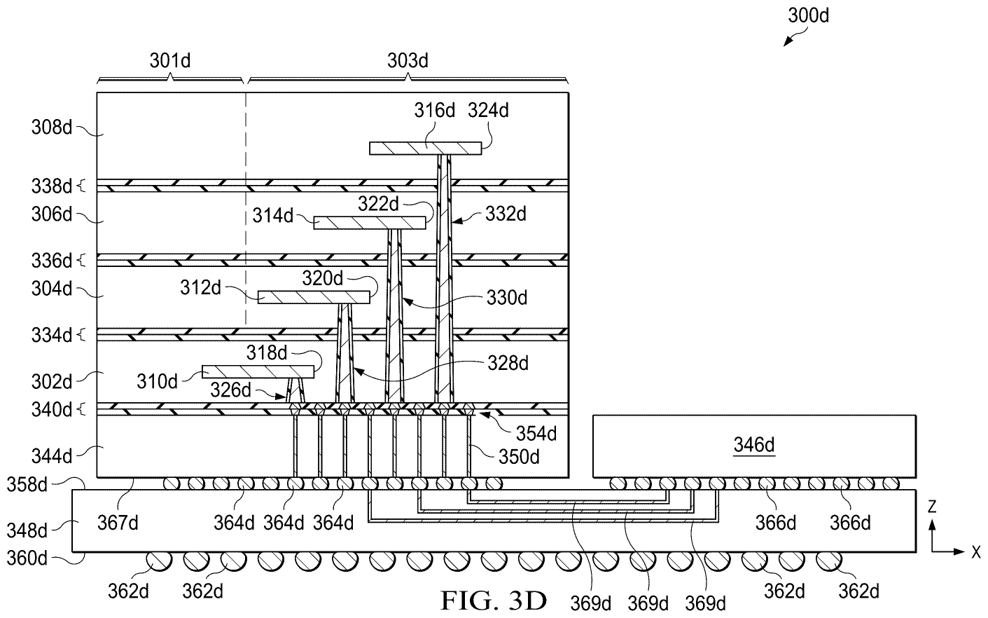

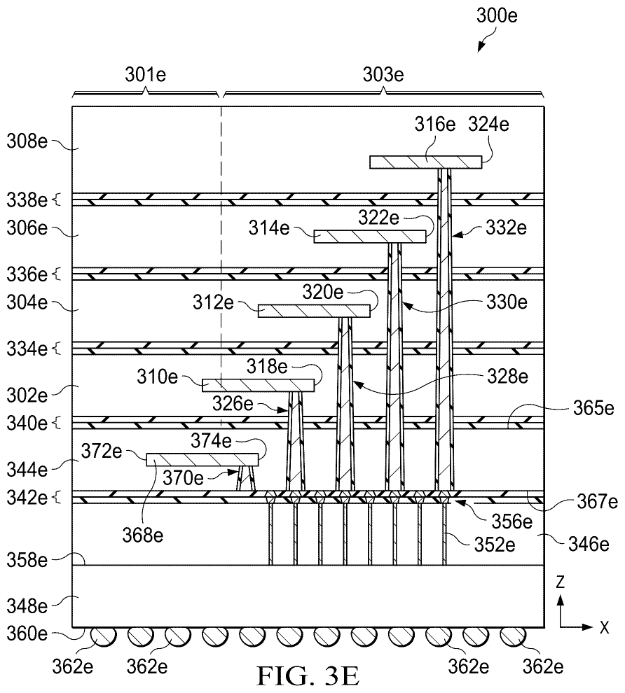

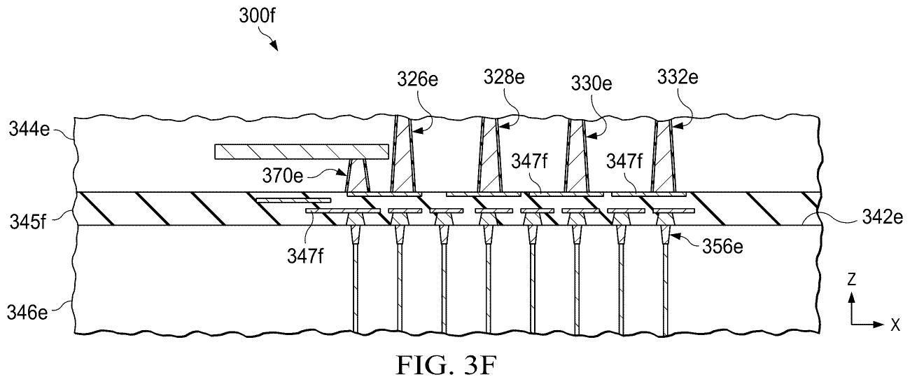

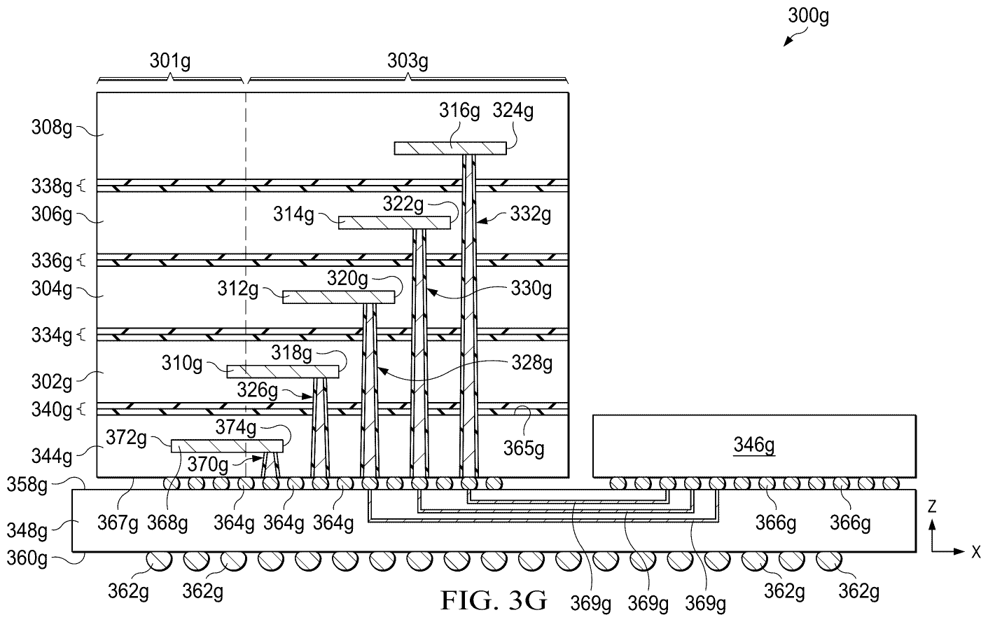

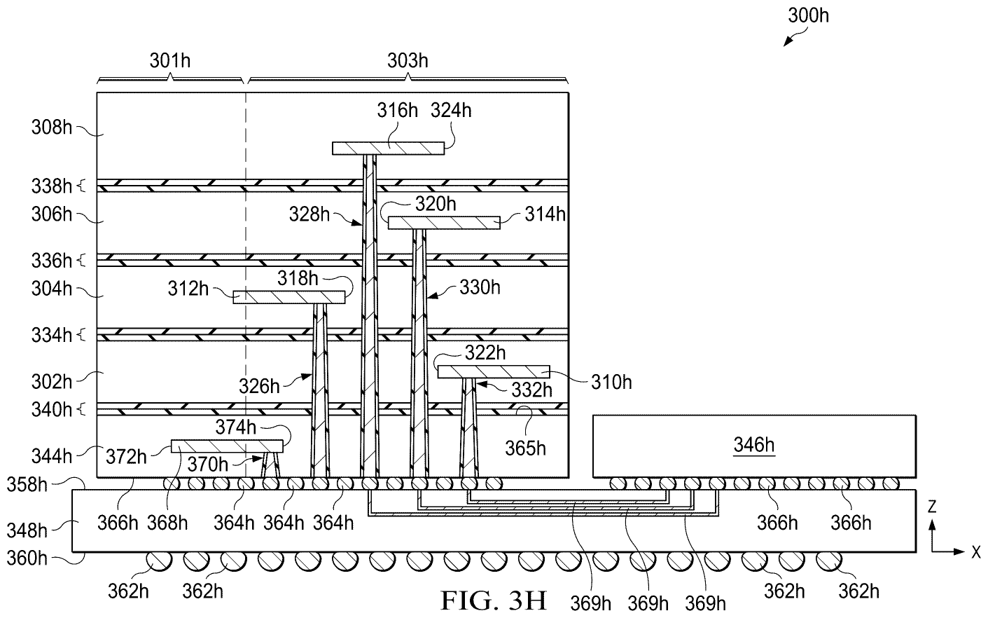

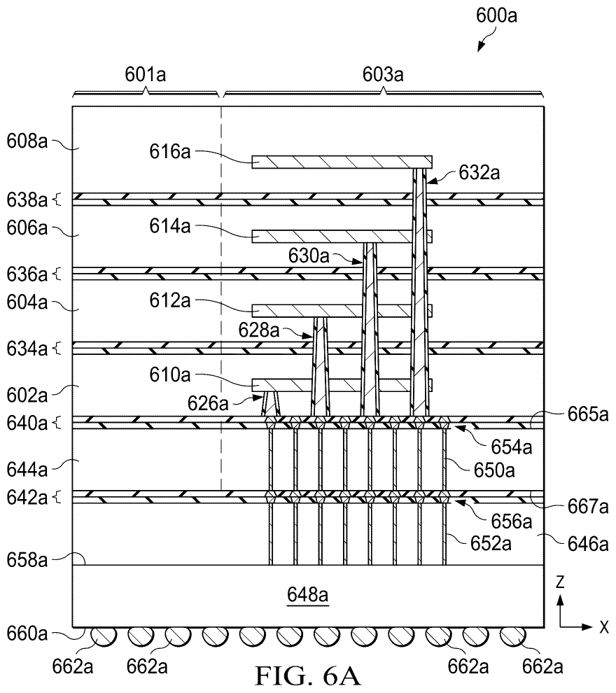

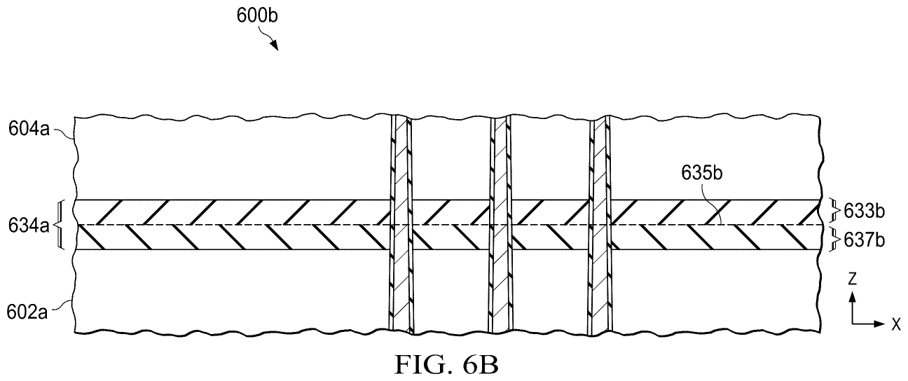

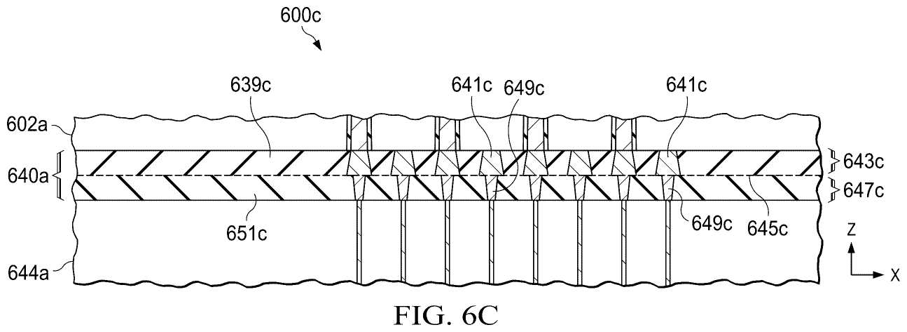

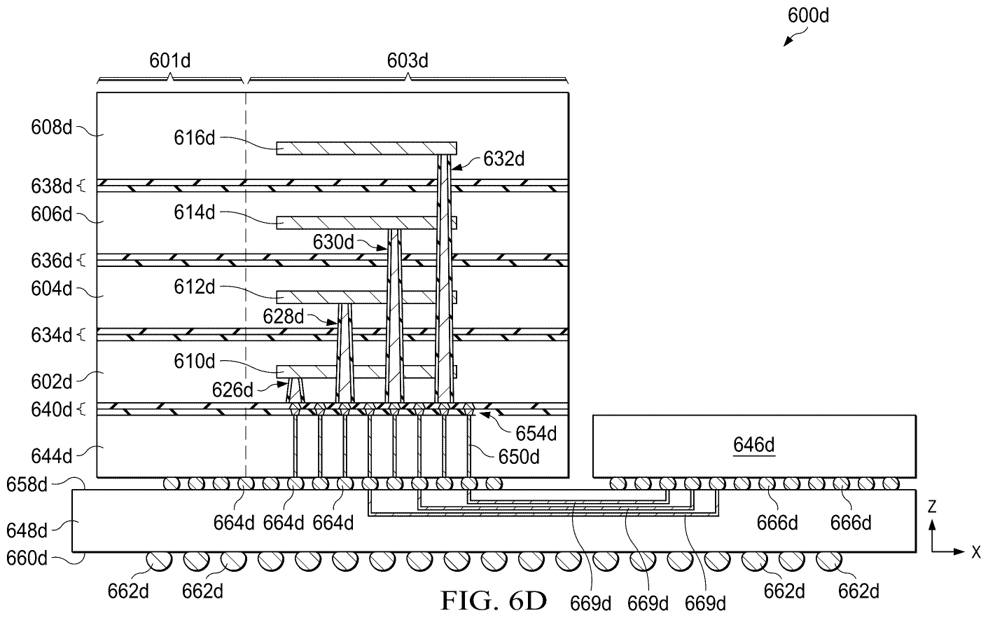

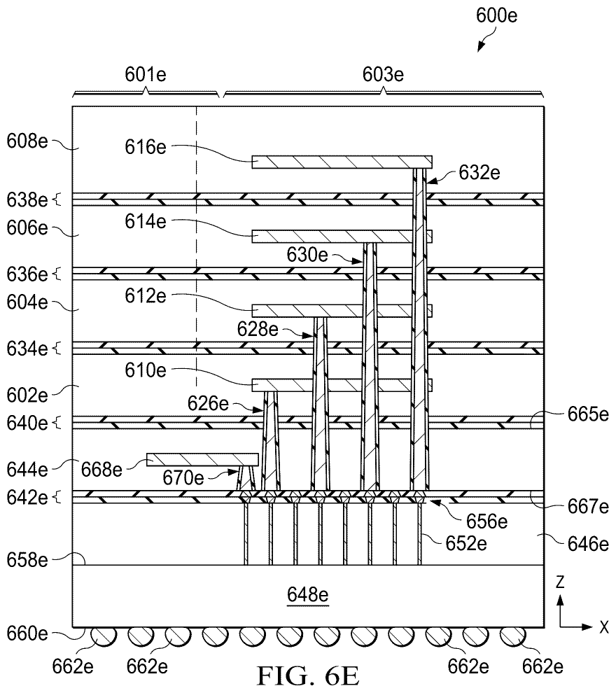

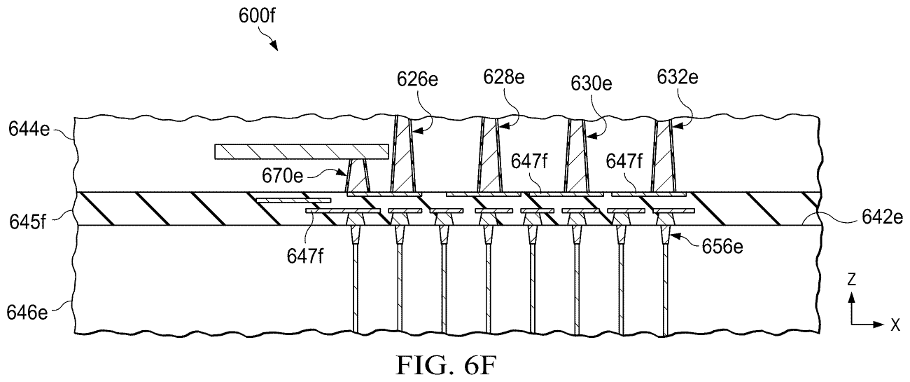

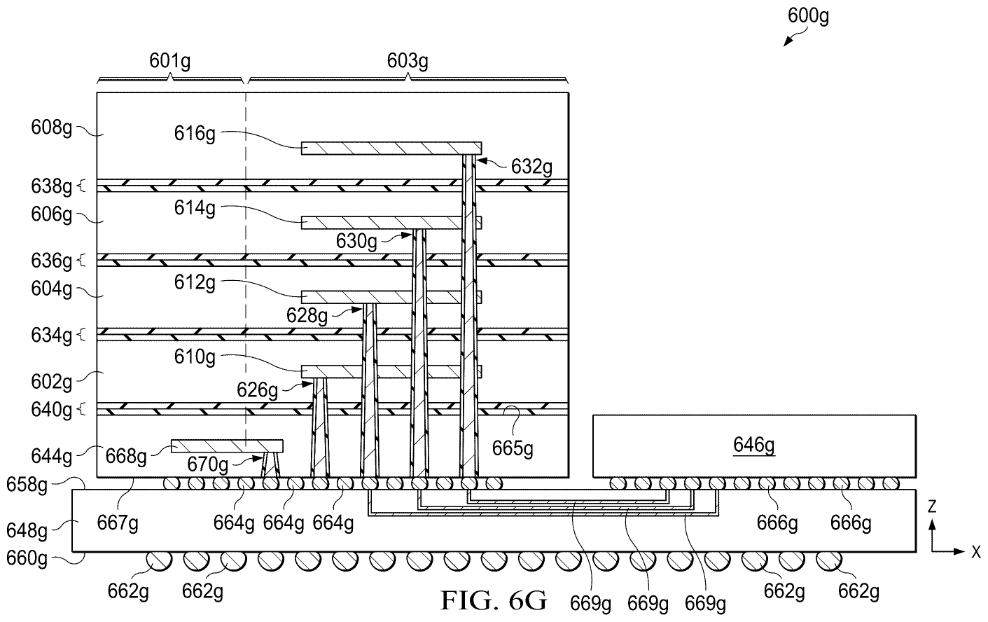

Memory dice 102 can include any memory device disclosed herein, such as a memory device (e.g., a 3D memory device) based on any one of semiconductor structures as described with respect to FIGS. 2A-2E, 3A-3D, 4A-4J, 6A-6D, and 7A-7M. In some implementations, memory dice 102 include one or more dynamic random access memory (DRAM) devices. In some implementations, memory dice 102 include one or more NAND Flash memories. In some implementations, memory dice 102 can include a high bandwidth memory (HBM). In some implementations, memory dice 102 can be stacked together, e.g., as described with further details with respect to FIGS. 2A-2E, 3A-3D, and 6A-6D. In some implementations, memory dice 102 can include a combination of one or more HBM devices as described with respect to FIGS. 2C and 3A-3D and one or more HBM devices as described with respect to FIGS. 2D and 6A-6D.

Base die 104 (also referred to as a logic die or a buffer die) can include buffer circuitry and test logic for memory devices 102. Base die 104 can be configured to provide physical layer communication protocols (e.g., IEEE-1500) between memory dice 102 and computing die 108. Base die 104 can be configured to transmit data between memory dice 102 and computing die 108 based on control commands and addresses from computing die 108.

Computing die 108 can be a logic device and can include at least one processor of an electronic device, such as a central processing unit (CPU), a graphics processing unit (GPU), an application-specific integrated circuit (ASIC), or a system-on-chip (SoC), such as an application processor (AP). Computing die 108 can be configured to send or receive data to or from memory dice 102. Computing die 108 is coupled to base die 104 through an interface 106. Interface 106 can include connections provided by bonding contacts (e.g., as described with respect to FIGS. 3A and 6A) or an interposer (e.g., as described with respect to FIGS. 3D and 6D). In some implementations, interface 106 includes connections provided by any suitable combination of the aforementioned techniques.

System 100 can further include the external host die 112 coupled to computing die 108 through an interface 110. For example, external host die 112 can be a computer, and computing die 108 can be a CPU of the computer. In this example, interface 110 includes connections provided by a mainboard of the computer that are coupled to the CPU. As another example, external host die 112 is a graphics card, computing die 108 is a GPU of the graphics card, and interface 110 includes connections provided by a printed circuit board (PCB) of the graphics card that are coupled to the GPU.

System 100 may further include a memory controller (a.k.a., a controller circuit, which is not shown in FIG. 1) coupled to memory dice 102. In some implementations, the memory controller is located in the computing die 108. Consistent with implementations of the present disclosure, the memory controller can include conductive interconnections through a cover layer that are in contact with conductive pads in a conductive pad layer, and the memory controller can be coupled to memory dice 102 through at least one of the conductive interconnections. The memory controller is configured to control memory dice 102. For example, the memory controller may be configured to operate channel structures via word lines. The memory controller can manage data stored in memory dice 102 and communicate with computing die 108.

In some implementations, the memory controller is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller is designed/configured for operating in a high duty cycle environment SSDs or embedded multi-media-cards (eMMCs) used as data storage for mobile devices, such as smartphones, tablets, laptop computers, etc., and enterprise storage arrays. The memory controller can be configured to control operations of memory dice 102, such as read, erase, and program (or write) operations. The memory controller can also be configured to manage various functions with respect to the data stored or to be stored in memory dice 102 including, but not limited to bad-block management, garbage collection, logical-to-physical address conversion, wear leveling, etc. In some implementations, the memory controller is further configured to process error correction codes (ECCs) with respect to the data read from or written to memory dice 102. In some other implementations, the base die 104 instead of the memory controller is configured to process ECCs. Any other suitable functions may be performed by the memory controller as well, for example, formatting memory dice 102.

The memory controller can communicate with an external device (e.g., computing die 108) according to a particular communication protocol. For example, the memory controller may communicate with the external device through at least one of various interface protocols, such as a USB protocol, an MMC protocol, a peripheral component interconnection (PCI) protocol, a PCIexpress (PCTe or PCI-e) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller and one or more memory dice 102 can be integrated into various types of storage devices, for example, be included in the same package, such as a universal Flash storage (UFS) package or an eMMC package. That is, system 100 can be implemented and packaged into different types of end electronic products. For example, the memory controller and a single memory die 102 may be integrated into a memory card. The memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

FIGS. 2A-2E illustrate example semiconductor devices 200 and 200d, according to some aspects of the present disclosure. The semiconductor device 200 or 200d can be used to form a memory device, e.g., an HBM.

It is noted that X, Y, and Z axes (also referred to as X, Y, and Z directions) are included in FIGS. 2A-2E to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 2A, the semiconductor device 200 includes a stack 202 of memory dice 204a-204d. Each of the memory dice 204a-204d can be a dynamic random access memory (DRAM) device. The memory dice 204a-204d are stacked (e.g., sequentially) along a vertical direction (e.g., the Z direction). The stack 202 includes one or more device areas 206 and one or more connection areas 208. Each of the memory dice 204a-204d can include a memory array and a peripheral circuitry in each device area 206. The memory array can include an array of memory cells, and the peripheral circuitry can be coupled to the memory array.

The semiconductor device 200 further includes contact structures 210 in the connection areas 208. Each contact structure 210 can extend into one of the memory dice 204a-204d and can be coupled out to an external component outside of the stack 202. As described with further details with respect to some other figures in the present disclosure, each contact structure 210 can include a conductive material and can be connected to a conductive layer of one of the memory dice 204a-204d. In some implementations, adjacent memory dices (e.g., memory dice 204a and 204b) among the memory devices 204a-204d are bonded through a corresponding bonding layer (not shown in FIG. 2A). The semiconductor device 200 can further include a base die 212. The stack 202 can be stacked on the base die 212 along the vertical direction. In some implementations, memory die 204a and the base die 212 are bonded through another bonding layer (not shown in FIG. 2A).

FIG. 2B illustrates a cross-sectional view of the semiconductor device 200 along a cut line AA′ of FIG. 2A, according to some aspects of the present disclosure. The semiconductor device 200 includes two device areas 206 arranged in a horizontal direction (e.g., the X direction). The semiconductor device 200 also includes a connection area 208 between the two device areas 206 along the X direction. While FIG. 2B shows an example arrangement of device area(s) 206 and connection area(s) 208, any other suitable arrangements are possible. In some implementations, semiconductor device 200 can include one device area 206 and one connection area 208 adjacent to each other along the X direction. In some implementations, as shown in FIG. 2E, semiconductor device 200 can include two connection areas 208 arranged along the X direction and one device area 206 between the two connection areas 208 along the X direction. In some implementations, semiconductor device 200 can include a first connection area 208, a second connection area 208, and a device area 206 arranged along the X direction. The first connection area 208 can be in the center of the semiconductor device 200, and the second connection area 208 can be on one side (e.g., on the left side) of the first connection area 208. The device area 206 can be on another side (e.g., on the right side) of the first connection area 208. In some implementations, the connection area 208 may exclude word lines in the memory dice 204a-204d. This way, contact structures 210 in the connection area 208 can bypass conductive materials (e.g., metal) of the word lines in the memory dice 204a-204d and can extend through dielectric materials (e.g., an insulation layer or a substrate of a memory device), thereby making manufacture of the semiconductor device 200 cost efficient. A cross section (e.g., in the X-Y plane) of connection area(s) 208 and a cross section (e.g., in the X-Y plane) of device area(s) 206 can be of any suitable sizes. For example, in FIG. 2B, a ratio of a size of a cross section of connection area 208 to a sum of a size of a cross section of the device area 206 (on the left side) and a size of a cross section of the device area 206 (on the right side) can be in any suitable range (e.g., between ⅙ and ⅕). The cross section of connection area 208 and the cross sections of the two device areas 206 can be in the X-Y plane. In some implementations, placing device area(s) 206 in a center of the semiconductor device 200 and placing connection area(s) 208 on one side or two sides of device area(s) 206 along the horizontal direction can make the bonding between memory dice 204a-204d more stable.

In some implementations, each of connection areas 208 can include more than 1,000 contact structures 210. Each contact structure 210 can have a critical dimension (CD) in any suitable range (e.g., between 0.5 micrometer (μm) and 10 μm).

FIG. 2C illustrates a cross-sectional view of the semiconductor device 200 along a cut line BB′ of FIG. 2A, according to some aspects of the present disclosure. Memory die 204a includes a substrate 220a extending along the X direction. Substrate 220a can be any suitable semiconductor substrate having any suitable semiconductor materials, such as monocrystalline, polycrystalline or single crystalline semiconductors. For example, substrate 220a can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. Memory die 204a also includes conductive layers 222a and 224a. Each of conductive layers 222a and 224a extends from device area 206 to connection area 208 and can be coupled to a memory array of memory die 204a or a peripheral circuit of the memory array in device area 206. For example, conductive layers 222a and 224a can be coupled to input/output ports of the memory die 204a. In some implementations, conductive layers 222a and 224a can be configured to provide one or more of power supplies, clock signals, or data path signals to memory die 204a. Each of memory dice 204b-204d also includes their respective substrates 220b-220d and conductive layers (e.g., 222b and 224b, 222c and 224c, 222d and 224d). The conductive layers in each of memory dice 204b-204d are also coupled to a corresponding memory array or a peripheral circuit of the memory die. Similar to conductive layers 222a and 224a, the conductive layers in each of memory dice 204b-204d can also be configured to provide one or more of power supplies, clock signals, or data path signals to the memory die.

In some implementations, some of memory dice 204a-204d can have a reduced thickness (along the Z direction) by having their substrates thinned. As shown in FIG. 2C, each of substrate 220a-220c is thinned while substrate 220d is not. As a result, a thickness of each of memory dice 204a-204c is smaller than a thickness of memory die 204d. The thickness of each of memory dice 204a-204d can be in any suitable range (e.g., between 3 μm and 20 μm).

The semiconductor device 200 includes bonding layers 221a-221c. As shown in FIG. 2C, each of bonding layers 221a-221c is between two of memory dice 204a-204d. Memory dice 204a and 204b are bonded through bonding layer 221a. Memory dice 204b and 204c are bonded through bonding layer 221b. Memory dice 204c and 204d are bonded through bonding layers 221c. Detailed structures of bonding layers 221a-221c are described with respect to some other figures (e.g., FIG. 3B) in the present disclosure. In some implementations, the semiconductor device 200 include a device (not shown) on top of memory die 204a. The device and memory die 204a can be bonded through another bonding layer (not shown) between the device and memory die 204a.

The semiconductor device 200 includes contact structures 226a-226d and 228a-228d in connection area 208. Contact structures 226a-226d and 228a-228d can be examples of contact structures 210 of FIGS. 2A-2B. Contact structure 226a can include an inner layer 230 surrounded by an outer layer 232. In other words, the inner layer 230 is on an inner surface of the outer layer 232. The inner layer 230 can include a conductive material (e.g., copper or tungsten), and the outer layer 232 can include an insulating material (e.g., silicon oxide). Similarly, each of contact structures 226b-226d and 228a-228d also includes a conductive inner layer and an insulating outer layer. Contact structures 226a-226d and 228a-228d extend along the vertical direction (e.g., the Z direction).

In some implementations, each of contact structures 226a-226d and 228a-228d is a continuous structure extending along the Z direction. In other words, each of contact structures 226a-226d and 228a-228d includes a continuous inner layer and a continuous outer layer both extending along the Z direction.

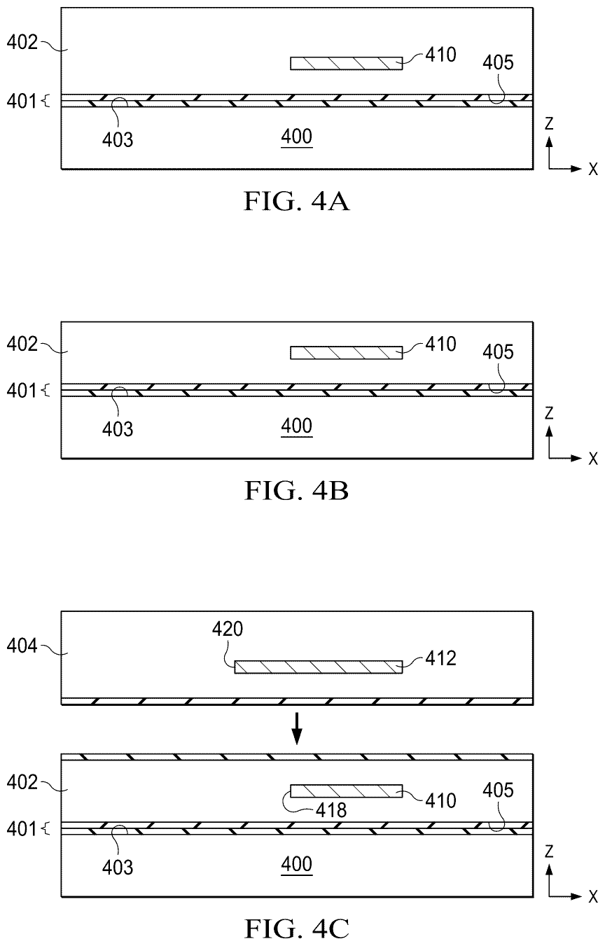

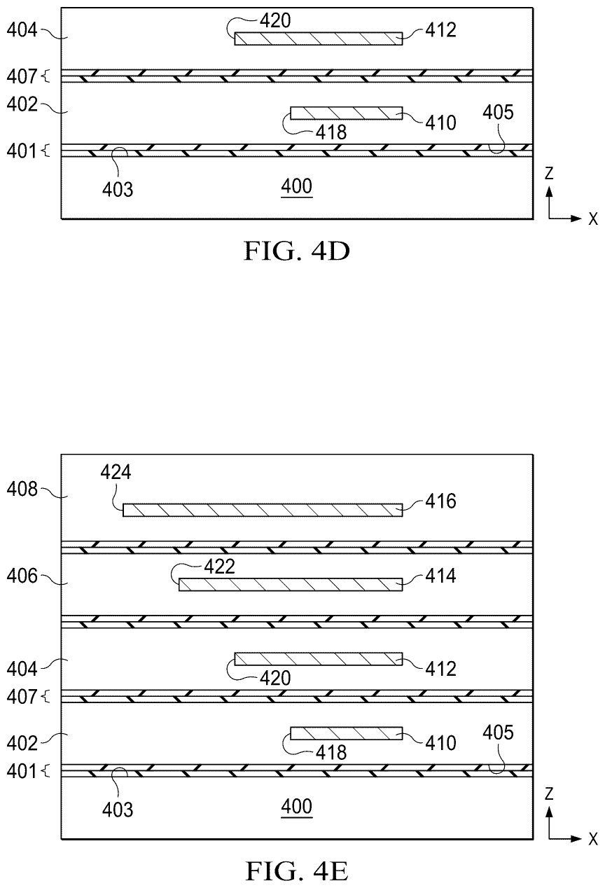

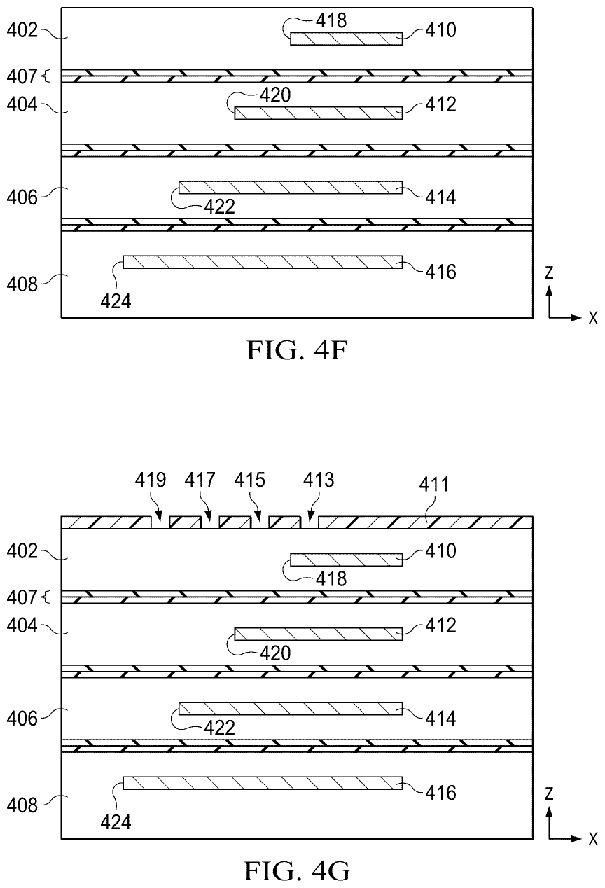

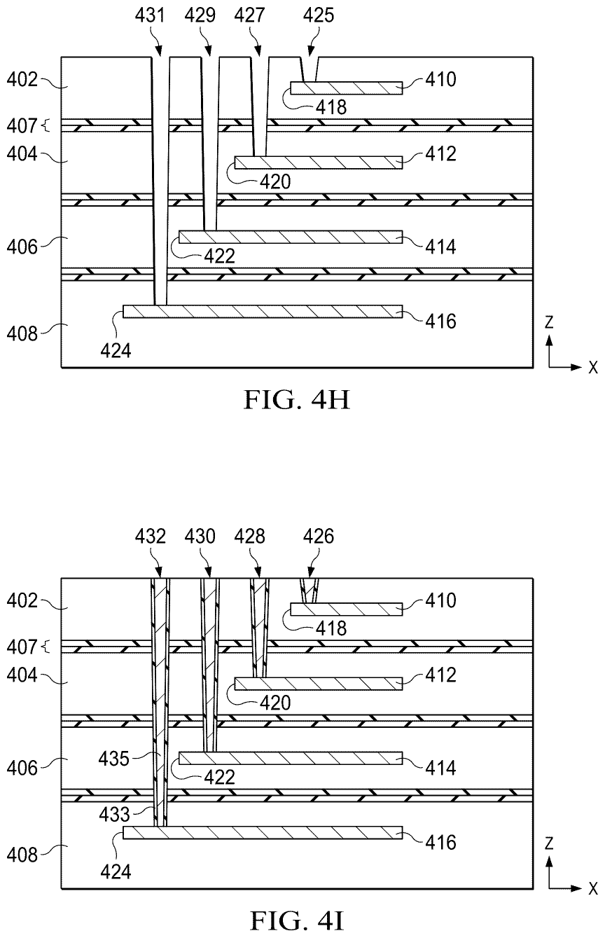

In some implementations, each contact structure of contact structures 226a-226d and 228a-228d can have a shape like a cylinder or a truncated cone. In some implementations, a size of a first cross section of the contact structure at a first position along the Z direction is larger than a size of a second cross section of the contact structure at a second position along the Z direction. The first cross section and the second cross section can be perpendicular to the Z direction. The first position is further away from the thickest memory die among memory dice 204a-204d than the second position. For example, contact structure 226d can have a cross section in memory die 204a and another cross section in memory die 204b. A size of the cross section in memory die 204a can be larger than a size of the cross section in memory die 204b. In some implementations, contact structures 226a-226d and 228a-228d can be formed by a same process (e.g., as described with further details with respect to FIGS. 4G-4I).

Contact structures 226a and 228a extend into memory die 204a without extending through bonding layer 221a. Contact structures 226a and 228a are respectively connected to conductive layers 222a and 224a of memory die 204a. Contact structures 226b and 228b extend through memory die 204a (including substrate 220a) and bonding layer 221a and into memory die 204b without extending through bonding layer 221b. Contact structures 226b and 228b are respectively connected to conductive layers 222b and 224b of memory die 204b. Contact structure 226b does not extend through conductive layer 222a, and contact structure 228b does not extend through conductive layer 224a. Contact structures 226c and 228c extend through memory die 204a (including substrate 220a), bonding layer 221a, memory die 204b (including substrate 220b), and bonding layer 221b and into memory die 204c without extending through bonding layer 221c. Contact structures 226c and 228c are respectively connected to conductive layers 222c and 224c of memory die 204c. Contact structure 226c does not extend through conductive layers 222a and 222b, and contact structure 228c does not extend through conductive layers 224a and 224b. Contact structures 226d and 228d extend through memory die 204a (including substrate 220a), bonding layer 221a, memory die 204b (including substrate 220b), bonding layer 221b, memory die 204c (including substrate 220c), and bonding layer 221c and into memory die 204d. Contact structures 226d and 228d are respectively connected to conductive layers 222d and 224d of memory device 204d. Contact structure 226d does not extend through conductive layers 222a, 222b, and 222c, and contact structure 228d does not extend through conductive layers 224a, 224b, and 224c.

In some implementations, the conductive layers 222a-222d can form a stepped structure to allow each of contact structures 226a-226d to connect to one of conductive layers 222a-222d without extending through other conductive layers. In some implementations, as shown in FIG. 2C, conductive layers 222a-222d can have various lengths. Conductive layers 222a-222d can extend from substantially the same position in the X direction and extend by different lengths (e.g., to the right side) to form the stepped structure. Specifically, contact structure 226b is between an end 234a (e.g., on the right side) of conductive layer 222a and an end 234b (e.g., on the right side) of conductive layer 222b along the X direction. That is, end 234a of conductive layer 222a is between contact structure 226a and contact structure 226b along the X direction. This way, contact structure 226b can extend through memory die 204a and bypass conducive layer 222a of memory die 204a (e.g., without extending through conducive layer 222a). Similarly, contact structure 226c is between end 234b of conductive layer 222b and an end 234c (e.g., on the right side) of conductive layer 222c along the X direction, so that contact structure 226c can extend through memory dice 204a-204b and bypass conducive layers 222a-222b (e.g., without extending through conducive layers 222a-222b). In addition, contact structure 226d is between end 234c of conductive layer 222c and an end 234d (e.g., on the right side) of conductive layer 222d along the X direction, so that contact structure 226d can extend through memory dice 204a-204c and bypass conducive layers 222a-222c (e.g., without extending through conducive layers 222a-222c).

In a similar way, the conductive layers 224a-224d also can form a stepped structure to allow each of contact structures 228a-228d to connect to one of conductive layers 224a-224d without extending through other conductive layers. While FIG. 2C shows an example in which stepped structures are formed by conductive layers of different lengths, other suitable ways to arrange the conductive layers are also possible (e.g., as described with further details with respect to FIGS. 3A, 3D, 3E, 3G, and 3H).

FIG. 2D illustrates a cross-sectional view of a semiconductor device 200d along cut line BB′, according to some aspects of the present disclosure. Semiconductor device 200d differs from semiconductor device 200 of FIG. 2C in that memory dice 204a-204d of semiconductor device 200d can include conductive layers of the same length and at the same position along the X direction. As shown in FIG. 2D, memory die 204a includes conductive layers 236a and 238a. Each of conductive layers 236a and 238a extends from device area 206 to connection area 208 and is coupled to a memory array of memory die 204a or a peripheral circuit of the memory array in device area 206. For example, conductive layers 236a and 238a can be coupled to input/output ports of the memory die 204a. In some implementations, conductive layers 236a and 238a can be configured to provide one or more of power supplies, clock signals, or data path signals to memory die 204a. Each of memory dice 204b-204d also includes their respective conductive layers (e.g., 236b and 238b, 236c and 238c, 236d and 238d). The conductive layers in each of memory dice 204b-204d are also coupled to a corresponding memory array or a peripheral circuit of each memory die. Similar to conductive layers 236a and 238a, the conductive layers in each of memory dice 204b-204d can also be configured to provide one or more of power supplies, clock signals, or data path signals to the memory die. Conductive layers 236a-236d have the same length and are at the same position along the X direction. Similarly, conductive layers 238a-238d also have the same length and are at the same position along the X direction. In some implementations, conductive layers 236a-236d have the same shape, and conductive layers 238a-238d have the same shape. The manufacture cost can be reduced because conductive layers in each memory die can be formed using the same mask.

Semiconductor device 200d includes contact structures 226a-226d and 228a-228d extending along the vertical direction (e.g., the Z direction). Contact structures 226a and 228a extend into memory die 204a without extending through bonding layer 221a. Contact structures 226a and 228a are respectively connected to conductive layers 236a and 238a of memory die 204a. Contact structures 226b and 228b extend through memory die 204a (including substrate 220a) and bonding layer 221a and into memory die 204b without extending through bonding layer 221b. Contact structure 226b extends through conductive layer 236a, and contact structure 228b extends through conductive layer 238a. Contact structures 226b and 228b are respectively connected to conductive layers 236b and 238b of memory die 204b. Contact structures 226c and 228c extend through memory die 204a (including substrate 220a), bonding layer 221a, memory die 204b (including substrate 220b), and bonding layer 221b and into memory die 204c without extending through bonding layer 221c. Contact structure 226c extends through conductive layers 236a-236b, and contact structure 228c extends through conductive layers 238a-238b. Contact structures 226c and 228c are respectively connected to conductive layers 236c and 238c of memory die 204c. Contact structures 226d and 228d extend through memory die 204a (including substrate 220a), bonding layer 221a, memory die 204b (including substrate 220b), bonding layer 221b, memory die 204c (including substrate 220c), and bonding layer 221c and into memory die 204d without extending through memory die 204d. Contact structure 226d extends through conductive layers 236a-236c, and contact structure 228d extends through conductive layers 238a-238c. Contact structures 226d and 228d are respectively connected to conductive layers 236d and 238d of memory die 204d.

In some implementations, for each contact structure of contact structures 226a-226d and 228a-228d, the outer layer of the contact structure is between the inner layer of the contact structure and conductive layers that the contact structure extends through. The outer layer can insulate the inner layer from the conductive layers that the contact structure extends through.

While FIGS. 2A-2E and some other figures in the present disclosure show examples in which contact structures are coupled to stacked memory dice, any other suitable semiconductor devices or dice can also be stacked and coupled to contact structures using similar techniques. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

FIG. 3A illustrates a side view of a semiconductor device 300a, according to some aspects of the present disclosure. The semiconductor device 300a includes memory dice 302a-308a, a base die 344a, a computing die 346a, and an interposer 348a stacked (e.g., sequentially) along the vertical direction (e.g., the Z direction). Memory dice 302a-308a can be examples of memory dice 102 of FIG. 1 and memory dice 204a-204d of FIG. 2A (e.g., DRAMs). The stack of memory dice 302a-308a includes a device area 301a and a connection area 303a adjacent to each other along the horizontal direction (e.g., the X direction). Memory dice 302a-308a include conductive layers 310a-316a extending along the horizontal direction (e.g., the X direction), respectively. Each of conductive layers 310a-316a has one end coupled to a memory array or a peripheral circuit in a corresponding memory die in device area 301a and another end (e.g., ends 318a-324a) extending away from device area 301a. Each of conductive layers 310a-316a can be coupled to input/output ports of the corresponding memory die, or can be configured to provide one or more of power supplies, clock signals, or data path signals to the corresponding memory die.

As shown in FIG. 3A, the semiconductor device 300a includes contact structures 326a-332a in connection area 303a. Contact structures 326a-332a can be examples of contact structures 210 of FIGS. 2A-2B. The semiconductor device 300a further includes bonding layers (e.g., bonding layers 334a, 336a, and 338a) between adjacent memory dice of memory dice 302a-308a, a bonding layer 340a between memory die 302a and base die 344a, and a bonding layer 342a between base die 344a and computing die 346a. Each of these bonding layers can include a dielectric material such as silicon oxide.

Contact structures 326a-332a extend along the vertical direction (e.g., the Z direction) and are coupled to conductive layers 310a-316a, respectively. Contact structure 326a extends into memory die 302a and is connected to conductive layer 310a of memory die 302a without extending through bonding layer 334a. Contact structure 328a extends through memory die 302a and bonding layer 334a into memory die 304a without extending through bonding layer 336a. Contact structure 328a is connected to conductive layer 312a of memory die 304a without extending through conductive layer 310a. Contact structure 330a extends through memory dice 302a-304a, bonding layers 334a and 336a into memory die 306a without extending through bonding layer 338a. Contact structure 330a is connected to conductive layer 314a of memory die 306a without extending through conductive layers 310a and 312a. Contact structure 332a extends through memory dice 302a-306a and bonding layers 334a-338a into memory die 308a without extending through memory die 308a. Contact structure 332a is connected to conductive layer 316a of memory die 308a without extending through conductive layers 310a-314a.

The conductive layers 310a-316a can form a stepped structure to allow each of contact structures 326a-332a to connect to one of conductive layers 310a-316a without extending through other conductive layers. In some implementations, as shown in FIG. 3A, conductive layers 310a-316a can have the same length and are offset along the X direction. In other words, the ends 318a-324a (e.g., the ends on the right side) of conductive layers 310a-316a can be offset along the X direction. Specifically, contact structure 328a is between end 318a of conductive layer 310a and end 320a of conductive layer 312a along the X direction. That is, end 318a of conductive layer 310a is between contact structure 326a and contact structure 328a along the X direction. This way, contact structure 328a can extend through memory die 302a and bypass conductive layer 310a of memory die 302a. Similarly, contact structure 330a is between end 320a of conductive layer 312a and end 322a of conductive layer 314a along the X direction, so that contact structure 330a can extend through memory dice 302a-304a and bypass conducive layers 310a-312a. In addition, contact structure 332a is between end 322a of conductive layer 314a and end 324a of conductive layer 316a along the X direction, so that contact structure 332a can extend through memory dice 302a-306a and bypass conducive layers 310a-314a. It is understood that the example stepped structure formed by the conductive layers 310a-316a as shown in FIG. 3A is for illustration purpose and is not intended to be construed in a limiting sense. FIG. 3H illustrates a difference structure formed by conductive layers of a semiconductor device 300h, which can also allow each contact structure of semiconductor device 300h to connect to one of the conductive layers of semiconductor device 300h without extending through other conductive layers.

In some implementations, bonding layers 334a, 336a, and 338a can be referred to as direct bonding layers since they are formed through direct dielectric-dielectric bonding. Each of bonding layers 334a, 336a, and 338a can include at least one dielectric material and exclude a conductive bonding contact. In some implementations, bonding layers 340a and 342a can be referred to as hybrid bonding layers since they can be formed through hybrid dielectric-dielectric bonding and metal-metal bonding. Each of bonding layers 340a and 342a can include bonding contacts (e.g., conductive bonding contacts) and at least one dielectric material isolating the bonding contacts. As shown in FIG. 3A, bonding layer 340a includes conductive bonding contacts 354a. Conductive bonding contacts 354a can be configured to connect memory die 302a and base die 344a. In some implementations, memory die 302a can include an interconnect layer (not shown in FIG. 3A) in contact with bonding layer 340a. The interconnect layer of memory die 302a has a structure similar to that of interconnect layer 345f described in FIG. 3F. Each of contact structures 326a-332a can be coupled to the interconnect layer of memory die 302a. The interconnect layer of memory die 302a can be coupled to base die 344a through conductive bonding contacts 354a in bonding layer 340a. Base die 344a includes vias 350a extending through base die 344a along the Z direction and being connected to conductive bonding contacts 354a. Each of the contact structures 326a-332a is coupled to a respective one of the vias 350a through a corresponding conductive bonding contact 354a. Bonding layer 342a includes conductive bonding contacts 356a. Conductive bonding contacts 356a can be configured to connect base die 344a and computing die 346a. Computing die 346a can be an example of computing die 108 of FIG. 1. Computing die 346a includes vias 352a extending through computing die 346a along the Z direction and being connected to conductive bonding contacts 356a. Each via 350a is coupled to a respective via 352a through a corresponding conductive bonding contact 356a. In some implementations, vias 350a and 352a can be through-silicon vias (TSVs). Structures of bonding layers 334a, 336a, 338a, 340a, and 342a are described later with further details with respect to FIGS. 3B and 3C.

In some implementations, base die 344a includes a control circuitry that is configured to control memory dice 302a-308a. The control circuitry can be coupled to memory dice 302a-308a, for example, through contact structures 326a-332a, the interconnect layer of memory die 302a, and conductive bonding contacts 354a.

The interposer 348a has a surface 358a and a surface 360a. The surface 358a can be bonded to the computing die 346a. Conductive terminals 362a can be connected to the surface 360a. The interposer 348a can include interconnection lines that connect vias 352a of computing device 346a to the conductive terminals 362a. The conductive terminals 362a can be coupled to an external device (e.g., external host die 112 of FIG. 1). In some implementations, the conductive terminals 362a can be micro bumps.

In some implementations, as shown in FIG. 3A, memory dice 302a-306a can have a reduced thickness (along the Z direction) by having their substrates thinned. The topmost memory die 308a (e.g., the one among memory dice 302a-308a that is farthest away from base die 344a) may not be thinned. As a result, a thickness of each of memory dice 302a-306a can be smaller than a thickness of memory die 308a. The thickness of each of memory dice 302a-308a can be in any suitable range (e.g., between 3 μm and 20 μm).

FIG. 3B illustrates a diagram 300b showing an enlarged view of bonding layer 334a of FIG. 3A, according to some aspects of the present disclosure. Bonding layer 334a can include a top bonding layer 333b and a bottom bonding layer 337b bonded at a bonding interface 335b. Each of the top bonding layer 333b and the bottom bonding layer 337b can include a dielectric material (including, but not limited to, silicon oxide, silicon nitride, silicon oxynitride, low-k dielectrics, or any combination thereof) and can exclude a conductive bonding contact. Memory die 304a can be bonded on top of memory die 302a in a face-to-face manner through bonding layer 334a. Bonding interface 335b is disposed between the top bonding layer 333b and the bottom bonding layer 337b as a result of direct bonding (e.g., dielectric-dielectric bonding), which forms bonding between surfaces without using intermediate layers, such as solder or adhesives. In some implementations, for example, when the dielectric material of the top bonding layer 333b and the dielectric material of the bottom bonding layer 337b are different materials, bonding interface 335b can be a visible layer with a certain thickness that includes a top surface of the bottom bonding layer 337b and a bottom surface of the top bonding layer 333b. In some implementations, for example, when the dielectric material of the top bonding layer 333b and the dielectric material of the bottom bonding layer 337b are the same material, bonding interface 335b may not be visible and may form a continuous part with the top bonding layer 333b and the bottom bonding layer 337b. Bonding layers 336a and 338a of FIG. 3A can have structures similar to that of bonding layer 334a as described in FIG. 3B.

FIG. 3C illustrates a diagram 300c showing an enlarged view of bonding layer 340a of FIG. 3A, according to some aspects of the present disclosure. Bonding layer 340a can include a top bonding layer 343c and a bottom bonding layer 347c bonded at a bonding interface 345c. The top bonding layer 343c includes conductive bonding contacts 341c and a dielectric material 339c isolating conductive bonding contacts 341c. Conductive bonding contacts 341c can include conductive materials including, but not limited to, silicon oxide, silicon nitride, silicon oxynitride, low-k dielectrics, or any combination thereof. Dielectric material 339c can include dielectrics including, but not limited to, silicon oxide, silicon nitride, silicon oxynitride, low-k dielectrics, or any combination thereof. Similarly, the bottom bonding layer 347c includes conductive bonding contacts 349c and a dielectric material 351c isolating conductive bonding contacts 349c. Conductive bonding contacts 349c can include conductive materials including, but not limited to, silicon oxide, silicon nitride, silicon oxynitride, low-k dielectrics, or any combination thereof. Dielectric material 351c can include dielectrics including, but not limited to, silicon oxide, silicon nitride, silicon oxynitride, low-k dielectrics, or any combination thereof.

Conductive bonding contacts 341c and 349c can be examples of conductive bonding contacts 354a of FIG. 3A. Conductive bonding contacts 341c are in contact with conductive bonding contacts 349c at bonding interface 345c. Memory die 302a can be bonded on top of base die 344a in a face-to-face manner through bonding layer 340a. Bonding interface 345c is disposed between the top bonding layer 343c and the bottom bonding layer 347c as a result of hybrid bonding (e.g., metal-metal/dielectric-dielectric bonding). The hybrid bonding forms bonding between surfaces without using intermediate layers, such as solder or adhesives and can obtain metal-metal bonding and dielectric-dielectric bonding simultaneously. In some implementations, for example, when the dielectric material 339c of the top bonding layer 343c and the dielectric material 351c of the bottom bonding layer 347c are different materials, bonding interface 345c can be a visible layer with a certain thickness that includes a top surface of the bottom bonding layer 347c and a bottom surface of the top bonding layer 343c. In some implementations, for example, when the dielectric material 339c and the dielectric material 351c are the same material, bonding interface 345c may not be visible and may form a continuous part with the top bonding layer 343c and the bottom bonding layer 347c. Bonding layer 342a of FIG. 3A can have a structure similar to that of bonding layer 340a as described in FIG. 3C.

FIG. 3D illustrates a side view of a semiconductor device 300d, according to some aspects of the present disclosure. The semiconductor device 300d includes memory dice 302d-308d, a base die 344d, a computing die 346d, and an interposer 348d. Memory dice 302d-308d and base die 344d are stacked (e.g., sequentially) along the Z direction. Base die 344d and computing die 346d are integrated on different positions of the interposer 348d along the X direction. Memory dice 302d-308d are similar to memory dice 302a-308a of FIG. 3A. Memory dice 302d-308d can be examples of memory dice 102 of FIG. 1 and memory dice 204a-204d of FIG. 2A (e.g., DRAMs). The stack of memory dice 302d-308d includes a device area 301d and a connection area 303d adjacent to device area 301d along the horizontal direction (e.g., the X direction). Memory dice 302d-308d include conductive layers 310d-316d extending along the horizontal direction (e.g., the X direction), respectively. Each of conductive layers 310d-316d has one end coupled to a memory array or a peripheral circuit in a corresponding memory die in device area 301d and another end (e.g., ends 318d-324d) extending away from device area 301d. Each of conductive layers 310d-316d can be coupled to input/output ports of the corresponding memory die, or can be configured to provide one or more of power supplies, clock signals, or data path signals to the corresponding memory die.

As shown in FIG. 3D, the semiconductor device 300d includes contact structures 326d-332d in connection area 303d. Contact structures 326d-332d can be examples of contact structures 210 of FIGS. 2A-2B. The semiconductor device 300d further includes bonding layers (e.g., bonding layers 334d, 336d, and 338d) between adjacent memory dice of memory dice 302d-308d and a bonding layer 340d between memory die 302d and base die 344d. Each of these bonding layers can include a dielectric material such as silicon oxide.

Contact structures 326d-332d extend along the vertical direction (e.g., the Z direction) and are coupled to conductive layers 310d-316d, respectively. Contact structure 326d extends into memory die 302d and is connected to conductive layer 310d of memory die 302d without extending through bonding layer 334d. Contact structure 328d extends through memory die 302d and bonding layer 334d into memory die 304d without extending through bonding layer 336d. Contact structure 328d is connected to conductive layer 312d of memory die 304d without extending through conductive layer 310d. Contact structure 330d extends through memory die 302d-304d and bonding layers 334d and 336d into memory die 306d without extending through bonding layer 338d. Contact structure 330d is connected to conductive layer 314d of memory die 306d without extending through conductive layers 310d and 312d. Contact structure 332d extends through memory dice 302d-306d into memory die 308d without extending through memory die 308d. Contact structure 332d is connected to conductive layer 316d of memory die 308d without extending through conductive layers 310d-314d.

The conductive layers 310d-316d can form a stepped structure to allow each of contact structures 326d-332d to connect to one of conductive layers 310d-316d without extending through other conductive layers. In some implementations, as shown in FIG. 3D, conductive layers 310d-316d can have the same length and are offset along the X direction. In other words, the ends 318d-324d (e.g., the ends on the right side) of conductive layers 310d-316d can be offset along the X direction. Specifically, contact structure 328d is between end 318d of conductive layer 310d and end 320d of conductive layer 312d along the X direction. That is, end 318d of conductive layer 310d is between contact structure 326d and contact structure 328d along the X direction. This way, contact structure 328d can extend through memory die 302d and bypass conductive layer 310d of memory die 302d. Similarly, contact structure 330d is between end 320d of conductive layer 312d and end 322d of conductive layer 314d along the X direction, so that contact structure 330d can extend through memory dice 302d-304d and bypass conducive layers 310d-312d. In addition, contact structure 332d is between end 322d of conductive layer 314d and end 324d of conductive layer 316d along the X direction, so that contact structure 332d can extend through memory dice 302d-306d and bypass conducive layers 310d-314d.

In some implementations, bonding layers 334d, 336d, and 338d can be referred to as direct bonding layers and can have structures similar to that of bonding layer 334a described in FIG. 3B. Each of bonding layers 334d, 336d, and 338d can include at least one dielectric material and exclude a conductive bonding contact. In some implementations, bonding layer 340d can be referred to as a hybrid bonding layer and can have a structure similar to that of bonding layer 340a described in FIG. 3C. Bonding layer 340d can include bonding contacts (e.g., conductive bonding contacts 354d as shown in FIG. 3D) and at least one dielectric material isolating the bonding contacts. Conductive bonding contacts 354d can be configured to connect memory die 302d and base die 344d. In some implementations, memory die 302d can include an interconnect layer (not shown in FIG. 3D) in contact with bonding layer 340d. The interconnect layer of memory die 302d has a structure similar to that of interconnect layer 345f described in FIG. 3F. Each of contact structures 326d-332d can be coupled to the interconnect layer of memory die 302d. The interconnect layer of memory die 302d can be coupled to base die 344d through conductive bonding contacts 354d in bonding layer 340d. Base die 344d includes vias 350d extending through base die 344d along the Z direction and being connected to conductive bonding contacts 354d. Each of the contact structures 326d-332d is coupled to a respective one of the vias 350d through a corresponding conductive bonding contact 354d. In some implementations, vias 350d can be TSVs.

In some implementations, base die 344d includes a control circuitry that is configured to control memory dice 302d-308d. The control circuitry can be coupled to memory dice 302d-308d, for example, through contact structures 326d-332d, the interconnect layer of memory die 302d, and conductive bonding contacts 354d.

The base die 344d can be coupled to the computing die 346d through the interposer 348d. The interposer 348d has a surface 358d and a surface 360d. The vias 350d in the base die 344d can be connected to conductive terminals 364d on surface 358d of the interposer 348d. The computing die 346d can be connected to conductive terminals 366d on surface of 358d the interposer 348d. The semiconductor device 300d can include conductive terminals 362d connected to the surface 360d of the interposer 348d. Conductive terminals 364d, 366d, and 362d can be coupled through conductive lines (e.g., conductive lines 369d as shown in FIG. 3D) in the interposer 348d. The conductive terminals 362d can be coupled to an external device (e.g., the external host die 112 of FIG. 1). In some implementations, the conductive terminals 364d, 366d, and 362d can be micro bumps. It is understood that in practice, base die 344d, computing die 346d, and interposer 348d can be integrated together using any suitable packaging technology including, for example, Chip-on-Wafer-on-Substrate (CoWoS).

In some implementations, as shown in FIG. 3D, memory dice 302d-306d can have a reduced thickness (along the Z direction) by having their substrates thinned. The topmost memory die 308d (e.g., the one among memory dice 302d-308d that is farthest away from base die 344d) may not be thinned. As a result, a thickness of each of memory dice 302d-306d can be smaller than a thickness of memory die 308d. The thickness of each of memory dice 302d-308d can be in any suitable range (e.g., between 3 μm and 20 μm).

FIG. 3E illustrates a side view of a semiconductor device 300e, according to some aspects of the present disclosure. The semiconductor device 300e includes memory dice 302e-308e, a base die 344c, a computing die 346e, and an interposer 348e stacked (e.g., sequentially) along the vertical direction (e.g., the Z direction). Memory dice 302e-308e are similar to memory dice 302a-308a of FIG. 3A. Memory dice 302e-308e can be examples of memory dice 102 of FIG. 1 and memory dice 204a-204d of FIG. 2A (e.g., DRAMs). The stack of memory dice 302e-308e includes a device area 301e and a connection area 303e adjacent to device area 301e along the horizontal direction (e.g., the X direction). Memory dice 302e-308e include conductive layers 310e-316c extending along the horizontal direction (e.g., the X direction), respectively. Each of conductive layers 310e-316e has one end coupled to a memory array or a peripheral circuit in a corresponding memory die in device area 301e and another end (e.g., ends 318e-324e) extending away from device area 301c. Each of conductive layers 310e-316e can be coupled to input/output ports of the corresponding memory die, or can be configured to provide one or more of power supplies, clock signals, or data path signals to the corresponding memory die.

As shown in FIG. 3E, the semiconductor device 300e includes contact structures 326c-332e in connection area 303c. Contact structures 326e-332e can be examples of contact structures 210 of FIGS. 2A-2B. The semiconductor device 300e further includes bonding layers (e.g., bonding layers 334c, 336e, and 338c) between adjacent memory dice of memory dice 302e-308c and a bonding layer 340e between memory die 302e and base die 344c. Each of these bonding layers can include a dielectric material silicon oxide. Base die 344e includes a surface 365e and another surface 367e. Surface 365e is bonded to memory die 302e through bonding layer 340c. Base die 344c further includes a conductive layer 368e and a contact structure 370e connected to the conductive layer 368e. Contact structure 370e extends along the Z direction into base die 344c. Conductive layer 368e includes an end 372e coupled to a circuit of base die 344e and another end 374c closer to the contact structure 370c. In some implementations, bonding layers 334c, 336c, 338c, and 340e can be referred to as direct bonding layers and can have structures similar to that of bonding layer 334a described in FIG. 3B. Each of bonding layers 334c, 336e, 338c, and 340c can include at least one dielectric material and exclude a conductive bonding contact. In some implementations, bonding layer 342e can be referred to as a hybrid bonding layer and can have a structure similar to that of bonding layer 340a described in FIG. 3C. Bonding layer 342e can include bonding contacts (e.g., conductive bonding contacts 356e as shown in FIG. 3E) and at least one dielectric material isolating the bonding contacts.

Contact structures 370e and 326e-332e extend along the vertical direction (e.g., the Z direction) and are coupled to conductive layers 368e and 310e-316e, respectively. Specifically, contact structure 370e extends into base die 344c without extending through bonding layer 340c. Contact structure 326e extends through bonding layer 340e into memory die 302e without extending through bonding layer 334c. Contact structure 326e is connected to conductive layer 310e of memory die 302e without extending through conductive layer 368c. Contact structure 328e extends through memory die 302e and bonding layers 340e and 334e into memory die 304c without extending through bonding layer 336e. Contact structure 328e is connected to conductive layer 312e of memory die 304c without extending through conductive layers 368e and 310c. Contact structure 330e extends through memory die 302e-304e and bonding layers 340c, 334c, and 336e and into memory die 306e without extending through bonding layer 338c. Contact structure 330e is connected to conductive layer 314e of memory die 306e without extending through conductive layers 368c, 310c, and 312e. Contact structure 332e extends through memory dice 302e-306c and bonding layers 340c, 334c, 336c, and 338e and into memory die 308e without extending through memory die 308c. Contact structure 332e is connected to conductive layer 316e of memory die 308e without extending through conductive layers 368c, 310c, 312e, and 314c.

The conductive layers 368e and 310e-316e can form a stepped structure to allow each of contact structures 370e and 326e-332e to connect to one of conductive layers 368e and 310e-316c without extending through other conductive layers. In some implementations, as shown in FIG. 3E, conductive layers 368e and 310e-316e are offset along the X direction. In some implementations, conductive layers 310c-316e can have the same length. Specifically, the ends 374c and 318c-324e (e.g., the ends on the right side) of conductive layers 368e and 310e-316e can be offset along the X direction. Contact structure 326e is between end 374e of conductive layer 368c and end 318e of conductive layer 310e along the X direction. That is, end 374e of conductive layer 368e is between contact structure 370e and contact structure 326e along the X direction. This way, contact structure 326e can extend through base die 344e and bypass conducive layer 368e of base die 344c. Contact structure 328e is between end 318e of conductive layer 310e and end 320c of conductive layer 312e along the X direction. That is, end 318e of conductive layer 310c is between contact structure 326e and contact structure 328e along the X direction. This way, contact structure 328e can extend through memory die 302e and bypass conductive layer 310e of memory die 302e. Similarly, contact structure 330e is between end 320e of conductive layer 312e and end 322e of conductive layer 314e along the X direction, so that contact structure 330e can extend through memory dice 302e-304e and bypass conducive layers 310e-312e. In addition, contact structure 332e is between end 322e of conductive layer 314e and end 324e of conductive layer 316c along the X direction, so that contact structure 332e can extend through memory dice 302c-306e and bypass conducive layers 310c-314c.

Base die 344e can include an interconnect layer (not shown in FIG. 3E) in contact with bonding layer 342c. Each of contact structures 326e-332e and 370e can be coupled to the interconnect layer of base die 344c. An example of the interconnect layer of base die 344c is described later with further details with respect to FIG. 3F. The interconnect layer of base die 344c can be coupled to computing die 346e through conductive bonding contacts 356e in bonding layer 342c. Conductive bonding contacts 356e can be configured to couple base die 344c and memory dice 302e-308e to computing die 346c. Computing die 346e can be an example of computing die 108 of FIG. 1. Computing die 346e includes vias 352e extending through computing die 346c along the Z direction and being connected to conductive bonding contacts 356e. Each of the contact structures 370e and 326e-332e can be coupled to a respective one of the vias 352e through the interconnect layer of base die 344e and a corresponding conductive bonding contact 356c. In some implementations, vias 352e can be TSVs.

In some implementations, base die 344e includes a control circuitry that is configured to control memory dice 302e-308c. The control circuitry can be coupled to memory dice 302e-308c, for example, through contact structures 370e and 326e-332e, the interconnect layer of base die 344c, and conductive bonding contacts 356c.

The interposer 348e has a surface 358e and a surface 360e. The surface 358e can be bonded to the computing die 346e. Conductive terminals 362e can be connected to the surface 360c. The interposer 348e can include interconnection lines that connect vias 352e of computing die 346c to the conductive terminals 362c. The conductive terminals 362e can be coupled to an external device (e.g., the external host die 112 of FIG. 1). In some implementations, the conductive terminals 362e can be micro bumps.

In some implementations, as shown in FIG. 3E, memory dice 302e-306e can have a reduced thickness (along the Z direction) by having their substrates thinned. The topmost memory die 308e (e.g., the one among memory dice 302e-308e that is farthest away from base die 344c) may not be thinned. As a result, a thickness of each of memory dice 302e-306e can be smaller than a thickness of memory die 308c. The thickness of each of memory dice 302e-308e can be in any suitable range (e.g., between 3 μm and 20 μm).

FIG. 3F illustrates a diagram 300f showing an enlarged view of an interconnect layer 345f in base die 344c of FIG. 3E, according to some aspects of the present disclosure. The interconnect layer 345f is between contact structures 326e-332e and 370e and bonding layer 342e along the Z direction. The interconnect layer 345f can include interconnects (also referred to herein as “contacts”), including lateral interconnect lines 347f and vertical interconnect access (VIA) contacts (not shown). Contact structures 326e-332e and 370e and conductive bonding contacts 356e of bonding layer 342e can be coupled to the interconnects in the interconnect layer 345f. As used herein, the term “interconnects” can broadly include any suitable types of interconnects, such as middle-end-of-line (MEOL) interconnects and back-end-of-line (BEOL) interconnects. The interconnect layer 345f can further include one or more interlayer dielectric (ILD) layers (also known as “intermetal dielectric (IMD) layers”) in which the interconnect lines 347f and VIA contacts can form. That is, the interconnect layer 345f can include interconnect lines 347e and VIA contacts in multiple ILD layers. The interconnect lines 347f and VIA contacts in the interconnect layer 345f can include conductive materials including, but not limited to, tungsten (W), cobalt (Co), copper (Cu), aluminum (Al), silicides, or any combination thereof. The ILD layers in the interconnect layer 345f can include dielectric materials including, but not limited to, silicon oxide, silicon nitride, silicon oxynitride, low dielectric constant (low-k) dielectrics, or any combination thereof.

FIG. 3G illustrates a side view of a semiconductor device 300g, according to some aspects of the present disclosure. The semiconductor device 300g includes memory dice 302g-308g, a base die 344g, a computing die 346g, and an interposer 348g. Memory dice 302g-308g and base die 344g are stacked sequentially along the Z direction. Base die 344g and computing die 346g are integrated on different positions of the interposer 348g along the X direction. Memory dice 302g-308g are similar to memory dice 302a-308a of FIG. 3A. Memory dice 302g-308g can be examples of memory dice 102 of FIG. 1 and memory dice 204a-204d of FIG. 2A (e.g., DRAMs). The stack of memory devices 302g-308g includes a device area 301g and a connection area 303g adjacent to device area 301g along the horizontal direction (e.g., the X direction). Memory dice 302g-308g include conductive layers 310g-316g extending along the horizontal direction (e.g., the X direction), respectively. Each of conductive layers 310g-316g has one end coupled to a memory array or a peripheral circuit in a corresponding memory die in device area 301g and another end (e.g., ends 318g-324g) extending away from device area 301g. Each of conductive layers 310g-316g can be coupled to input/output ports of the corresponding memory die, or can be configured to provide one or more of power supplies, clock signals, or data path signals to the corresponding memory die.

As shown in FIG. 3G, the semiconductor device 300g includes contact structures 326g-332g in connection area 303g. Contact structures 326g-332g can be examples of contact structures 210 of FIGS. 2A-2B. The semiconductor device 300g further includes bonding layers (e.g., bonding layers 334g, 336g, and 338g) between adjacent memory dice of memory dice 302g-308g and a bonding layer 340g between memory die 302g and base die 344g. Each of these bonding layers can include silicon oxide. Base die 344g includes a surface 365g and another surface 367g. Surface 365g is bonded to memory die 302g through bonding layer 340g. Base die 344g further includes a conductive layer 368g and a contact structure 370g connected to the conductive layer 368g. Contact structure 370g extends along the Z direction into base die 344g. Conductive layer 368g includes an end 372g coupled to a circuit of base die 344g and another end 374g closer to the contact structure 370g. In some implementations, bonding layers 334g, 336g, 338g, and 340g can be referred to as direct bonding layers and can have structures similar to that of bonding layer 334a described in FIG. 3B. Each of bonding layers 334g, 336g, 338g, and 340g can include at least one dielectric material and exclude a conductive bonding contact.

Contact structures 370g and 326g-332g extend along the vertical direction (e.g., the Z direction) and are coupled to conductive layers 368g and 310g-316g, respectively. Specifically, contact structure 370g extends into base die 344g without extending through bonding layer 340g. Contact structure 326g extends through bonding layer 340g into memory die 302g without extending through bonding layer 334g. Contact structure 326g is connected to conductive layer 310g of memory die 302g without extending through conductive layer 368g. Contact structure 328g extends through memory die 302g and bonding layers 340g and 334g into memory die 304g without extending through bonding layer 336g. Contact structure 328g is connected to conductive layer 312g of memory die 304g without extending through conductive layers 368g and 310g. Contact structure 330g extends through memory die 302g-304g and bonding layers 340g, 334g, and 336g and into memory die 306g without extending through bonding layer 338g. Contact structure 330g is connected to conductive layer 314g of memory die 306g without extending through conductive layers 368g, 310g, and 312g. Contact structure 332g extends through memory dice 302g-306g and bonding layers 340g, 334g, 336g, and 338g and into memory die 308g without extending through memory die 308g. Contact structure 332g is connected to conductive layer 316g of memory die 308g without extending through conductive layers 368g, 310g, 312g, and 314g.

The conductive layers 368g and 310g-316g can form a stepped structure to allow each of contact structures 370g and 326g-332g to connect to one of conductive layers 368g and 310g-316g without extending through other conductive layers. In some implementations, as shown in FIG. 3G, conductive layers 368g and 310g-316g are offset along the X direction. In some implementations, conductive layers 310g-316g can have the same length. Specifically, the ends 374g and 318g-324g (e.g., the ends on the right side) of conductive layers 368g and 310g-316g can be offset along the X direction. Contact structure 326g is between end 374g of conductive layer 368g and end 318g of conductive layer 310g along the X direction. That is, end 374g of conductive layer 368g is between contact structure 370g and contact structure 326g along the X direction. This way, contact structure 326g can extend through base die 344g and bypass conducive layer 368g of base die 344g. Contact structure 328g is between end 318g of conductive layer 310g and end 320g of conductive layer 312g along the X direction. That is, end 318g of conductive layer 310g is between contact structure 326g and contact structure 328g along the X direction. This way, contact structure 328g can extend through memory die 302g and bypass conductive layer 310g of memory die 302g. Similarly, contact structure 330g is between end 320g of conductive layer 312g and end 322g of conductive layer 314g along the X direction, so that contact structure 330g can extend through memory dice 302g-304g and bypass conducive layers 310g-312g. In addition, contact structure 332g is between end 322g of conductive layer 314g and end 324g of conductive layer 316g along the X direction, so that contact structure 332g can extend through memory dice 302g-306g and bypass conducive layers 310g-314g.

Base die 344g can include an interconnect layer (not shown in FIG. 3G). The interconnect layer of base die 344g has a structure similar to that of interconnect layer 345f described in FIG. 3F. Each of contact structures 326g-332g and 370g can be coupled to the interconnect layer of base die 344g. The base die 344g can be coupled to the computing die 346g through the interconnect layer and the interposer 348g. The interposer 348g has a surface 358g and a surface 360g. Interconnects in the interconnect layer of base die 344g can be connected to conductive terminals 364g on surface 358g of the interposer 348g. The computing die 346g can be connected to conductive terminals 366g on surface 358g of the interposer 348g. The semiconductor device 300g can include conductive terminals 362g connected to the surface 360g of the interposer 348g. Conductive terminals 364g, 366g, and 362g can be coupled through conductive lines (e.g., conductive lines 369g as shown in FIG. 3G) in the interposer 348g. The conductive terminals 362g can be coupled to an external device (e.g., the external host die 112 of FIG. 1). In some implementations, the conductive terminals 364g, 366g, and 362g can be micro bumps. It is understood that in practice, base die 344g, computing die 346g, and interposer 348g can be integrated together using any suitable packaging technology including, for example, Chip-on-Wafer-on-Substrate (CoWoS).

In some implementations, base die 344g includes a control circuitry that is configured to control memory dice 302g-308g. The control circuitry can be coupled to memory dice 302g-308g, for example, through contact structures 370g and 326g-332g and the interconnect layer of base die 344g.

In some implementations, as shown in FIG. 3G, memory dice 302g-306g can have a reduced thickness (along the Z direction) by having their substrates thinned. The topmost memory die 308g (e.g., the one among memory dice 302g-308g that is farthest away from base die 344g) may not be thinned. As a result, a thickness of each of memory dice 302g-306g can be smaller than a thickness of memory die 308g. The thickness of each of memory dice 302g-308g can be in any suitable range (e.g., between 3 μm and 20 μm).

FIG. 3H illustrates a side view of a semiconductor device 300h, according to some aspects of the present disclosure. The semiconductor device 300h includes memory dice 302h-308h, a base die 344h, a computing die 346h, and an interposer 348h. Memory dice 302h-308h and base die 344h are stacked sequentially along the Z direction. Base die 344h and computing die 346h are integrated on different positions of the interposer 348h along the X direction. Memory dice 302h-308h are similar to memory dice 302a-308a of FIG. 3A. Memory dice 302h-308h can be examples of memory dice 102 of FIG. 1 and memory dice 204a-204d of FIG. 2A (e.g., DRAMs). The stack of memory devices 302h-308h includes a device area 301h and a connection area 303h adjacent to device area 301h along the horizontal direction (e.g., the X direction). Memory dice 302h-308h include conductive layers 310h-316h extending along the horizontal direction (e.g., the X direction), respectively. Each of conductive layers 310h-316h can be coupled (e.g., through one of its ends) to a memory array or a peripheral circuit in a corresponding memory die in device area 301h. In some implementations, each of conductive layers 310h-316h can be coupled to input/output ports of the corresponding memory die, or can be configured to provide one or more of power supplies, clock signals, or data path signals to the corresponding memory die.

As shown in FIG. 3H, the semiconductor device 300h includes contact structures 326h-332h in connection area 303h. Contact structures 326h-332h can be examples of contact structures 210 of FIGS. 2A-2B. The semiconductor device 300h further includes bonding layers (e.g., bonding layers 334h, 336h, and 338h) between adjacent memory dice of memory dice 302h-308h and a bonding layer 340h between memory die 302h and base die 344h. Each of these bonding layers can include silicon oxide. Base die 344h includes a surface 365h and another surface 367h. Surface 365h is bonded to memory die 302h through bonding layer 340h. Base die 344h further includes a conductive layer 368h and a contact structure 370h connected to the conductive layer 368h. Contact structure 370h extends along the Z direction into base die 344h. Conductive layer 368h includes an end 372h coupled to a circuit of base die 344h and another end 374h closer to the contact structure 370h. In some implementations, bonding layers 334h, 336h, 338h, and 340h can be referred to as direct bonding layers and can have structures similar to that of bonding layer 334a described in FIG. 3B. Each of bonding layers 334h, 336h, 338h, and 340h can include at least one dielectric material and exclude a conductive bonding contact.

Contact structures 370h and 326h-332h extend along the vertical direction (e.g., the Z direction) and are coupled to conductive layers 368h and 310h-316h, respectively. Specifically, contact structure 370h extends into base die 344h without extending through bonding layer 340h. Contact structure 326h extends through memory die 302h and bonding layers 340h and 334h into memory die 304h without extending through bonding layer 336h. Contact structure 326h is connected to conductive layer 312h of memory die 304h without extending through conductive layers 310h, 314h, 316h, and 368h. Contact structure 328h extends through memory dice 302h-306h and bonding layers 340h, 334h, 336h, and 338h and into memory die 308h without extending through memory die 308h. Contact structure 328h is connected to conductive layer 316h of memory die 308h without extending through conductive layers 310h, 312h, 314h, and 368h. Contact structure 330h extends through memory die 302h-304h and bonding layers 340h, 334h, and 336h and into memory die 306h without extending through bonding layer 338h. Contact structure 330h is connected to conductive layer 314h of memory die 306h without extending through conductive layers 310h, 312h, 316h, and 368h. Contact structure 332h extends through bonding layer 340h into memory die 302h without extending through bonding layer 334h. Contact structure 332h is connected to conductive layer 310h of memory die 302h without extending through conductive layers 312h, 314h, 316h, and 368h.

As shown in FIG. 3H, while the conductive layers 368h and 310h-316h forms a structure different from the stepped structures in some other figures (e.g., FIGS. 3A, 3D, 3E, and 3G), each of contact structures 370h and 326h-332h can still connect to one of conductive layers 368h and 310h-316h without extending through other conductive layers. In some implementations, as shown in FIG. 3H, conductive layers 368h and 310h-316h are offset along the X direction. In some implementations, conductive layers 310h-316h can have the same length and have their ends offset along the X direction. Specifically, contact structure 326h is between end 374h of conductive layer 368h and end 318h of conductive layer 312h along the X direction. Contact structure 328h is between end 318h of conductive layer 312h and end 320h of conductive layer 314h along the X direction. Contact structure 330h is between end 320h of conductive layer 314h and end 322h of conductive layer 310h along the X direction. End 322h is between contact structure 330h and contact structure 332h along the X direction.

Base die 344h can include an interconnect layer (not shown in FIG. 3H). The interconnect layer of base die 344h has a structure similar to that of interconnect layer 345f described in FIG. 3F. Each of contact structures 326h-332h and 370h can be coupled to the interconnect layer of base die 344h. The base die 344h can be coupled to the computing die 346h through the interconnect layer and the interposer 348h. The interposer 348h has a surface 358h and a surface 360h. Interconnects in the interconnect layer of base die 344h can be connected to conductive terminals 364h on surface 358h of the interposer 348h. The computing die 346h can be connected to conductive terminals 366h on surface 358h of the interposer 348h. The semiconductor device 300h can include conductive terminals 362h connected to the surface 360h of the interposer 348h. Conductive terminals 364h, 366h, and 362h can be coupled through conductive lines (e.g., conductive lines 369h as shown in FIG. 3H) in the interposer 348h. The conductive terminals 362h can be coupled to an external device (e.g., the external host die 112 of FIG. 1). In some implementations, the conductive terminals 364h, 366h, and 362h can be micro bumps. It is understood that in practice, base die 344h, computing die 346h, and interposer 348h can be integrated together using any suitable packaging technology including, for example, Chip-on-Wafer-on-Substrate (CoWoS).

In some implementations, base die 344h includes a control circuitry that is configured to control memory dice 302h-308h. The control circuitry can be coupled to memory dice 302h-308h, for example, through contact structures 370h and 326h-332h and the interconnect layer of base die 344h.

In some implementations, as shown in FIG. 3H, memory dice 302h-306h can have a reduced thickness (along the Z direction) by having their substrates thinned. The topmost memory die 308h (e.g., the one among memory dice 302h-308h that is farthest away from base die 344h) may not be thinned. As a result, a thickness of each of memory dice 302h-306h can be smaller than a thickness of memory die 308h. The thickness of each of memory dice 302h-308h can be in any suitable range (e.g., between 3 μm and 20 μm).

FIGS. 4A-4J show an example process of manufacturing a semiconductor device, according to some aspects of the present disclosure. In some implementations, the process described herein can be used to manufacture any suitable semiconductor device, such as semiconductor device 200, 300a, or 300d.

FIG. 4A illustrates that the process can start with providing semiconductor structures 400 and 402 both extending along the horizontal direction (e.g., the X direction). Semiconductor structure 400 can be a carrier wafer. Semiconductor structure 402 can be a semiconductor device or a semiconductor die (e.g., memory die 204a of FIG. 2C or memory die 302a of FIG. 3A) that includes a conductive layer 410 (e.g., conductive layer 310a of FIG. 3A). Semiconductor structure 402 can be stacked on semiconductor structure 400 along the vertical direction (e.g., the Z direction) and bonded to semiconductor structure 400 through a bonding layer 401. Semiconductor structures 400 and 402 can be bonded using any suitable bonding technology (e.g., a direct bonding technology). For example, a first dielectric layer (e.g., silicon oxide) can be deposited on surface 403 of semiconductor structure 400, and a second dielectric layer (e.g., silicon oxide) can be deposited on surface 405 of semiconductor structure 402. By applying pressure and heat, the first dielectric layer and the second dielectric layer can be bonded together to form bonding layer 401 between semiconductor structures 400 and 402. Semiconductor structure 400 can serve as a support to semiconductor structure 402. Semiconductor structures 400 and 402 can have any suitable thicknesses along the Z direction. In some implementations, a thickness of semiconductor structure 402 can be in a range between 40 μm and 50 μm.

As shown in FIG. 4B, semiconductor structure 402 is thinned. Thinning semiconductor structure 402 includes removing a top portion (e.g., a portion farthest from semiconductor structure 400 along the Z direction) of semiconductor structure 402. For example, the thickness of semiconductor structure 402 can be reduced from about 40-50 μm to 3-20 μm by thinning. In some implementations, semiconductor structure 402 includes a substrate on its bottom and is flipped upside down before being bonded to semiconductor structure 400. That is, the substrate of the semiconductor structure 402 becomes the top of semiconductor structure 402 after the flip. Thus, a portion of the substrate of semiconductor structure 402 is removed by thinning the top portion of semiconductor structure 402. In some implementations, after being thinned, semiconductor structure 402 can still maintain its shape without producing substantial distortion or deformation due to the support provided by the semiconductor structure 400 (e.g., the carrier wafer).

As shown in FIG. 4C, a semiconductor structure 404 is provided. Semiconductor structure 404 (e.g., memory die 304a of FIG. 3A) includes a conductive layer 412 (e.g., conductive layer 312a of FIG. 3A). In some implementations, semiconductor structure 404 includes a substrate in its top portion, which is similar to semiconductor structure 402 as described with respect to FIG. 4B. Semiconductor structure 404 can be aligned with semiconductor structure 402 to offset an end 420 of conductive layer 412 and an end 418 of conductive layer 410 along the X direction. By doing so, conductive layer 412 and conductive layer 410 can form a stepped structure (e.g., the stepped structures as described with respect to FIGS. 2C and 3A-3D) so that a contact structure formed in later steps can be connected to conductive layer 412 without extending through conductive layer 410. A dielectric layer can be deposited on a bottom surface of semiconductor structure 404, and a dielectric layer can be deposited on a top surface of semiconductor structure 402. Semiconductor structure 404 can be stacked on and bonded to semiconductor structure 402 along the Z direction, which is similar to the example in which semiconductor structure 402 and semiconductor structure 400 are bonded as described with respect to FIG. 4A.

As shown in FIG. 4D, the dielectric layer of the semiconductor structure 404 and the dielectric layer of the semiconductor structure 402 can form a bonding layer 407. Semiconductor structure 404 is thinned by removing a top portion (e.g., a portion of the substrate of semiconductor structure 404).

FIG. 4E illustrate that a semiconductor structure 406 (e.g., memory die 306a of FIG. 3A) including a conductive layer 414 (e.g., conductive layer 314a of FIG. 3A) and a semiconductor structure 408 (e.g., memory die 308a of FIG. 3A) including a conductive layer 416 (e.g., conductive layer 316a of FIG. 3A) are provided. Semiconductor structure 406 are aligned with, stacked on, and bonded to semiconductor structure 404 in a way similar to the examples described with respect to FIGS. 4A-4D. Semiconductor structure 406 also can be thinned. Similarly, semiconductor structure 408 are aligned with, stacked on, and bonded to semiconductor structure 406. In some implementations, semiconductor structure 408 is not thinned, thereby providing support because of its thickness when a stack of semiconductor structures 404-408 is flipped upside down in later steps. The conductive layers 410-416 can form a stepped structure as described with respect to FIGS. 2C, 3A, and 3D. In some implementations, conductive layers 410-416 can have various lengths. For example, as shown in FIG. 4E, conductive layers 410-416 can extend from substantially the same position (e.g., on the right side) in the X direction and extend by different lengths (e.g., towards the left side). In other words, the ends 418-424 of conductive layers 410-416 are offset along the X direction. In some implementations, semiconductor structures 404-408 are labeled based on positions and length of conductive layers 410-416. Semiconductor structures 404-408 can be stacked in a correct order based on their labels.

While in this example a semiconductor device can include four semiconductor structures 402-408 stacked together, the technology disclosed herein can be applied to stacking any suitable number of semiconductor structures (e.g., 2, 5, or 8). The number of semiconductor structures can be determined based on factors including technology constraints, thermal considerations, signal integrity and interferences, physical size and application, costs and yields, reliability concerns, etc. In those cases, the last semiconductor structure (rather than the fourth one as shown in FIG. 4E), which is farthest from semiconductor structure 400, can be thicker than the other semiconductor structures along the Z direction. For example, the last semiconductor structure is not thinned, and the other semiconductor structures are thinned. This way, the last semiconductor structure can provide support due to its thickness when the stacked structure is flipped upside down in later steps.

As shown in FIG. 4F, semiconductor structure 400 can be removed by a debonding process. The stack of semiconductor structures 402-408 is flipped upside down. As the thickest among semiconductor structures 402-408, semiconductor structure 408 is now on the bottom and supports the other semiconductor structures.

FIG. 4G illustrates that a mask layer 411 is formed on top of semiconductor structure 402. Openings 413, 415, 417, and 419 are formed in the mask layer 411. In some implementations, mask layer 411 includes a photoresist material, and openings 413, 415, 417, and 419 can be formed by etching the mask layer 411. Positions of the openings 413, 415, 417, and 419 can be determined such that a respective contact hole (e.g., contact holes 425, 427, 429, and 431 of FIG. 4H) extending along the Z direction can extend from one of the openings 413, 415, 417, and 419 to a corresponding one of conductive layers 410-416 without extending through others of conductive layers 410-416.

FIG. 4H illustrates that contact holes 425, 427, 429, and 431 extending along the Z direction into semiconductor structures 402-408 are formed. Contact hole 425 extends into semiconductor structure 402 and reaches conductive layer 410. Contact hole 427 extends through semiconductor structure 402 into semiconductor structure 404 and reaches conductive layer 412. Contact hole 429 extends through semiconductor structures 402 and 404 into semiconductor structure 406 and reaches conductive layer 414. Contact hole 431 extends through semiconductor structures 402, 404, and 406 into semiconductor structure 408 and reaches conductive layer 416. In some implementations, contact holes 425, 427, 429, and 431 can be formed by etching off one or more dielectric materials in semiconductor structures 402-408 from openings 413, 415, 417, and 419. The stepped structure formed by the conductive layers 410-416 allows each of the contact holes 425, 427, 429, and 431 to connect to one of the semiconductor structure 402-408 and bypass others of the semiconductor structure 402-408. Specifically, contact hole 427 is between end 418 of conductive layer 410 and end 420 of conductive layer 412, contact hole 429 is between end 420 of conductive layer 412 and end 422 of conductive layer 414, and contact hole 431 is between end 422 of conductive layer 414 and end 424 of conductive layer 416. The mask layer 411 can be removed using, for example, chemical mechanical planarization (CMP) after contact holes 425, 427, 429, and 431 are formed. In some implementations, contact holes 425, 427, 429, and 431 are formed during a same etching process.

FIG. 4I illustrates that contact structures 426, 428, 430, and 432 are formed in contact holes 425, 427, 429, and 431, respectively. Each of contact structures 426, 428, 430, and 432 can include an outer layer (e.g., outer layer 433) and an inner layer (e.g., inner layer 435) on an inner surface of the outer layer 433. The inner layer can include a conductive material (e.g., copper or tungsten) and can be referred to as a conductive structure. The outer layer can include an insulating material (a dielectric material such as silicon oxide) and can be referred to as an insulating layer. Contact structures 426, 428, 430, and 432 can be formed by first depositing the dielectric material into the contact holes 425, 427, 429, and 431 to form insulating layers on inner surfaces of the contact holes 425, 427, 429, and 431. After that, bottoms of the insulating layers can be etched off to expose the conductive layers 410, 412, 414, and 416 in the contact holes 425, 427, 429, and 431, respectively. Then, inner layers of the contact structures 426, 428, 430, and 432 can be formed by depositing the conductive material into the contact holes 425, 427, 429, and 431. In some implementations, after deposition, CMP can be used to polish away excess materials such as metal and dielectric, leaving a flat surface with metal in the contact holes.

FIG. 4J illustrates that a semiconductor structure 444 is stacked on and bonded to semiconductor structure 402. Semiconductor structure 444 can be a base die (e.g., base die 212 of FIG. 2A, base die 344a of FIG. 3A, or base die 344d of FIG. 3D). Semiconductor structure 444 includes vias 450 extending along the Z direction. Semiconductor structure 444 can be bonded to semiconductor structure 402 using any suitable bonding techniques. In some implementations, semiconductor structure 444 and semiconductor structure 402 can be bonded through conductive bonding contacts and dielectric materials. Specifically, a bonding layer 443 can be formed on a top surface of semiconductor structure 402. Bonding layer 443 can include conductive bonding contacts 442 and a dielectric material isolating the conductive bonding contacts 442. Contact structures 426, 428, 430, and 432 are connected to corresponding bonding contacts of conductive bonding contacts 442. In some implementations, an interconnect layer is formed in semiconductor structure 402 before bonding layer 443 is formed. The interconnect layer can be coupled to contact structures 426, 428, 430, and 432. A bonding layer 445 can be formed on a bottom surface of semiconductor structure 444. Bonding layer 445 can include conductive bonding contacts 446 and a dielectric material isolating the conductive bonding contacts 446. Conductive bonding contacts 446 are connected to the vias 450 of the semiconductor structure 444. Conductive bonding contacts 442 and conductive bonding contacts 446 can include the same conductive material such as metal (e.g., copper). Bonding layer 443 and bonding layer 445 can include the same dielectric material (e.g., silicon oxide). Semiconductor structure 444 is stacked on semiconductor structure 402 so that bonding layer 445 is in contact with bonding layer 443 and each conductive bonding contact 446 is in contact with a corresponding conductive bonding contact 442. By applying pressure and heat, bonding layer 445 is bonded to bonding layer 443.

In some implementations, the process described with respect to FIGS. 4A-4J can be modified to form a semiconductor device having contact structures that extend through the semiconductor structure 444 (e.g., the stack of memory dice and base die as described with respect to FIGS. 3E, 3G, and 3H). For example, before forming mask layer 411 on top of semiconductor structure 402 (as shown in FIG. 4G), semiconductor structure 444 can be stacked on and bonded to semiconductor structure 402 though a dielectric bonding layer. Then mask layer 411 can be formed on top of semiconductor structure 444. Thus, contact structures extending through the semiconductor structure 444 can be formed by etching the mask layer 411 to form openings, forming contact holes extending from the openings to conductive layers 410-416, and forming contact structures in the contact holes, which is similar to the process as described with respect to FIGS. 4G-41.

In some implementations, semiconductor structures 402, 404, 406, 408, and 444 can be fabricated separately such that a limitation (e.g., thermal budget) of fabricating one of them does not limit the processes of fabricating another. In some implementations, semiconductor structures 402, 404, 406, 408, and 444 can be fabricated in parallel.

In some implementations, each of semiconductor structures 402, 404, 406, 408, and 444 includes a semiconductor die (e.g., a memory die or a base die). Each semiconductor die can include a fully functional electronic circuit (e.g., a microprocessor, memory, sensor, or any other suitable type of integrated circuit) and can be encapsulated in a protective package.

In some implementations, each of semiconductor structures 402, 404, 406, 408, and 444 includes a semiconductor wafer. The semiconductor wafer can include multiple semiconductor devices or dies manufactured by depositing multiple layers of various materials and etching them onto the semiconductor wafer in intricate patterns defined by a chip design. The process as described with respect to FIGS. 4A-4J is performed at the wafer level and is applied to multiple semiconductor wafers to form a stack of semiconductor wafers bonded together. After the process is complete, the stack of semiconductor wafers is cut and diced into individual pieces. Each individual piece (which can also be referred to as a die) includes a fully functional electronic circuit, which can be a microprocessor, an HBM, a sensor, or any other suitable type of integrated circuit. In some embodiments, each individual piece is encapsulated in a protective package, providing physical support, protection from environmental factor, and connections (e.g., through pins or solder balls) to external devices or systems.

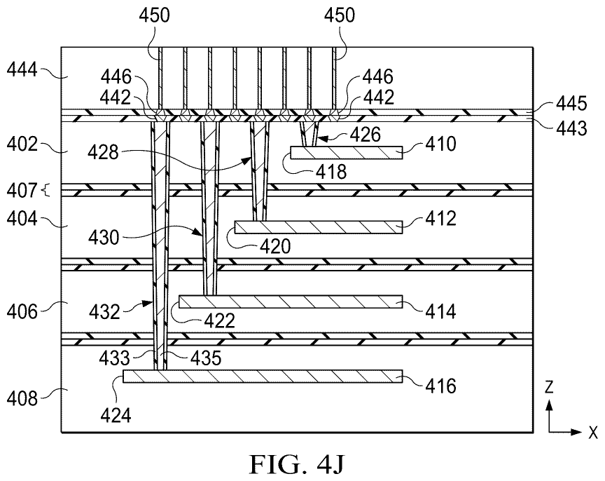

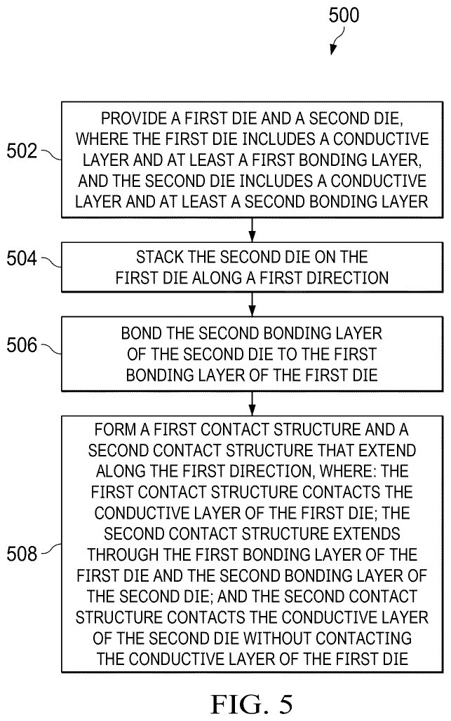

FIG. 5 illustrates a flow chart of an example process 500 of forming a semiconductor device, according to some aspects of the present disclosure. The semiconductor device can be similar to, or same as, the semiconductor devices 200, 300a, 300d, 300c, 300g, or 300h, or a part of these semiconductor devices, or a structure at an intermediate fabrication process of these semiconductor devices. The process 500 can be described in view of FIGS. 4A-4J. The process 500 can include the fabrication process of forming the semiconductor structures in FIGS. 4A-4J. The process 500 includes steps that can be performed with any suitable order and/or any combination.

At step 502, a first die and a second die are provided. The first die includes a conductive layer and at least a first bonding layer. The second die includes a conductive layer and at least a second bonding layer. The first die can be, for example, semiconductor structure 402 of FIG. 4D, and the second die can be, for example, semiconductor structure 404 of FIG. 4D. In some implementations, the first bonding layer of the first die and the second bonding layer of the second die each includes a dielectric material and excludes a conductive bonding contact. In some implementations, providing the first die includes thinning the first die by thinning a substrate comprised in the first die (e.g., thinning semiconductor structure 402 as described with respect to FIG. 4B).

At step 504, the second die is stacked on the first die along a first direction (e.g., the Z direction). In some implementations, stacking the second die on the first die along the first direction includes aligning the second die with the first die to offset a first end (e.g., end 418 of FIG. 4C) of the conductive layer of the first die and a first end (e.g., end 420 of FIG. 4C) of the conductive layer of the second die along a second direction (e.g., the X direction) perpendicular to the first direction.

At step 506, the second bonding layer of the second die is bonded to the first bonding layer of the first die. For example, the second bonding layer can be the dielectric layer deposited on the bottom surface of semiconductor structure 404, and the first bonding layer can be the dielectric layer deposited on the top surface of semiconductor structure 402, as described with respect to FIG. 4C.

At step 508, a first contact structure and a second contact structure that extend along the first direction are formed. The first contact structure (e.g., contact structure 426 of FIG. 4I) extends into the first die (e.g., semiconductor structure 402) and contacts the conductive layer (e.g., conductive layer 410) of the first die. The second contact structure (e.g., contact structure 428 of FIG. 4I) extends through the first bonding layer of the first die and the second bonding layer of the second die and into the second die (e.g., semiconductor structure 404). The second contact structure contacts the conductive layer (e.g., conductive layer 412) of the second die without contacting the conductive layer of the first die.

In some implementations, the process 500 further includes stacking the first die on a carrier wafer (e.g., semiconductor structure 400 of FIGS. 4A-4E). The first die can be stacked on the carrier wafer before the second die is stacked on the first die. The first die is between the carrier wafer and the second die.

In some implementations, the first contact structure and the second contact structure are formed by a same process (e.g., as described with respect to FIGS. 4H and 41). The process includes forming a first contact hole (e.g., contact hole 425 of FIG. 4H) and a second contact hole (e.g., contact hole 427 of FIG. 4H). The first contact hole and the second contact hole can be formed during a same etching process (e.g., as described with respect to FIG. 4H). The process further includes forming a respective insulating layer (e.g., outer layer 433 of FIG. 4I) in each of the first contact hole and the second contact hole. The process further includes forming a conductive structure in the insulating layer of each of the first contact hole and the second contact hole (e.g., by depositing a conductive material such as copper or tungsten into the first contact hole and the second contact hole). The first contact structure includes the insulating layer and the conductive structure in the first contact hole, and the second contact structure includes the insulating layer and the conductive structure in the second contact hole.

In some implementations, forming the first contact structure and the second contact structure further includes etching bottoms of the insulating layers to expose the conductive layer of the first die and the conductive layer of the second die in the first contact hole and the second contact hole respectively.

In some implementations, the process 500 further includes forming a mask layer (e.g., mask layer 411 of FIG. 4G) on top of the first die and etching the mask layer to form a first opening (e.g., opening 413 of FIG. 4G) and a second opening (e.g., opening 415 of FIG. 4G). The first contact hole extends from the first opening to the conductive layer of the first die, and the second contact hole extends from the second opening to the conductive layer of the second die.

In some implementations, the process 500 further includes forming a third bonding layer (e.g., bonding layer 443 of FIG. 4J) on top of the first die. The third bonding layer includes conductive bonding contacts (e.g., conductive bonding contacts 442 of FIG. 4J) and a dielectric material isolating the conductive bonding contacts. The first contact structure and the second contact structure can be coupled to the conductive bonding contacts.

In some implementations, the process 500 further includes providing a base die (e.g., semiconductor structure 444 of FIG. 4J). The base die includes a bottom bonding layer (e.g., bonding layer 445 of FIG. 4J), which includes conductive bonding contacts (e.g., conductive bonding contacts 446 of FIG. 4J) and a dielectric material isolating the conductive bonding contacts. As described with respect to FIG. 4J, the process 500 can further include stacking the base die on the first die and bonding the bottom bonding layer of the base die to the third bonding layer of the first die. The bottom bonding layer and the third bonding layer can be bonded by bonding the dielectric material of the bottom bonding layer to the dielectric material of the third bonding layer and bonding the conductive bonding contacts of the bottom bonding layer to the conductive bonding contacts of the third bonding layer.

FIG. 6A illustrates a side view of a semiconductor device 600a, according to some aspects of the present disclosure. The semiconductor device 600a includes memory dice 602a-608a, a base die 644a, a computing die 646a, and an interposer 648a stacked (e.g., sequentially) along the vertical direction (e.g., the Z direction). Memory dice 602a-608a can be examples of memory dice 102 of FIG. 1 and memory dice 204a-204d of FIG. 2A (e.g., DRAMs). The stack of memory dice 602a-608a includes a device area 601a and a connection area 603a adjacent to each other along the horizontal direction (e.g., the X direction). Memory dice 602a-608a include conductive layers 610a-616a extending along the horizontal direction (e.g., the X direction), respectively. Each of conductive layers 610a-616a is coupled to a memory array or a peripheral circuit in a corresponding memory die in device area 301a. Each of conductive layers 610a-616a can be coupled to input/output ports of the corresponding memory die, or can be configured to provide one or more of power supplies, clock signals, or data path signals to the corresponding memory die.

As shown in FIG. 6A, the semiconductor device 600a includes contact structures 626a-632a in connection area 603a. Contact structures 626a-632a can be examples of contact structures 210 of FIGS. 2A-2B. The semiconductor device 600a further includes bonding layers (e.g., bonding layers 634a, 636a, and 638a) between adjacent memory dice of memory dice 602a-608a, a bonding layer 640a between memory die 602a and base die 644a, and a bonding layer 642a between base die 644a and computing die 646a. Each of these bonding layers can include a dielectric material such as silicon oxide.

Contact structures 626a-632a extend along the vertical direction (e.g., the Z direction) and are coupled to conductive layers 610a-616a, respectively. Contact structure 626a extends into memory die 602a and contacts conductive layer 610a of memory die 602a without extending through bonding layer 634a. Contact structure 628a extends through conductive layer 610a of memory die 602a and bonding layer 634a. Contact structure 628a further extends into memory die 604a and contacts conductive layer 612a of memory die 604a without extending through bonding layer 636a. Contact structure 630a extends through conductive layer 610a of memory die 602a, bonding layer 634a, memory die 604a, conductive layer 612a, and bonding layer 636a. Contact structure 630a further extends into memory die 606a and contacts conductive layer 614a of memory die 606a without extending through bonding layer 638a. Contact structure 632a extends through conductive layer 610a of memory die 602a, bonding layer 634a, memory die 604a, conductive layer 612a, bonding layer 636a, memory die 606a, conductive layer 614a, and bonding layer 638a. Contact structure 632a further extends into memory die 608a and contacts conductive layer 616a of memory die 608a without extending through memory die 608a.

In some implementations, the conductive layers 610a-616a can be of the same size and can be located at the same position along the X direction. That is, conductive layers 610a-616a can be aligned along the Z direction. Each contact structure of contact structures 626a-632a can include a conductive structure (inner layer) extending along the Z direction and an insulating layer (outer layer) surrounding the conductive structure. The insulating layer can insulate the conductive structure from one or more conductive layers that the contact structure extends through.

In some implementations, bonding layers 634a, 636a, and 638a can be referred to as direct bonding layers since they are formed through direct dielectric-dielectric bonding. Each of bonding layers 634a, 636a, and 638a can include at least one dielectric material and exclude a conductive bonding contact. In some implementations, bonding layers 640a and 642a can be referred to as hybrid bonding layers since they can be formed through hybrid dielectric-dielectric bonding and metal-metal bonding. Each of bonding layers 640a and 642a can include bonding contacts (e.g., conductive bonding contacts) and at least one dielectric material isolating the bonding contacts. As shown in FIG. 6A, bonding layer 640a includes conductive bonding contacts 654a. Conductive bonding contacts 654a can be configured to connect memory die 602a and base die 644a. In some implementations, memory die 602a can include an interconnect layer (not shown in FIG. 6A) in contact with bonding layer 640a. The interconnect layer of memory die 602a has a structure similar to that of interconnect layer 645f described in FIG. 6F. Each of contact structures 626a-632a can be coupled to the interconnect layer of memory die 602a. The interconnect layer of memory die 602a can be coupled to base die 644a through conductive bonding contacts 654a in bonding layer 640a. Base die 644a includes vias 650a extending through base die 644a along the Z direction and being connected to conductive bonding contacts 654a. Each of the contact structures 626a-632a is coupled to a respective one of the vias 350a through a corresponding conductive bonding contact 654a. Bonding layer 642a includes conductive bonding contacts 656a. Conductive bonding contacts 656a can be configured to connect base die 644a and computing die 646a. Computing die 646a can be an example of computing die 108 of FIG. 1. Computing die 646a includes vias 652a extending through computing die 646a along the Z direction and being connected to conductive bonding contacts 656a. Each via 650a is coupled to a respective via 652a through a corresponding conductive bonding contact 656a. In some implementations, vias 650a and 652a can be through-silicon vias (TSVs). Structures of bonding layers 634a, 636a, 638a, 640a, and 642a are described later with further details with respect to FIGS. 6B and 6C.

In some implementations, base die 644a includes a control circuitry that is configured to control memory dice 602a-608a. The control circuitry can be coupled to memory dice 602a-608a, for example, through contact structures 626a-632a, the interconnect layer of memory die 602a, and conductive bonding contacts 654a.

The interposer 648a has a surface 658a and a surface 660a. The surface 658a can be bonded to the computing die 646a. Conductive terminals 662a can be connected to the surface 660a. The interposer 648a can include interconnection lines that connect vias 652a of computing device 646a to the conductive terminals 662a. The conductive terminals 662a can be coupled to an external device (e.g., external host die 112 of FIG. 1). In some implementations, the conductive terminals 662a can be micro bumps.

In some implementations, as shown in FIG. 6A, memory dice 602a-606a can have a reduced thickness (along the Z direction) by having their substrates thinned. The topmost memory die 608a (e.g., the one among memory dice 602a-608a that is farthest away from base die 644a) may not be thinned. As a result, a thickness of each of memory dice 602a-606a can be smaller than a thickness of memory die 608a. The thickness of each of memory dice 602a-608a can be in any suitable range (e.g., between 3 μm and 20 μm).

FIG. 6B illustrates a diagram 600b showing an enlarged view of bonding layer 634a of FIG. 6A, according to some aspects of the present disclosure. Bonding layer 634a can include a top bonding layer 633b and a bottom bonding layer 637b bonded at a bonding interface 635b. Each of the top bonding layer 633b and the bottom bonding layer 637b can include a dielectric material (including, but not limited to, silicon oxide, silicon nitride, silicon oxynitride, low-k dielectrics, or any combination thereof) and can exclude a conductive bonding contact. Memory die 604a can be bonded on top of memory die 602a in a face-to-face manner through bonding layer 634a. Bonding interface 635b is disposed between the top bonding layer 633b and the bottom bonding layer 637b as a result of direct bonding (e.g., dielectric-dielectric bonding), which forms bonding between surfaces without using intermediate layers, such as solder or adhesives. In some implementations, for example, when the dielectric material of the top bonding layer 633b and the dielectric material of the bottom bonding layer 637b are different materials, bonding interface 635b can be a visible layer with a certain thickness that includes a top surface of the bottom bonding layer 637b and a bottom surface of the top bonding layer 633b. In some implementations, for example, when the dielectric material of the top bonding layer 633b and the dielectric material of the bottom bonding layer 637b are the same material, bonding interface 635b may not be visible and may form a continuous part with the top bonding layer 633b and the bottom bonding layer 637b. Bonding layers 636a and 638a of FIG. 6A can have structures similar to that of bonding layer 634a as described in FIG. 6B.

FIG. 6C illustrates a diagram 600c showing an enlarged view of bonding layer 640a of FIG. 6A, according to some aspects of the present disclosure. Bonding layer 640a can include a top bonding layer 643c and a bottom bonding layer 647c bonded at a bonding interface 645c. The top bonding layer 643c includes conductive bonding contacts 641c and a dielectric material 639c isolating conductive bonding contacts 641c. Conductive bonding contacts 641c can include conductive materials including, but not limited to, silicon oxide, silicon nitride, silicon oxynitride, low-k dielectrics, or any combination thereof. Dielectric material 639c can include dielectrics including, but not limited to, silicon oxide, silicon nitride, silicon oxynitride, low-k dielectrics, or any combination thereof. Similarly, the bottom bonding layer 647c includes conductive bonding contacts 649c and a dielectric material 651c isolating conductive bonding contacts 649c. Conductive bonding contacts 649c can include conductive materials including, but not limited to, silicon oxide, silicon nitride, silicon oxynitride, low-k dielectrics, or any combination thereof. Dielectric material 651c can include dielectrics including, but not limited to, silicon oxide, silicon nitride, silicon oxynitride, low-k dielectrics, or any combination thereof.

Conductive bonding contacts 641c and 649c can be examples of conductive bonding contacts 654a of FIG. 6A. Conductive bonding contacts 641c are in contact with conductive bonding contacts 649c at bonding interface 645c. Memory die 602a can be bonded on top of base die 644a in a face-to-face manner through bonding layer 640a. Bonding interface 645c is disposed between the top bonding layer 643c and the bottom bonding layer 647c as a result of hybrid bonding (e.g., metal-metal/dielectric-dielectric bonding). The hybrid bonding forms bonding between surfaces without using intermediate layers, such as solder or adhesives and can obtain metal-metal bonding and dielectric-dielectric bonding simultaneously. In some implementations, for example, when the dielectric material 639c of the top bonding layer 643c and the dielectric material 651c of the bottom bonding layer 647c are different materials, bonding interface 645c can be a visible layer with a certain thickness that includes a top surface of the bottom bonding layer 647c and a bottom surface of the top bonding layer 643c. In some implementations, for example, when the dielectric material 639c and the dielectric material 651c are the same material, bonding interface 645c may not be visible and may form a continuous part with the top bonding layer 643c and the bottom bonding layer 647c. Bonding layer 642a of FIG. 6A can have a structure similar to that of bonding layer 640a as described in FIG. 6C.

FIG. 6D illustrates a side view of a semiconductor device 600d, according to some aspects of the present disclosure. The semiconductor device 600d includes memory dice 602d-608d, a base die 644d, a computing die 646d, and an interposer 648d. Memory dice 602d-608d and base die 644d are stacked (e.g., sequentially) along the Z direction. Base die 644d and computing die 646d are integrated on different positions of the interposer 648d along the X direction. Memory dice 602d-608d are similar to memory dice 602a-608a of FIG. 6A. Memory dice 602d-608d can be examples of memory dice 102 of FIG. 1 and memory dice 204a-204d of FIG. 2A (e.g., DRAMs). The stack of memory dice 602d-608d includes a device area 601d and a connection area 603d adjacent to device area 601d along the horizontal direction (e.g., the X direction). Memory dice 602d-608d include conductive layers 610d-616d extending along the horizontal direction (e.g., the X direction), respectively. Each of conductive layers 610d-616d is coupled to a memory array or a peripheral circuit in a corresponding memory die in device area 601d. Each of conductive layers 610d-616d can be coupled to input/output ports of the corresponding memory die, or can be configured to provide one or more of power supplies, clock signals, or data path signals to the corresponding memory die.

As shown in FIG. 6D, the semiconductor device 600d includes contact structures 626d-632d in connection area 603d. Contact structures 626d-632d can be examples of contact structures 210 of FIGS. 2A-2B. The semiconductor device 600d further includes bonding layers (e.g., bonding layers 634d, 636d, and 638d) between adjacent memory dice of memory dice 602d-608d and a bonding layer 640d between memory die 602d and base die 644d. Each of these bonding layers can include a dielectric material such as silicon oxide.

Contact structures 626d-632d extend along the vertical direction (e.g., the Z direction) and are coupled to conductive layers 610d-616d, respectively. Contact structure 626d extends into memory die 602d and contacts conductive layer 610d of memory die 602d without extending through bonding layer 634d. Contact structure 628d extends through conductive layer 610d of memory die 602d and bonding layer 634d. Contact structure 628d further extends into memory die 604d and contacts conductive layer 612d of memory die 604d without extending through bonding layer 636d. Contact structure 630d extends through conductive layer 610d of memory die 602d, bonding layer 634d, memory die 604d, conductive layer 612d, and bonding layer 636d. Contact structure 630d further extends into memory die 606d and contacts conductive layer 614d of memory die 606d without extending through bonding layer 638d. Contact structure 632d extends through conductive layer 610d of memory die 602d, bonding layer 634d, memory die 604d, conductive layer 612d, bonding layer 636d, memory die 606d, conductive layer 614d, and bonding layer 638d. Contact structure 632d further extends into memory die 608d and contacts conductive layer 616d of memory die 608d without extending through memory die 608d.

In some implementations, the conductive layers 610d-616d can be of the same size and can be located at the same position along the X direction. That is, conductive layers 610d-616d can be aligned along the Z direction. Each contact structure of contact structures 626d-632d can include a conductive structure (inner layer) extending along the Z direction and an insulating layer (outer layer) surrounding the conductive structure. The insulating layer can insulate the conductive structure from one or more conductive layers that the contact structure extends through.

In some implementations, bonding layers 634d, 636d, and 638d can be referred to as direct bonding layers and can have structures similar to that of bonding layer 634a described in FIG. 6B. Each of bonding layers 634d, 636d, and 638d can include at least one dielectric material and exclude a conductive bonding contact. In some implementations, bonding layer 640d can be referred to as a hybrid bonding layer and can have a structure similar to that of bonding layer 640a described in FIG. 6C. Bonding layer 640d can include bonding contacts (e.g., conductive bonding contacts 654d as shown in FIG. 6D) and at least one dielectric material isolating the bonding contacts. Conductive bonding contacts 654d can be configured to connect memory die 602d and base die 644d. In some implementations, memory die 602d can include an interconnect layer (not shown in FIG. 6D) in contact with bonding layer 640d. The interconnect layer of memory die 602d has a structure similar to that of interconnect layer 645f described in FIG. 6F. Each of contact structures 626d-632d can be coupled to the interconnect layer of memory die 602d. The interconnect layer of memory die 602d can be coupled to base die 644d through conductive bonding contacts 654d in bonding layer 640d. Base die 644d includes vias 650d extending through base die 644d along the Z direction and being connected to conductive bonding contacts 654d. Each of the contact structures 626d-632d is coupled to a respective one of the vias 650d through a corresponding conductive bonding contact 654d. In some implementations, vias 650d can be TSVs.

In some implementations, base die 644d includes a control circuitry that is configured to control memory dice 602d-608d. The control circuitry can be coupled to memory dice 602d-608d, for example, through contact structures 626d-632d, the interconnect layer of memory die 602d, and conductive bonding contacts 654d.

The base die 644d can be coupled to the computing die 646d through the interposer 648d. The interposer 648d has a surface 658d and a surface 660d. The vias 650d in the base die 644d can be connected to conductive terminals 664d on surface 658d of the interposer 648d. The computing die 646d can be connected to conductive terminals 666d on surface of 658d the interposer 648d. The semiconductor device 600d can include conductive terminals 662d connected to the surface 660d of the interposer 648d. Conductive terminals 664d, 666d, and 662d can be coupled through conductive lines (e.g., conductive lines 669d as shown in FIG. 6D) in the interposer 648d. The conductive terminals 662d can be coupled to an external device (e.g., the external host die 112 of FIG. 1). In some implementations, the conductive terminals 664d, 666d, and 662d can be micro bumps. It is understood that in practice, base die 644d, computing die 646d, and interposer 648d can be integrated together using any suitable packaging technology including, for example, Chip-on-Wafer-on-Substrate (CoWoS).

In some implementations, as shown in FIG. 6D, memory dice 602d-606d can have a reduced thickness (along the Z direction) by having their substrates thinned. The topmost memory die 608d (e.g., the one among memory dice 602d-608d that is farthest away from base die 644d) may not be thinned. As a result, a thickness of each of memory dice 602d-606d can be smaller than a thickness of memory die 608d. The thickness of each of memory dice 602d-608d can be in any suitable range (e.g., between 3 μm and 20 μm).

FIG. 6E illustrates a side view of a semiconductor device 600e, according to some aspects of the present disclosure. The semiconductor device 600e includes memory dice 602e-608c, a base die 644c, a computing die 646e, and an interposer 648e stacked (e.g., sequentially) along the vertical direction (e.g., the Z direction). Memory dice 602e-608e are similar to memory dice 602a-608a of FIG. 6A. Memory dice 602e-608e can be examples of memory dice 102 of FIG. 1 and memory dice 204a-204d of FIG. 2A (e.g., DRAMs). The stack of memory dice 602e-608e includes a device area 601e and a connection area 603e adjacent to device area 601e along the horizontal direction (e.g., the X direction). Memory dice 602e-608e include conductive layers 610e-616e extending along the horizontal direction (e.g., the X direction), respectively. Each of conductive layers 610e-616e is coupled to a memory array or a peripheral circuit in a corresponding memory die in device area 601e. Each of conductive layers 610e-616e can be coupled to input/output ports of the corresponding memory die, or can be configured to provide one or more of power supplies, clock signals, or data path signals to the corresponding memory die.

As shown in FIG. 6E, the semiconductor device 600e includes contact structures 626e-632e in connection area 603e. Contact structures 626e-632e can be examples of contact structures 210 of FIGS. 2A-2B. The semiconductor device 600e further includes bonding layers (e.g., bonding layers 634e, 636e, and 638e) between adjacent memory dice of memory dice 602e-608c and a bonding layer 640e between memory die 602e and base die 644c. Each of these bonding layers can include a dielectric material silicon oxide. Base die 644e includes a surface 665e and another surface 667e. Surface 665e is bonded to memory die 602e through bonding layer 640c. Base die 644c further includes a conductive layer 668e and a contact structure 670e connected to the conductive layer 668e. Contact structure 670e extends along the Z direction into base die 644c. Conductive layer 668e can be coupled between a circuit of base die 644e and the contact structure 370c. In some implementations, bonding layers 634c, 636e, 638e, and 640e can be referred to as direct bonding layers and can have structures similar to that of bonding layer 634a described in FIG. 6B. Each of bonding layers 634c, 636e, 638e, and 640e can include at least one dielectric material and exclude a conductive bonding contact. In some implementations, bonding layer 642e can be referred to as a hybrid bonding layer and can have a structure similar to that of bonding layer 640a described in FIG. 6C. Bonding layer 642e can include bonding contacts (e.g., conductive bonding contacts 656e as shown in FIG. 6E) and at least one dielectric material isolating the bonding contacts.

Contact structures 6260-632e and 670e extend along the vertical direction (e.g., the Z direction) and are coupled to conductive layers 610e-616e and 668e, respectively. Contact structure 670e extends into base die 644c and contacts conductive layer 668e of base die 644c without extending through bonding layer 640e. Contact structure 626e extends through bonding layer 640e into memory die 602e and contacts conductive layer 610e of memory die 602e without extending through bonding layer 634c. Contact structure 628e extends through bonding layer 640c, conductive layer 610e of memory die 602e, and bonding layer 634e. Contact structure 628e further extends into memory die 604e and contacts conductive layer 612e of memory die 604c without extending through bonding layer 636e. Contact structure 630e extends through bonding layer 640c, conductive layer 610e of memory die 602e, bonding layer 634e, memory die 604e, conductive layer 612e, and bonding layer 636e. Contact structure 630e further extends into memory die 606c and contacts conductive layer 614e of memory die 606e without extending through bonding layer 638c. Contact structure 632e extends through bonding layer 640e, conductive layer 610e of memory die 602e, bonding layer 634e, memory die 604e, conductive layer 612e, bonding layer 636c, memory die 606e, conductive layer 614e, and bonding layer 638c. Contact structure 632c further extends into memory die 608e and contacts conductive layer 616e of memory die 608c without extending through memory die 608e. While FIG. 6E shows an example where contact structures 626e-632e do not extend through conductive layer 668e, it is understood that in some other implementations, one or more of contact structures 626e-632e may extend through conductive layer 668c.

In some implementations, the conductive layers 610e-616e can be of the same size and can be located at the same position along the X direction. That is, conductive layers 610e-616e can be aligned along the Z direction. Each contact structure of contact structures 626e-632e can include a conductive structure (inner layer) extending along the Z direction and an insulating layer (outer layer) surrounding the conductive structure. The insulating layer can insulate the conductive structure from one or more conductive layers that the contact structure extends through.

Base die 644e can include an interconnect layer (not shown in FIG. 6E) in contact with bonding layer 642c. Each of contact structures 626e-632e and 670e can be coupled to the interconnect layer of base die 644c. An example of the interconnect layer of base die 644e is described later with further details with respect to FIG. 6F. The interconnect layer of base die 644c can be coupled to computing die 646e through conductive bonding contacts 656e in bonding layer 642c. Conductive bonding contacts 656e can be configured to couple base die 644c and memory dice 602e-608e to computing die 646e. Computing die 646e can be an example of computing die 108 of FIG. 1. Computing die 646e includes vias 652e extending through computing die 646c along the Z direction and being connected to conductive bonding contacts 656e. Each of the contact structures 670e and 626e-632e can be coupled to a respective one of the vias 652e through the interconnect layer of base die 644e and a corresponding conductive bonding contact 656e. In some implementations, vias 652e can be TSVs.

In some implementations, base die 644e includes a control circuitry that is configured to control memory dice 602e-608e. The control circuitry can be coupled to memory dice 602e-608e, for example, through contact structures 670e and 626e-632e, the interconnect layer of base die 644c, and conductive bonding contacts 656c.

The interposer 648e has a surface 658e and a surface 660e. The surface 658e can be bonded to the computing die 646c. Conductive terminals 662e can be connected to the surface 660c. The interposer 648e can include interconnection lines that connect vias 652e of computing die 646e to the conductive terminals 662e. The conductive terminals 662e can be coupled to an external device (e.g., the external host die 112 of FIG. 1). In some implementations, the conductive terminals 662e can be micro bumps.

In some implementations, as shown in FIG. 6E, memory dice 602e-606e can have a reduced thickness (along the Z direction) by having their substrates thinned. The topmost memory die 608c (e.g., the one among memory dice 602e-608e that is farthest away from base die 644c) may not be thinned. As a result, a thickness of each of memory dice 602e-606e can be smaller than a thickness of memory die 608e. The thickness of each of memory dice 602e-608e can be in any suitable range (e.g., between 3 μm and 20 μm).

FIG. 6F illustrates a diagram 600f showing an enlarged view of an interconnect layer 645f in base die 644e of FIG. 6E, according to some aspects of the present disclosure. The interconnect layer 645f is between contact structures 626e-632e and 670e and bonding layer 642c along the Z direction. The interconnect layer 645f can include interconnects (also referred to herein as “contacts”), including lateral interconnect lines 647f and VIA contacts (not shown). Contact structures 626e-632e and 670e and conductive bonding contacts 656e of bonding layer 642e can be coupled to the interconnects in the interconnect layer 645f. The interconnect layer 645f can further include one or more ILD layers (also known as IMD layers) in which the interconnect lines 647f and VIA contacts can form. That is, the interconnect layer 645f can include interconnect lines 647e and VIA contacts in multiple ILD layers. The interconnect lines 647f and VIA contacts in the interconnect layer 645f can include conductive materials including, but not limited to, W, Co, Cu, Al, silicides, or any combination thereof. The ILD layers in the interconnect layer 645f can include dielectric materials including, but not limited to, silicon oxide, silicon nitride, silicon oxynitride, low dielectric constant (low-k) dielectrics, or any combination thereof.

FIG. 6G illustrates a side view of a semiconductor device 600g, according to some aspects of the present disclosure. The semiconductor device 600g includes memory dice 602g-608g, a base die 644g, a computing die 646g, and an interposer 648g. Memory dice 602g-608g and base die 644g are stacked sequentially along the Z direction. Base die 644g and computing die 646g are integrated on different positions of the interposer 648g along the X direction. Memory dice 602g-608g are similar to memory dice 602a-608a of FIG. 3A. Memory dice 602g-608g can be examples of memory dice 102 of FIG. 1 and memory dice 204a-204d of FIG. 2A (e.g., DRAMs). The stack of memory devices 602g-608g includes a device area 601g and a connection area 603g adjacent to device area 601g along the horizontal direction (e.g., the X direction). Memory dice 602g-608g include conductive layers 610g-616g extending along the horizontal direction (e.g., the X direction), respectively. Each of conductive layers 610g-616g is coupled to a memory array or a peripheral circuit in a corresponding memory die in device area 601g. Each of conductive layers 610g-616g can be coupled to input/output ports of the corresponding memory die, or can be configured to provide one or more of power supplies, clock signals, or data path signals to the corresponding memory die.

As shown in FIG. 6G, the semiconductor device 600g includes contact structures 626g-632g in connection area 603g. Contact structures 626g-632g can be examples of contact structures 210 of FIGS. 2A-2B. The semiconductor device 600g further includes bonding layers (e.g., bonding layers 634g, 636g, and 638g) between adjacent memory dice of memory dice 602g-608g and a bonding layer 640g between memory die 602g and base die 644g. Each of these bonding layers can include silicon oxide. Base die 644g includes a surface 665g and another surface 667g. Surface 665g is bonded to memory die 602g through bonding layer 640g. Base die 644g further includes a conductive layer 668g and a contact structure 670g connected to the conductive layer 668g. Contact structure 670g extends along the Z direction into base die 644g. Conductive layer 668g can be coupled between a circuit of base die 644g and the contact structure 670g. In some implementations, bonding layers 634g, 636g, 638g, and 640g can be referred to as direct bonding layers and can have structures similar to that of bonding layer 634a described in FIG. 6B. Each of bonding layers 634g, 636g, 638g, and 640g can include at least one dielectric material and exclude a conductive bonding contact.

Contact structures 626g-632g and 670g extend along the vertical direction (e.g., the Z direction) and are coupled to conductive layers 610g-616g and 668g, respectively. Contact structure 670g extends into base die 644g and contacts conductive layer 668g of base die 644g without extending through bonding layer 640g. Contact structure 626g extends through bonding layer 640g into memory die 602g and contacts conductive layer 610g of memory die 602g without extending through bonding layer 634g. Contact structure 628g extends through bonding layer 640g, conductive layer 610g of memory die 602g, and bonding layer 634g. Contact structure 628g further extends into memory die 604g and contacts conductive layer 612g of memory die 604g without extending through bonding layer 636g. Contact structure 630g extends through bonding layer 640g, conductive layer 610g of memory die 602g, bonding layer 634g, memory die 604g, conductive layer 612g, and bonding layer 636g. Contact structure 630g further extends into memory die 606g and contacts conductive layer 614g of memory die 606g without extending through bonding layer 638g. Contact structure 632g extends through bonding layer 640g, conductive layer 610g of memory die 602g, bonding layer 634g, memory die 604g, conductive layer 612g, bonding layer 636g, memory die 606g, conductive layer 614g, and bonding layer 638g. Contact structure 632g further extends into memory die 608g and contacts conductive layer 616g of memory die 608g without extending through memory die 608g. While FIG. 6G shows an example where contact structures 626g-632g do not extend through conductive layer 668g, it is understood that in some other implementations, one or more of contact structures 626g-632g may extend through conductive layer 668g.

In some implementations, the conductive layers 610g-616g can be of the same size and can be located at the same position along the X direction. That is, conductive layers 610g-616g can be aligned along the Z direction. Each contact structure of contact structures 626g-632g can include a conductive structure (inner layer) extending along the Z direction and an insulating layer (outer layer) surrounding the conductive structure. The insulating layer can insulate the conductive structure from one or more conductive layers that the contact structure extends through.

Base die 644g can include an interconnect layer (not shown in FIG. 6G). The interconnect layer of base die 644g has a structure similar to that of interconnect layer 645f described in FIG. 6F. Each of contact structures 626g-632g and 670g can be coupled to the interconnect layer of base die 644g. The base die 644g can be coupled to the computing die 646g through the interconnect layer and the interposer 648g. The interposer 648g has a surface 658g and a surface 660g. Interconnects in the interconnect layer of base die 644g can be connected to conductive terminals 664g on surface 658g of the interposer 648g. The computing die 646g can be connected to conductive terminals 666g on surface 658g of the interposer 648g. The semiconductor device 600g can include conductive terminals 662g connected to the surface 660g of the interposer 648g. Conductive terminals 664g, 666g, and 662g can be coupled through conductive lines (e.g., conductive lines 669g as shown in FIG. 6G) in the interposer 648g. The conductive terminals 662g can be coupled to an external device (e.g., the external host die 112 of FIG. 1). In some implementations, the conductive terminals 664g, 666g, and 662g can be micro bumps. It is understood that in practice, base die 644g, computing die 646g, and interposer 648g can be integrated together using any suitable packaging technology including, for example, Chip-on-Wafer-on-Substrate (CoWoS).

In some implementations, base die 644g includes a control circuitry that is configured to control memory dice 602g-608g. The control circuitry can be coupled to memory dice 602g-608g, for example, through contact structures 670g and 626g-632g and the interconnect layer of base die 644g.

In some implementations, as shown in FIG. 6G, memory dice 602g-606g can have a reduced thickness (along the Z direction) by having their substrates thinned. The topmost memory die 608g (e.g., the one among memory dice 602g-608g that is farthest away from base die 644g) may not be thinned. As a result, a thickness of each of memory dice 602g-606g can be smaller than a thickness of memory die 608g. The thickness of each of memory dice 602g-608g can be in any suitable range (e.g., between 3 μm and 20 μm).

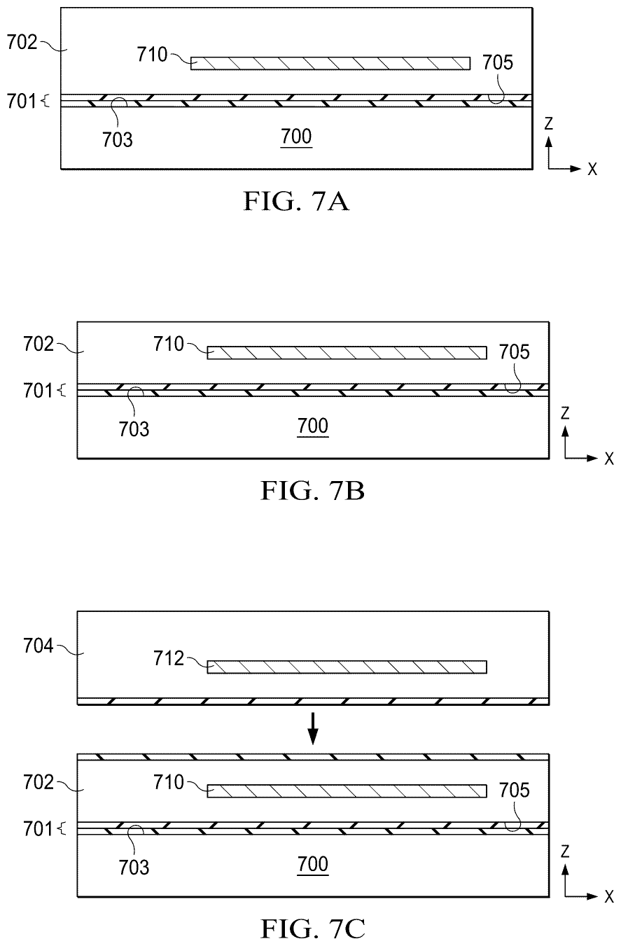

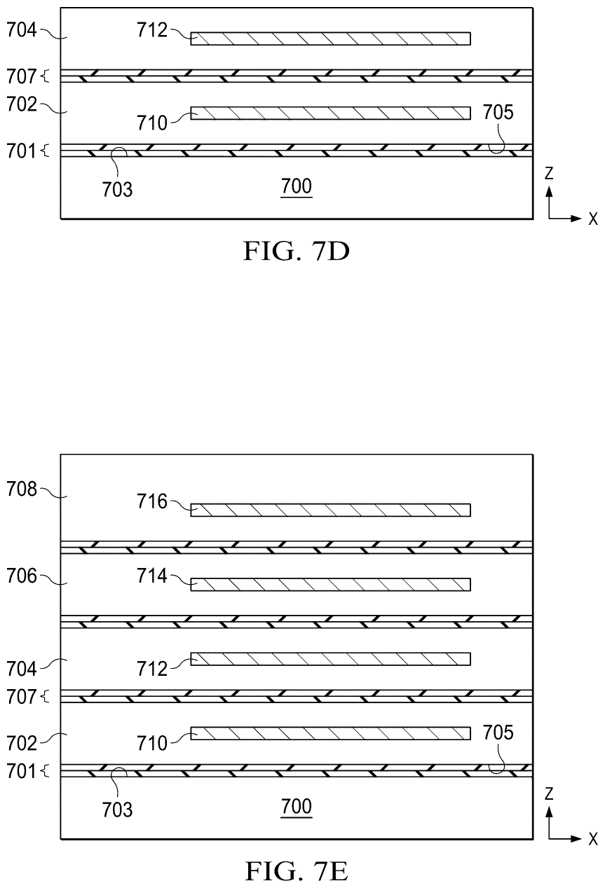

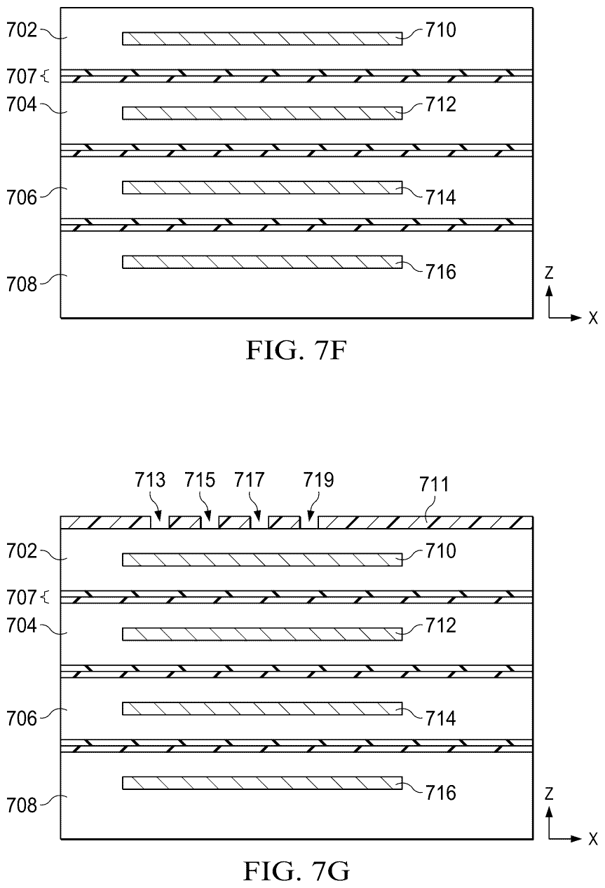

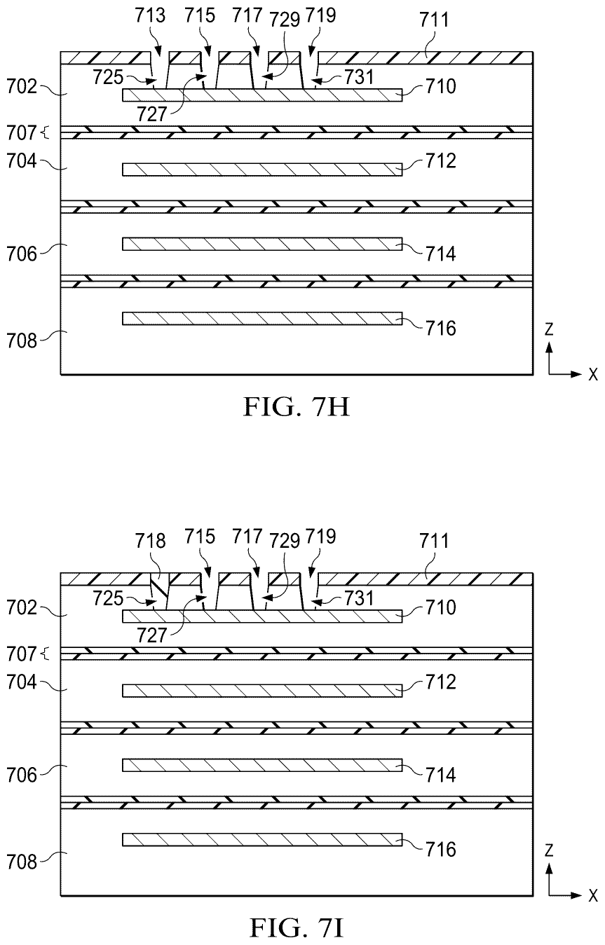

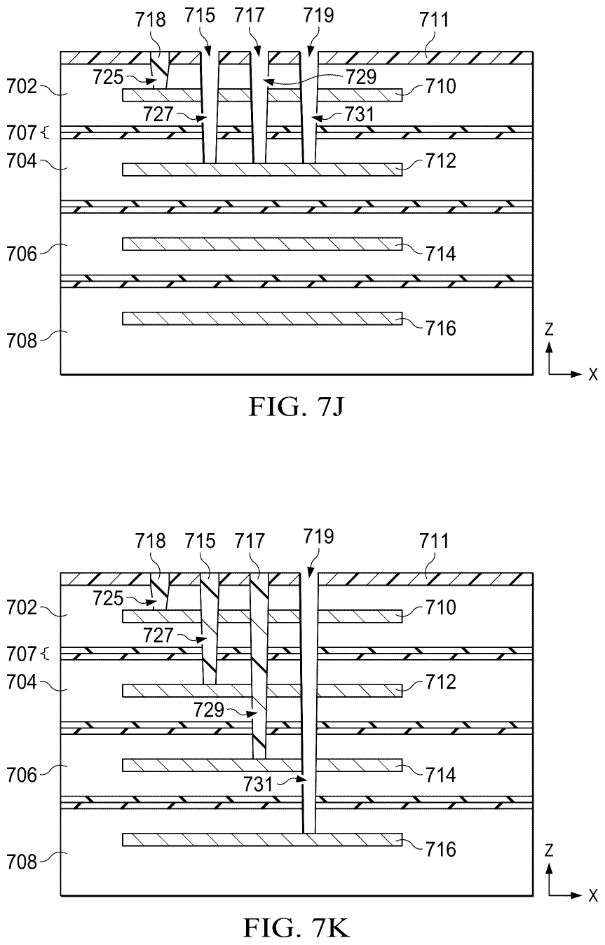

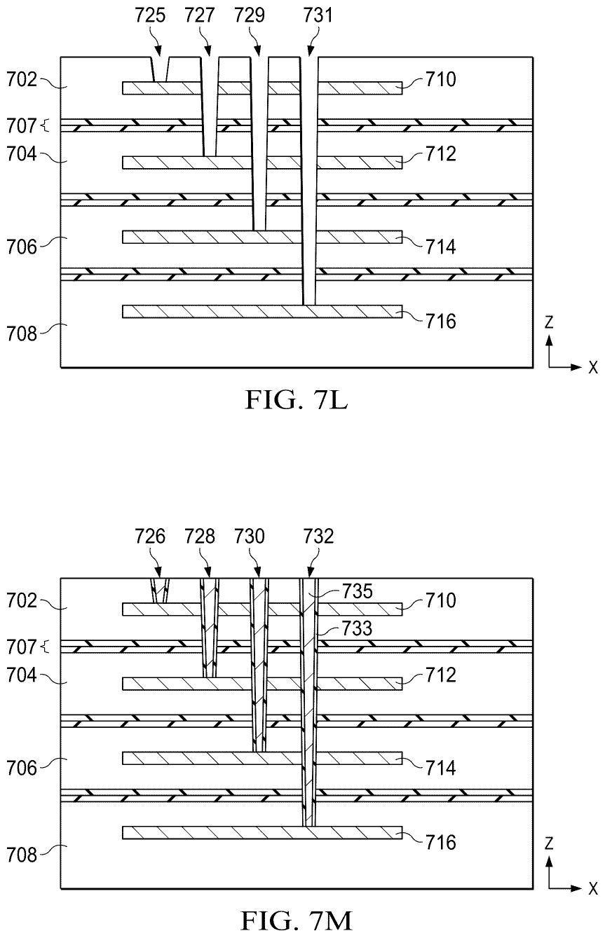

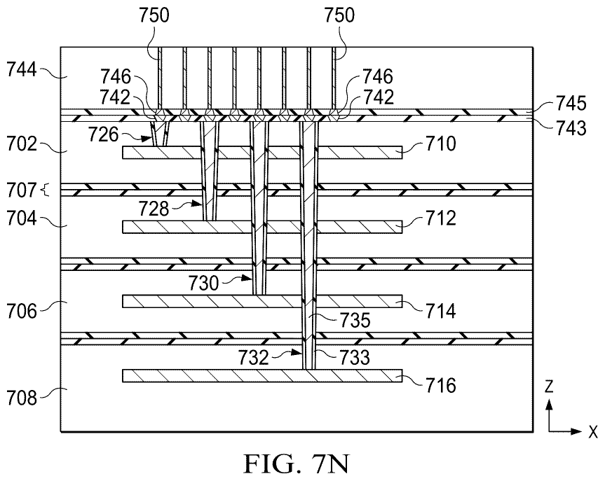

FIGS. 7A-7N show an example process of manufacturing a semiconductor device, according to some aspects of the present disclosure. In some implementations, the process described herein can be used to manufacture any suitable semiconductor devices, such as semiconductor devices 200d, 600a, and 600d.

FIG. 7A illustrates that the process can start with providing semiconductor structures 700 and 702 both extending along the horizontal direction (e.g., the X direction). Semiconductor structure 700 can be a carrier wafer. Semiconductor structure 702 can be a semiconductor device or a semiconductor die (e.g., memory die 204a of FIG. 2D or memory die 602a of FIG. 6A) that includes a conductive layer 710 (e.g., conductive layer 610a of FIG. 6A). Semiconductor structure 702 can be stacked on semiconductor structure 700 along the vertical direction (e.g., the Z direction) and bonded to semiconductor structure 700 through a bonding layer 701. Semiconductor structures 700 and 702 can be bonded using any suitable bonding technology (e.g., a direct bonding technology). For example, a first dielectric layer (e.g., silicon oxide) can be deposited on surface 703 of semiconductor structure 700, and a second dielectric layer (e.g., silicon oxide) can be deposited on surface 705 of semiconductor structure 702. By applying pressure and heat, the first dielectric layer and the second dielectric layer can be bonded together to form bonding layer 701 between semiconductor structures 700 and 702. Semiconductor structure 700 can serve as a support to semiconductor structure 702. Semiconductor structures 700 and 702 can have any suitable thicknesses along the Z direction. In some implementations, a thickness of semiconductor structure 702 can be in a range between 40 μm and 50 μm.

As shown in FIG. 7B, semiconductor structure 702 is thinned. Thinning semiconductor structure 702 includes removing a top portion (e.g., a portion farthest from semiconductor structure 700 along the Z direction) of semiconductor structure 702. For example, the thickness of semiconductor structure 702 can be reduced from about 40-50 μm to 3-20 μm by thinning. In some implementations, semiconductor structure 702 includes a substrate on its bottom and is flipped upside down before being bonded to semiconductor structure 700. That is, the substrate of the semiconductor structure 702 becomes the top of semiconductor structure 702 after the flip. Thus, a portion of the substrate of semiconductor structure 702 is removed by thinning the top portion of semiconductor structure 702. In some implementations, after being thinned, semiconductor structure 702 can still maintain its shape without producing substantial distortion or deformation due to the support provided by the semiconductor structure 700 (e.g., the carrier wafer).

As shown in FIG. 7C, a semiconductor structure 704 is provided. Semiconductor structure 704 (e.g., memory die 604a of FIG. 6A) includes a conductive layer 712 (e.g., conductive layer 612a of FIG. 6A). In some implementations, semiconductor structure 704 includes a substrate in its top portion, which is similar to semiconductor structure 702 as described with respect to FIG. 7B. Semiconductor structure 704 can be aligned with semiconductor structure 702 to place conductive layer 712 and conductive layer 710 at a same position along the X direction. By doing so, conductive layer 712 and conductive layer 710 can be aligned along the Z direction. In some implementations, conductive layer 712 and conductive layer 710 can be of the same size. A dielectric layer can be deposited on a bottom surface of semiconductor structure 704, and a dielectric layer can be deposited on a top surface of semiconductor structure 702. Semiconductor structure 704 can be stacked on and bonded to semiconductor structure 702 along the Z direction, which is similar to the example in which semiconductor structure 702 and semiconductor structure 700 are bonded as described with respect to FIG. 7A.

As shown in FIG. 7D, the dielectric layer of the semiconductor structure 704 and the dielectric layer of the semiconductor structure 702 can form a bonding layer 707. Semiconductor structure 704 is thinned by removing a top portion (e.g., a portion of the substrate of semiconductor structure 704).

FIG. 7E illustrate that a semiconductor structure 706 (e.g., memory die 606a of FIG. 6A) including a conductive layer 714 (e.g., conductive layer 614a of FIG. 6A) and a semiconductor structure 708 (e.g., memory die 608a of FIG. 6A) including a conductive layer 716 (e.g., conductive layer 616a of FIG. 6A) are provided. Semiconductor structure 706 are aligned with, stacked on, and bonded to semiconductor structure 704 in a way similar to the examples described with respect to FIGS. 7A-7D. Semiconductor structure 706 also can be thinned. Similarly, semiconductor structure 708 are aligned with, stacked on, and bonded to semiconductor structure 706. In some implementations, semiconductor structure 708 is not thinned, thereby providing support to other semiconductor structures because of its thickness when a stack of semiconductor structures 704-708 is flipped upside down in later steps. The conductive layers 710-716 can be of the same length and can be aligned along the Z direction. In some implementations, semiconductor structures 704-708 (e.g., before the thinning) can have the same structure. Thus, an order in which semiconductor structures 704-708 are stacked may not affect the fabrication process. In other words, labeling semiconductor structures 704-708 may not be necessary.

While in this example a semiconductor device can include four semiconductor structures 702-708 stacked together, the technology disclosed herein can be applied to stacking any suitable number of semiconductor structures (e.g., 2, 5, or 8). The number of semiconductor structures can be determined based on factors including technology constraints, thermal considerations, signal integrity and interferences, physical size and application, costs and yields, reliability concerns, etc. In those cases, the last semiconductor structure (rather than the fourth one as shown in FIG. 7E), which is farthest from semiconductor structure 700, can be thicker than the other semiconductor structures along the Z direction. For example, the last semiconductor structure is not thinned, and the other semiconductor structures are thinned. This way, the last semiconductor structure can provide support due to its thickness when the stacked structure is flipped upside down in later steps.

As shown in FIG. 7F, semiconductor structure 700 can be removed by a debonding process. The stack of semiconductor structures 702-708 is flipped upside down. As the thickest among semiconductor structures 702-708, semiconductor structure 708 is now on the bottom and supports the other semiconductor structures.

FIG. 7G illustrates that a mask layer 711 is formed on top of semiconductor structure 702. Openings 713, 715, 717, and 719 are formed in the mask layer 711. In some implementations, mask layer 711 includes a photoresist material, and openings 713, 715, 717, and 719 can be formed by etching the mask layer 711. Positions of the openings 713, 715, 717, and 719 can be determined such that each contact hole (e.g., contact holes 725, 727, 729, and 731 of FIG. 7H) extending along the Z direction can extend from one of the openings 713, 715, 717, and 719 and reach conductive layer 710.

FIG. 7H illustrates that contact holes 725, 727, 729, and 731 extending along the Z direction into semiconductor structure 702 are formed. Contact holes 725, 727, 729, and 731 respectively extends from openings 713, 715, 717, and 719 and reach conductive layer 710. In some implementations, contact holes 725, 727, 729, and 731 are formed by etching an isolating material (e.g., silicon oxide) in semiconductor structure 702 (for example, using a first etching gas).

FIG. 7I illustrates that contact hole 725 is filled with a filler material 718. In some implementations, the filler material 718 can include any suitable material such as a dielectric material or the photoresist material in mask layer 711.

FIG. 7J illustrates that contact holes 727, 729, and 731 can be deepened, and the deepened contact holes 727, 729, and 731 extend through conductive layer 710 and reach conductive layer 712. Contact holes 727, 729, and 731 can be deepened by etching through conductive layer 710 (e.g., using a second etching gas) and etching the materials (e.g., silicon oxide) between conductive layer 710 and conductive layer 712 (e.g., using the first etching gas). The second etching gas can have a faster etching rate for a conductive material (e.g., metal) in the conductive layer (e.g., conductive layers 710-716) than the first etching gas.

FIG. 7K illustrates that contact holes 729 and 731 can be further deepened. The contact hole 727 that extends from opening 715 to conductive layer 712 is filled with a filler material (e.g., filler material 718). Contact holes 729 and 731 can be deepened by etching through conductive layer 712 (e.g., using the second etching gas) and etching the materials (e.g., silicon oxide) between conductive layer 712 and conductive layer 714 (e.g., using the first etching gas). The deepened contact holes 729 and 731 extend through conductive layer 710 and conductive layer 712 and reach conductive layer 714. Then, the deepened contact holes 729 can be filled with a filler material (e.g., filler material 718). Contact hole 731 can be further deepened by etching through conductive layer 714 (e.g., using the second etching gas) and etching the materials (e.g., silicon oxide) between conductive layer 714 and conductive layer 716 (e.g., using the first etching gas). The deepened contact hole 731 can extend from opening 719 to conductive layer 716.

FIG. 7L illustrates that the filler material in contact holes 725, 727, and 729 is removed. The mask layer 411 also can be removed using, for example, chemical mechanical planarization (CMP).

FIG. 7M illustrates that contact structures 726, 728, 730, and 732 are formed in contact holes 725, 727, 729, and 731, respectively. Each of contact structures 726, 728, 730, and 732 can include an outer layer (e.g., outer layer 733) and an inner layer (e.g., inner layer 735) on an inner surface of the outer layer 733. The inner layer can include a conductive material (e.g., copper or tungsten) and can be referred to as a conductive structure. The outer layer can include an insulating material (a dielectric material such as silicon oxide) and can be referred to as an insulating layer. Contact structures 726, 728, 730, and 732 can be formed by first depositing the dielectric material into the contact holes 725, 727, 729, and 731 to form insulating layers on inner surfaces of the contact holes 725, 727, 729, and 731. After that, bottoms of the insulating layers can be etched off to expose the conductive layers 710, 712, 714, and 716 in the contact holes 725, 727, 729, and 731, respectively. Then, inner layers of the contact structures 726, 728, 730, and 732 can be formed by depositing the conductive material into the contact holes 725, 727, 729, and 731. As a result, contact structures 726, 728, 730, and 732 are coupled to conductive layers 710, 712, 714, and 716, respectively, and the respective outer layer 733 can insulate each conductive structure from one or more conductive layers that the contact structure extends through. In some implementations, after deposition, CMP can be used to polish away excess materials such as metal and dielectric, leaving a flat surface with metal in the contact holes.

FIG. 7N illustrates that a semiconductor structure 744 is stacked on and bonded to semiconductor structure 702. Semiconductor structure 744 can be a base die (e.g., base die 212 of FIG. 2A, base die 644a of FIG. 6A, or base die 644d of FIG. 6D). Semiconductor structure 744 includes vias 750 extending along the Z direction. Semiconductor structure 744 can be bonded to semiconductor structure 702 using any suitable bonding techniques. In some implementations, semiconductor structure 744 and semiconductor structure 702 can be bonded through conductive bonding contacts and dielectric materials. Specifically, a bonding layer 743 can be formed on a top surface of semiconductor structure 702. Bonding layer 743 can include conductive bonding contacts 742 and a dielectric material isolating the conductive bonding contacts 742. Contact structures 726, 728, 730, and 732 are connected to corresponding bonding contacts of conductive bonding contacts 742. In some implementations, an interconnect layer is formed in semiconductor structure 702 before bonding layer 743 is formed. The interconnect layer can be coupled to contact structures 726, 728, 730, and 732. A bonding layer 745 can be formed on a bottom surface of semiconductor structure 744. Bonding layer 745 can include conductive bonding contacts 746 and a dielectric material isolating the conductive bonding contacts 746. Conductive bonding contacts 746 are connected to the vias 750 of the semiconductor structure 744. Conductive bonding contacts 742 and conductive bonding contacts 746 can include the same conductive material such as metal (e.g., copper). Bonding layer 743 and bonding layer 745 can include the same dielectric material (e.g., silicon oxide). Semiconductor structure 744 is stacked on semiconductor structure 702 so that bonding layer 745 is in contact with bonding layer 743 and each conductive bonding contact 746 is in contact with a corresponding conductive bonding contact 742. By applying pressure and heat, bonding layer 745 is bonded to bonding layer 743.

In some implementations, the process described with respect to FIGS. 7A-7N can be modified to form a semiconductor device having contact structures that extend through the semiconductor structure 744 (e.g., the stack of memory dice and base die as described with respect to FIGS. 6E and 6G). For example, before forming mask layer 711 on top of semiconductor structure 702 (as shown in FIG. 7G), semiconductor structure 744 can be stacked on and bonded to semiconductor structure 702 though a dielectric bonding layer. Then mask layer 711 can be formed on top of semiconductor structure 744. Thus, contact structures extending through the semiconductor structure 744 can be formed by etching the mask layer 711 to form openings, forming contact holes extending from the openings to conductive layers 710-716, and forming contact structures in the contact holes, which is similar to the process as described with respect to FIGS. 7G-7M.

In some implementations, semiconductor structures 702, 704, 706, 708, and 744 can be fabricated separately such that a limitation (e.g., thermal budget) of fabricating one of them does not limit the processes of fabricating another. In some implementations, semiconductor structures 702, 704, 706, 708, and 744 can be fabricated in parallel.

In some implementations, each of semiconductor structures 702, 704, 706, 708, and 744 includes a semiconductor die (e.g., a memory die or a base die). Each semiconductor die can include a fully functional electronic circuit (e.g., a microprocessor, memory, sensor, or any other suitable type of integrated circuit) and can be encapsulated in a protective package.

In some implementations, each of semiconductor structures 702, 704, 706, 708, and 744 includes a semiconductor wafer. The semiconductor wafer can include multiple semiconductor devices or dies manufactured by depositing multiple layers of various materials and etching them onto the semiconductor wafer in intricate patterns defined by a chip design. The process as described with respect to FIGS. 7A-7N is performed at the wafer level and is applied to multiple semiconductor wafers to form a stack of semiconductor wafers bonded together. After the process is complete, the stack of semiconductor wafers is cut and diced into individual pieces. Each individual piece (which can also be referred to as a die) includes a fully functional electronic circuit, which can be a microprocessor, an HBM, a sensor, or any other suitable type of integrated circuit. In some embodiments, each individual piece is encapsulated in a protective package, providing physical support, protection from environmental factor, and connections (e.g., through pins or solder balls) to external devices or systems.

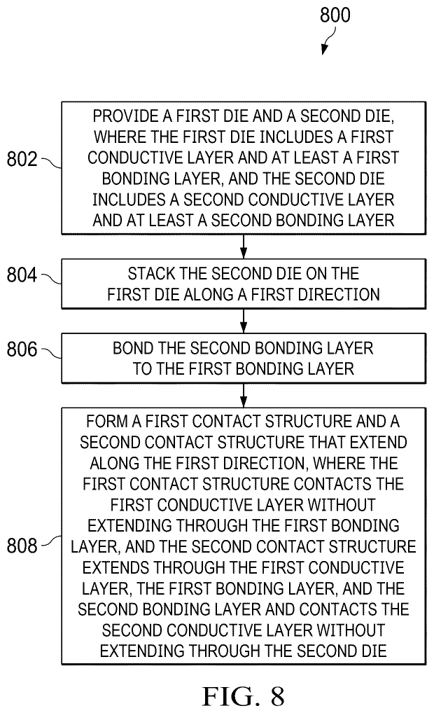

FIG. 8 illustrates a flow chart of an example process 800 of forming a semiconductor device, according to some aspects of the present disclosure. The semiconductor device can be similar to, or same as, the semiconductor devices 200d, 600a, 600d, 600c, and 600g, or a part of these semiconductor devices, or a structure at an intermediate fabrication process of these semiconductor devices. The process 800 can be described in view of FIGS. 7A-7N. The process 800 can include the fabrication process of forming the semiconductor structures in FIGS. 7A-7N. The process 800 includes steps that can be performed with any suitable order and/or any combination.

At step 802, a first die and a second die are provided. The first die includes a first conductive layer and at least a first bonding layer. The second die includes a second conductive layer and at least a second bonding layer. The first die can be, for example, semiconductor structure 702 of FIG. 7D, and the second die can be, for example, semiconductor structure 704 of FIG. 7D. In some implementations, the first bonding layer of the first die and the second bonding layer of the second die each includes a dielectric material and excludes a conductive bonding contact. In some implementations, providing the first die includes thinning the first die by thinning a substrate comprised in the first die (e.g., thinning semiconductor structure 702 as described with respect to FIG. 7B).

At step 804, the second die is stacked on the first die along a first direction (e.g., the Z direction). In some implementations, stacking the second die on the first die along the first direction includes aligning the second die with the first die to place the second conductive layer and the first conductive layer at a same position along a second direction (e.g., the X direction) perpendicular to the first direction.

At step 806, the second bonding layer of the second die is bonded to the first bonding layer of the first die. For example, the second bonding layer can be the dielectric layer deposited on the bottom surface of semiconductor structure 704, and the first bonding layer can be the dielectric layer deposited on the top surface of semiconductor structure 702, as described with respect to FIG. 7C.

At step 808, a first contact structure and a second contact structure that extend along the first direction are formed. The first contact structure (e.g., contact structure 726 of FIG. 7M) extends into the first die (e.g., semiconductor structure 702) and contacts the first conductive layer (e.g., conductive layer 710) of the first die without extending through the first bonding layer. The second contact structure (e.g., contact structure 728 of FIG. 7M) extends through the first conductive layer, the first bonding layer of the first die, and the second bonding layer of the second die and into the second die (e.g., semiconductor structure 704). The second contact structure contacts the second conductive layer (e.g., conductive layer 712) of the second die without extending through the second die.

In some implementations, the process 800 further includes stacking the first die on a carrier wafer (e.g., semiconductor structure 700 of FIGS. 7A-7N). The first die can be stacked on the carrier wafer before the second die is stacked on the first die. The first die is between the carrier wafer and the second die.

In some implementations, the first contact structure and the second contact structure are formed by the following process (e.g., as described with respect to FIGS. 7H-7M). The process includes forming a mask layer (e.g., mask layer 711 of FIG. 7G) on top of the first die and etching the mask layer to form a first opening (e.g., opening 713 of FIG. 7G) and a second opening (e.g., opening 715 of FIG. 7G). Then, a first contact hole (e.g., contact hole 725 of FIG. 7H) and a second contact hole (e.g., contact hole 727 of FIG. 7H) extending along the first direction are formed. The first contact hole extends from the first opening to the first conductive layer, and the second contact hole extends from the second opening to the first conductive layer. The process further includes filling the first contact hole with a filler material (e.g., filler material 718 of FIG. 7I). The second contact hole is deepened until the second contact hole extends through the first conductive layer and extends to the second conductive layer. The filler material in the first contact hole is removed. The process further includes forming a respective insulating layer (e.g., outer layer 733 of FIG. 7M) in each of the first contact hole and the second contact hole. The process further includes forming a conductive structure in the insulating layer of each of the first contact hole and the second contact hole (e.g., by depositing a conductive material such as copper or tungsten into the first contact hole and the second contact hole). The first contact structure includes the insulating layer and the conductive structure in the first contact hole, and the second contact structure includes the insulating layer and the conductive structure in the second contact hole.

In some implementations, forming the first contact structure and the second contact structure further includes etching bottoms of the insulating layers to expose the first conductive layer of the first die and the second conductive layer of the second die in the first contact hole and the second contact hole respectively.

In some implementations, forming the first contact hole and the second contact hole includes etching an isolating material in the first die using a first etching gas, and deepening the second contact hole includes etching a conductive material of the first conductive layer using a second etching gas that is different from the first etching gas.

In some implementations, the process 800 further includes forming a third bonding layer (e.g., bonding layer 743 of FIG. 7N) on a top surface of the first die opposite to the first bonding layer. The third bonding layer includes conductive bonding contacts (e.g., conductive bonding contacts 742 of FIG. 7N) and a dielectric material isolating the conductive bonding contacts. The first contact structure and the second contact structure can be coupled to the conductive bonding contacts.

In some implementations, the process 800 further includes providing a base die (e.g., semiconductor structure 744 of FIG. 7N). The base die includes a bottom bonding layer (e.g., bonding layer 745 of FIG. 7N), which includes conductive bonding contacts (e.g., conductive bonding contacts 746 of FIG. 7N) and a dielectric material isolating the conductive bonding contacts. The base die can further include vias extending along the first direction. As described with respect to FIG. 7N, the process 800 can further include stacking the base die on the first die and bonding the bottom bonding layer of the base die to the third bonding layer of the first die. The bottom bonding layer and the third bonding layer can be bonded by bonding the dielectric material of the bottom bonding layer to the dielectric material of the third bonding layer and bonding the conductive bonding contacts of the bottom bonding layer to the conductive bonding contacts of the third bonding layer.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first layer, a second layer, a first die between the first layer and the second layer, and a second die stacked together along a first direction, wherein:
each of the first die and the second die has a conductive layer; and
the first die and the second die are bonded through the second layer;
a first contact structure coupled to the conductive layer of the first die, wherein the first contact structure extends along the first direction and contacts the conductive layer of the first die without extending through the second layer; and
a second contact structure coupled to the conductive layer of the second die, wherein:
the second contact structure extends through the second layer along the first direction without extending through the second die; and
the second contact structure contacts the conductive layer of the second die without extending through the conductive layer of the first die.

2. The semiconductor device of claim 1, further comprising a base die, wherein:
the base die, the first layer, the first die, the second layer, and the second die are stacked along the first direction; and
the base die and the first die are bonded through the first layer.

3. The semiconductor device of claim 1, wherein:
a first end of the conductive layer of the first die and a first end of the conductive layer of the second die are offset along a second direction perpendicular to the first direction.

4. The semiconductor device of claim 3, wherein:
the second contact structure is between the first end of the conductive layer of the first die and the first end of the conductive layer of the second die along the second direction.

5. The semiconductor device of claim 2, wherein:
the second layer comprises at least one dielectric material and excludes a conductive bonding contact; and
the first layer comprises conductive bonding contacts and at least one dielectric material isolating the conductive bonding contacts.

6. The semiconductor device of claim 5, wherein:
the second layer comprises a top bonding layer and a bottom bonding layer each comprising a dielectric material and excluding a conductive bonding contact;
the dielectric material of the top bonding layer of the second layer is bonded to the dielectric material of the bottom bonding layer of the second layer;
the first layer comprises a top bonding layer and a bottom bonding layer each comprising conductive bonding contacts and a dielectric material isolating the conductive bonding contacts;
the dielectric material of the top bonding layer of the first layer is bonded to the dielectric material of the bottom bonding layer of the first layer; and
the conductive bonding contacts of the top bonding layer of the first layer are bonded to the conductive bonding contacts of the bottom bonding layer of the first layer.

7. The semiconductor device of claim 5, wherein:
the base die comprises first vias extending along the first direction and being coupled to the conductive bonding contacts of the first layer; and
each of the first contact structure and the second contact structure is coupled to one of the first vias through one of the conductive bonding contacts of the first layer.

8. A semiconductor device, comprising:
a base die, a first layer, a second layer, a first die between the first layer and the second layer, and a second die stacked together along a first direction, wherein:
each of the base die, the first die, and the second die has a conductive layer;
the first die and the second die are bonded through the second layer; and
the base die and the first die are bonded through the first layer;
a first contact structure coupled to the conductive layer of the base die, wherein the first contact structure extends along the first direction and contacts the conductive layer of the base die without extending through the first layer;
a second contact structure coupled to the conductive layer of the first die, wherein:
the second contact structure extends through the first layer along the first direction without extending through the second layer; and
the second contact structure contacts the conductive layer of the first die without extending through the conductive layer of the base die; and
a third contact structure coupled to the conductive layer of the second die, wherein:
the third contact structure extends through the first layer and the second layer along the first direction without extending through the second die; and
the third contact structure contacts the conductive layer of the second die without extending through the conductive layer of the first die.

9. The semiconductor device of claim 8, wherein:
a first end of the conductive layer of the first die and a first end of the conductive layer of the second die are offset along a second direction perpendicular to the first direction.

10. The semiconductor device of claim 9, wherein:
the third contact structure is between the first end of the conductive layer of the first die and the first end of the conductive layer of the second die along the second direction.

11. The semiconductor device of claim 8, wherein:
the second layer comprises at least one dielectric material and excludes a conductive bonding contact; and
the first layer comprises at least one dielectric material and excludes a conductive bonding contact.

12. The semiconductor device of claim 11, wherein:
the second layer comprises a top bonding layer and a bottom bonding layer each comprising a dielectric material and excluding a conductive bonding contact;
the dielectric material of the top bonding layer of the second layer is bonded to the dielectric material of the bottom bonding layer of the second layer;
the first layer comprises a top bonding layer and a bottom bonding layer each comprising a dielectric material and excluding a conductive bonding contact; and
the dielectric material of the top bonding layer of the first layer is bonded to the dielectric material of the bottom bonding layer of the first layer.

13. The semiconductor device of claim 8, wherein:
the base die comprises an interconnect layer extending along a second direction perpendicular to the first direction; and
each of the first contact structure, the second contact structure, and the third contact structure is coupled to the interconnect layer.

14. A method, comprising:
providing a first die and a second die, wherein the first die comprises a conductive layer and at least a first bonding layer, and the second die comprises a conductive layer and at least a second bonding layer;
stacking the second die on the first die along a first direction;
bonding the second bonding layer of the second die to the first bonding layer of the first die; and
forming a first contact structure and a second contact structure that extend along the first direction, wherein:
the first contact structure contacts the conductive layer of the first die;
the second contact structure extends through the first bonding layer of the first die and the second bonding layer of the second die; and
the second contact structure contacts the conductive layer of the second die without contacting the conductive layer of the first die.

15. The method of claim 14, wherein stacking the second die on the first die along the first direction comprises:
aligning the second die with the first die to offset a first end of the conductive layer of the first die and a first end of the conductive layer of the second die along a second direction perpendicular to the first direction.

16. The method of claim 14, wherein providing the first die comprises:
thinning the first die by thinning a substrate comprised in the first die.

17. The method of claim 14, wherein the first contact structure and the second contact structure are formed by a same process comprising:
forming a first contact hole and a second contact hole;
forming an insulating layer in each of the first contact hole and the second contact hole; and
forming the first contact structure and the second contact structure by forming a conductive structure in the insulating layer of each of the first contact hole and the second contact hole, wherein the first contact structure comprises the insulating layer and the conductive structure in the first contact hole, and the second contact structure comprises the insulating layer and the conductive structure in the second contact hole.

18. The method of claim 14, further comprising:
forming a third bonding layer on top of the first die, wherein the third bonding layer comprises conductive bonding contacts and a dielectric material isolating the conductive bonding contacts.

19. The method of claim 18, further comprising:
providing a base die, wherein the base die comprises a bottom bonding layer comprising conductive bonding contacts and a dielectric material isolating the conductive bonding contacts.

20. The method of claim 19, further comprising:
stacking the base die on the first die by bonding the dielectric material of the bottom bonding layer of the base die to the dielectric material of the third bonding layer of the first die and bonding the conductive bonding contacts of the bottom bonding layer of the base die to the conductive bonding contacts of the third bonding layer of the first die.
